(19) United States
(12) Patent Application Publication
(10) Pub. No.: US 2023/0045583 A1
(43) Pub. Date: Feb. 9, 2023

(54) ORGANIC ELECTROLUMINESCENCE DEVICE, ELECTRONIC APPARATUS, AND METHOD FOR FABRICATING ORGANIC ELECTROLUMINESCENCE DEVICE

(71) Applicant: IDEMITSU KOSAN CO., LTD., Tokyo (JP)

(72) Inventors: Yoshinori AOYAMA, Tokyo (JP); Kazuki NISHIMURA, Tokyo (JP); Sayaka MIZUTANI, Tokyo (JP); Masato MITANI, Tokyo (JP); Ryota TAKAHASHI, Tokyo (JP)

(73) Assignee: IDEMITSU KOSAN CO., LTD., Tokyo (JP)

(21) Appl. No.: 17/849,574

(22) Filed: Jun. 24, 2022

(30) Foreign Application Priority Data
Jun. 30, 2021 (JP) 2021-109468

(51) Int. Cl. H01L 51/00

(52) U.S. Cl. CPC H01L 51/0067; H01L 51/0073; H01L 51/0072; H01L 51/0058; H01L 51/508

(57) ABSTRACT

An organic electroluminescence device comprising: a cathode; an anode; an emitting layer disposed between the cathode and the anode; and a first layer disposed between the emitting layer and the cathode, wherein the emitting layer comprises a host compound, the first layer comprises a first compound and a second compound, and the three compounds are in a relationship satisfying the following Conditions 1 and 2:
(Condition 1)
   the electron affinity Af_{H} of the host compound and the electron affinity Af_{ETA} of the first compound satisfy the following expressions (1-1) and (1-2):

Af_{H}<Af_{ETA} (1-1)

|Af_{H}−Af_{ETA}|≤0.10 (1-2)
(Condition 2)
   the electron affinity Af_{H} of the host compound and the electron affinity Af_{ETB} of the second compound satisfy the following expressions (2-1) and (2-2):

Af_{H}>Af_{ETB} (2-1)

|A_{fH}−Af_{ETB}|≤0.10 (2-2).

### TECHNICAL FIELD

Embodiments described herein generally relate to an organic electroluminescence device, an electronic apparatus, and a method for fabricating an organic electroluminescence device.

### BACKGROUND ART

When voltage is applied to an organic electroluminescence device (hereinafter, referred to as an organic EL device), holes and electrons are injected into an emitting layer from an anode and a cathode, respectively. Then, thus injected holes and electrons are recombined in the emitting layer, and excitons are formed therein.

The conventional organic EL device has insufficient device performance. The organic EL device has been gradually improved in order to increase device performance, but further elevation in the device performance is required.

### RELATED ART DOCUMENTS

### Patent Documents

[Patent Document 1] JP 2018-168361 A

### SUMMARY OF THE INVENTION

An object of the invention is to provide an organic EL device having higher performance.

As a result of intensive studies focusing on the configuration of the electron-transporting zone of the organic EL device, the inventors considered that, in the conventional organic EL device, electrons tend to be pooled at the interface between the emitting layer and the electron-transporting zone, and that increase in the device performance is hindered due to the unnecessary interaction between the pooled electrons and the exciton of the emitting layer. For example, Patent Document 1 discloses a specific example of an organic EL device in which one layer in an electron-transporting zone contains two compounds in which the absolute value of the affinity (electron affinity) of one compound is smaller than that of the host compound in the emitting layer, and the absolute value of the affinity of the other compound is larger than that of the host compound in the emitting layer. The inventors considered that, in such a conventional organic EL device, since the difference between the absolute value of the affinity of the “other compound” and the absolute value of the affinity of the host compound is too large (in other words, the absolute value of the affinity of the “other compound” is too large than the absolute value of the affinity of the host compound), an energy barrier is generated at the interface between the emitting layer and the electron-transporting zone, and as a result, electrons tend to be pooled at the interface.

Therefore, the inventors have found that, by containing two compounds in one layer in the electron-transporting zone, the absolute value of the affinity of one compound is smaller in a certain range than the absolute value of the affinity of the host material in the emitting layer, and the absolute value of the affinity of the other compound is larger (not becomes too large) in a certain range than the absolute value of the affinity of the host material in the emitting layer, the carrier balance is improved, pool of electrons at the interface between the emitting layer and the electron-transporting zone can be suppressed, and an organic EL device having higher performance can be obtained, whereby the invention has been completed.

It should be noted that Patent Document 1 is available as a basic application document of priority pertaining to the international application (PCT/JP2019/034437, WO 2020/050217).

According to the invention, the following organic EL device and the like are provided.
1. An organic electroluminescence device comprising

a cathode;

an anode; and

an emitting layer disposed between the cathode and the anode,

a first layer disposed between the emitting layer and the cathode,

wherein

the emitting layer comprises a host compound,

the first layer comprises a first compound and a second compound; and

the three compounds are in a relationship satisfying the following Conditions 1 and 2:

### (Condition 1)

the electron affinity Af_{H} of the host compound and the electron affinity Af_{ETA} of the first compound satisfy the following expressions (1-1) and (1-2):

Af_{H}<Af_{ETA} (1-1)

|Af_{H}−Af_{ETA}|≤0.10 (1-2)

### (Condition 2)

the electron affinity Af_{H} of the host compound and the electron affinity Af_{ETB} of the second compound satisfy the following expressions (2-1) and (2-2):

Af_{H}>Af_{ETB} (2-1)

|Af_{H}−Af_{ETB}≡1≤0.10 (2-2)

According to the invention, an organic EL device having higher performance can be provided.

### BRIEF DESCRIPTION OF THE DRAWINGS

The FIGURE is a diagram showing a schematic configuration of the organic EL device according to an aspect of the invention.

### MODE FOR CARRYING OUT THE INVENTION

### Definition

In this specification, a hydrogen atom includes its isotopes different in the number of neutrons, namely, a protium, a deuterium and a tritium.

In this specification, at a bondable position in a chemical formula where a symbol such as “R”, or “D” representing a deuterium atom is not indicated, a hydrogen atom, that is, a protium atom, a deuterium atom or a tritium atom is bonded.

In this specification, the number of ring carbon atoms represents the number of carbon atoms forming a subject ring itself among the carbon atoms of a compound having a structure in which atoms are bonded in a ring form (for example, a monocyclic compound, a fused ring compound, a cross-linked compound, a carbocyclic compound, or a heterocyclic compound). When the subject ring is substituted by a substituent, the carbon contained in the substituent is not included in the number of ring carbon atoms. The same shall apply to “the number of ring carbon atoms” described below, unless otherwise specified. For example, a benzene ring has 6 ring carbon atoms, a naphthalene ring includes 10 ring carbon atoms, a pyridine ring includes 5 ring carbon atoms, and a furan ring includes 4 ring carbon atoms. Further, for example, a 9,9-diphenylfluorenyl group includes 13 ring carbon atoms, and a 9,9′-spirobifluorenyl group includes 25 ring carbon atoms.

When a benzene ring is substituted by, for example, an alkyl group as a substituent, the number of carbon atoms of the alkyl group is not included in the number of ring carbon atoms of the benzene ring. Therefore, the number of ring carbon atoms of the benzene ring substituted by the alkyl group is 6. When a naphthalene ring is substituted by, for example, an alkyl group as a substituent, the number of carbon atoms of the alkyl group is not included in the number of ring carbon atoms of the naphthalene ring. Therefore, the number of ring carbon atoms of the naphthalene ring substituted by the alkyl group is 10.

In this specification, the number of ring atoms represents the number of atoms forming a subject ring itself among the atoms of a compound having a structure in which atoms are bonded in a ring form (for example, the structure includes a monocyclic ring, a fused ring and a ring assembly) (for example, a monocyclic compound, a fused ring compound, a cross-linked compound, a carbocyclic compound and a heterocyclic compound). The number of ring atoms does not include atoms which do not form the ring (for example, a hydrogen atom which terminates a bond of the atoms forming the ring), or atoms contained in a substituent when the ring is substituted by the substituent. The same shall apply to “the number of ring atoms” described below, unless otherwise specified. For example, the number of atoms of a pyridine ring is 6, the number of atoms of a quinazoline ring is 10, and the number of a furan ring is 5. For example, hydrogen atoms bonded to a pyridine ring and atoms constituting a substituent substituted on the pyridine ring are not included in the number of ring atoms of the pyridine ring. Therefore, the number of ring atoms of a pyridine ring with which a hydrogen atom or a substituent is bonded is 6. For example, hydrogen atoms and atoms constituting a substituent which are bonded with a quinazoline ring is not included in the number of ring atoms of the quinazoline ring. Therefore, the number of ring atoms of a quinazoline ring with which a hydrogen atom or a substituent is bonded is 10.

In this specification, “XX to YY carbon atoms” in the expression “a substituted or unsubstituted ZZ group including XX to YY carbon atoms” represents the number of carbon atoms in the case where the ZZ group is unsubstituted by a substituent, and does not include the number of carbon atoms of a substituent in the case where the ZZ group is substituted by the substituent. Here, “YY” is larger than “XX”, and “XX” means an integer of 1 or more and “YY” means an integer of 2 or more.

In this specification, “XX to YY atoms” in the expression “a substituted or unsubstituted ZZ group including XX to YY atoms” represents the number of atoms in the case where the ZZ group is unsubstituted by a substituent, and does not include the number of atoms of a substituent in the case where the ZZ group is substituted by the substituent. Here, “YY” is larger than “XX”, and “XX” means an integer of 1 or more and “YY” means an integer of 2 or more.

In this specification, the unsubstituted ZZ group represents the case where the “substituted or unsubstituted ZZ group” is a “ZZ group unsubstituted by a substituent”, and the substituted ZZ group represents the case where the “substituted or unsubstituted ZZ group” is a “ZZ group substituted by a substituent”.

In this specification, a term “unsubstituted” in the case of “a substituted or unsubstituted ZZ group” means that hydrogen atoms in the ZZ group are not substituted by a substituent. Hydrogen atoms in a term “unsubstituted ZZ group” are a protium atom, a deuterium atom, or a tritium atom.

In this specification, a term “substituted” in the case of “a substituted or unsubstituted ZZ group” means that one or more hydrogen atoms in the ZZ group are substituted by a substituent. Similarly, a term “substituted” in the case of “a BB group substituted by an AA group” means that one or more hydrogen atoms in the BB group are substituted by the AA group.

“Substituent as Described in this Specification”

Hereinafter, the substituent described in this specification will be explained.

The number of ring carbon atoms of the “unsubstituted aryl group” described in this specification is 6 to 50, preferably 6 to 30, and more preferably 6 to 18, unless otherwise specified.

The number of ring atoms of the “unsubstituted heterocyclic group” described in this specification is 5 to 50, preferably 5 to 30, and more preferably 5 to 18, unless otherwise specified.

The number of carbon atoms of the “unsubstituted alkyl group” described in this specification is 1 to 50, preferably 1 to 20, and more preferably 1 to 6, unless otherwise specified.

The number of carbon atoms of the “unsubstituted alkenyl group” described in this specification is 2 to 50, preferably 2 to 20, and more preferably 2 to 6, unless otherwise specified.

The number of carbon atoms of the “unsubstituted alkynyl group” described in this specification is 2 to 50, preferably 2 to 20, and more preferably 2 to 6, unless otherwise specified.

The number of ring carbon atoms of the “unsubstituted cycloalkyl group” described in this specification is 3 to 50, preferably 3 to 20, and more preferably 3 to 6, unless otherwise specified.

The number of ring carbon atoms of the “unsubstituted arylene group” described in this specification is 6 to 50, preferably 6 to 30, and more preferably 6 to 18, unless otherwise specified.

The number of ring atoms of the “unsubstituted divalent heterocyclic group” described in this specification is 5 to 50, preferably 5 to 30, and more preferably 5 to 18, unless otherwise specified.

The number of carbon atoms of the “unsubstituted alkylene group” described in this specification is 1 to 50, preferably 1 to 20, and more preferably 1 to 6, unless otherwise specified.

“Substituted or unsubstituted aryl group”

Specific examples of the “substituted or unsubstituted aryl group” described in this specification (specific example group G1) include the following unsubstituted aryl groups (specific example group G1A), substituted aryl groups (specific example group G1B), and the like. (Here, the unsubstituted aryl group refers to the case where the “substituted or unsubstituted aryl group” is an “aryl group unsubstituted by a substituent”, and the substituted aryl group refers to the case where the “substituted or unsubstituted aryl group” is an “aryl group substituted by a substituent”.). In this specification, in the case where simply referred as an “aryl group”, it includes both a “unsubstituted aryl group” and a “substituted aryl group.”

The “substituted aryl group” means a group in which one or more hydrogen atoms of the “unsubstituted aryl group” are substituted by a substituent. Specific examples of the “substituted aryl group” include, for example, groups in which one or more hydrogen atoms of the “unsubstituted aryl group” of the following specific example group G1A are substituted by a substituent, the substituted aryl groups of the following specific example group G1B, and the like. It should be noted that the examples of the “unsubstituted aryl group” and the examples of the “substituted aryl group” enumerated in this specification are mere examples, and the “substituted aryl group” described in this specification also includes a group in which a hydrogen atom bonded with a carbon atom of the aryl group itself in the “substituted aryl group” of the following specific group G1B is further substituted by a substituent, and a group in which a hydrogen atom of a substituent in the “substituted aryl group” of the following specific group G1B is further substituted by a substituent.

Unsubstituted Aryl Group (Specific Example Group G1A):

a phenyl group,

a p-biphenyl group,

a m-biphenyl group,

an o-biphenyl group,

a p-terphenyl-4-yl group,

a p-terphenyl-3-yl group,

a p-terphenyl-2-yl group,

a m-terphenyl-4-yl group,

a n-terphenyl-3-yl group,

a n-terphenyl-2-yl group,

an o-terphenyl-4-yl group,

an o-terphenyl-3-yl group,

an o-terphenyl-2-yl group,

a 1-naphthyl group,

a 2-naphthyl group,

an anthryl group,

a benzanthryl group,

a phenanthryl group,

a benzophenanthryl group,

a phenalenyl group,

a pyrenyl group,

a chrysenyl group,

a benzochrysenyl group,

a triphenylenyl group,

a benzaotriphenylenyl group,

a tetracenyl group,

a pentacenyl group,

a fluorenyl group,

a 9,9-spirobifluorenyl group,

a benzofluorenyl group,

a dibenzofluorenyl group,

a fluoranthenyl group,

a benzofluoranthenyl group,

a perylenyl group, and

a monovalent aryl group derived by removing one hydrogen atom from the ring structures represented by each of the following general formulas (TEMP-1) to (TEMP-15).

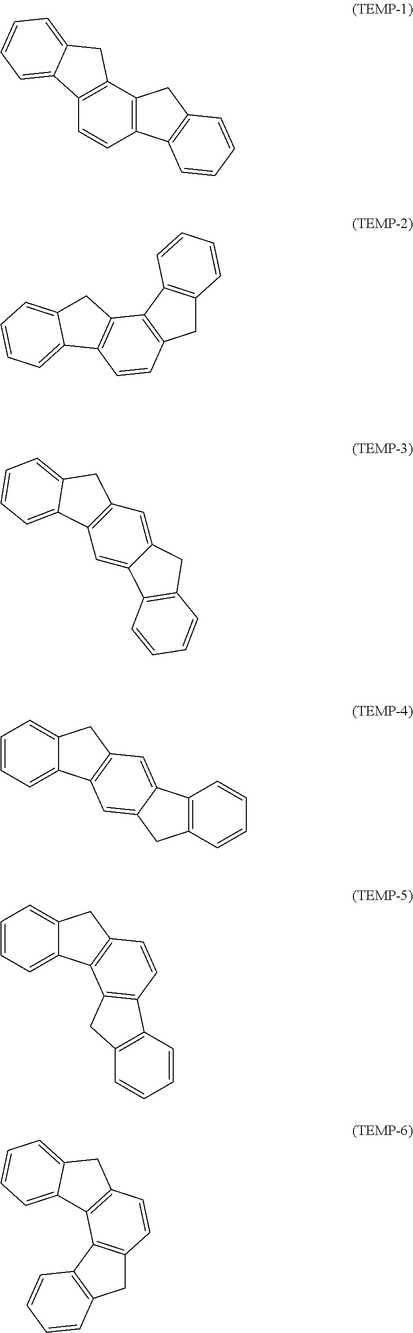

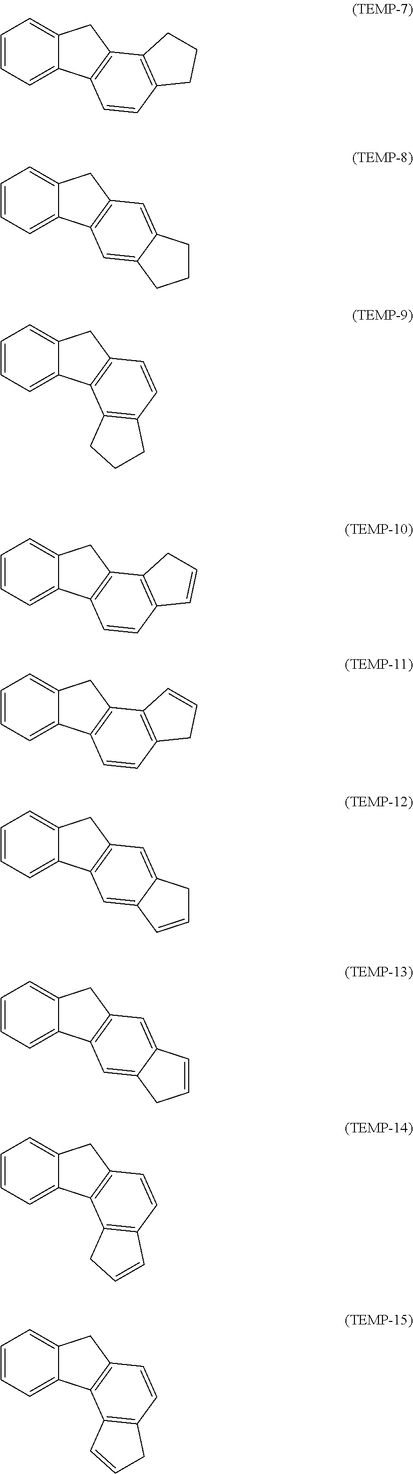

Substituted Aryl Group (Specific Example Group G1B):

an o-tolyl group,

a m-tolyl group,

a p-tolyl group,

a p-xylyl group,

a m-xylyl group,

an o-xylyl group,

a p-isopropylphenyl group,

a m-isopropylphenyl group,

an o-isopropylphenyl group,

a p-t-butylphenyl group,

a m-t-butylphenyl group,

an o-t-butylphenyl group,

a 3,4,5-trimethylphenyl group,

a 9,9-dimethylfluorenyl group,

a 9,9-diphenylfluorenyl group,

a 9,9-bis(4-methylphenyl)fluorenyl group,

a 9,9-bis(4-isopropylphenyl)fluorenyl group,

a 9,9-bis(4-t-butylphenyl)fluorenyl group,

a cyanophenyl group,

a triphenylsilylphenyl group,

a trimethylsilylphenyl group,

a phenylnaphthyl group,

a naphthylphenyl group, and

a group in which one or more hydrogen atoms of a monovalent group derived from the ring structures represented by each of the general formulas (TEMP-1) to (TEMP-15) are substituted by a substituent.

“Substituted or unsubstituted heterocyclic group”

The “heterocyclic group” described in this specification is a ring group having at least one hetero atom in the ring atom. Specific examples of the hetero atom include a nitrogen atom, an oxygen atom, a sulfur atom, a silicon atom, a phosphorus atom, and a boron atom.

The “heterocyclic group” in this specification is a monocyclic group or a fused ring group. The “heterocyclic group” in this specification is an aromatic heterocyclic group or a non-aromatic heterocyclic group.

Specific examples of the “substituted or unsubstituted heterocyclic group” (specific example group G2) described in this specification include the following unsubstituted heterocyclic group (specific example group G2A), the following substituted heterocyclic group (specific example group G2B), and the like. (Here, the unsubstituted heterocyclic group refers to the case where the “substituted or unsubstituted heterocyclic group” is a “heterocyclic group unsubstituted by a substituent”, and the substituted heterocyclic group refers to the case where the “substituted or unsubstituted heterocyclic group” is a “heterocyclic group substituted by a substituent”.). In this specification, in the case where simply referred as a “heterocyclic group”, it includes both the “unsubstituted heterocyclic group” and the “substituted heterocyclic group.”

The “substituted heterocyclic group” means a group in which one or more hydrogen atom of the “unsubstituted heterocyclic group” are substituted by a substituent. Specific examples of the “substituted heterocyclic group” include a group in which a hydrogen atom of “unsubstituted heterocyclic group” of the following specific example group G2A is substituted by a substituent, the substituted heterocyclic groups of the following specific example group G2B, and the like. It should be noted that the examples of the “unsubstituted heterocyclic group” and the examples of the “substituted heterocyclic group” enumerated in this specification are mere examples, and the “substituted heterocyclic group” described in this specification includes groups in which hydrogen atom bonded with a ring atom of the heterocyclic group itself in the “substituted heterocyclic group” of the specific example group G2B is further substituted by a substituent, and a group in which hydrogen atom of a substituent in the “substituted heterocyclic group” of the specific example group G2B is further substituted by a substituent.

Specific example group G2A includes, for example, the following unsubstituted heterocyclic group containing a nitrogen atom (specific example group G2A1), the following unsubstituted heterocyclic group containing an oxygen atom (specific example group G2A2), the following unsubstituted heterocyclic group containing a sulfur atom (specific example group G2A3), and the monovalent heterocyclic group derived by removing one hydrogen atom from the ring structures represented by each of the following general formulas (TEMP-16) to (TEMP-33) (specific example group G2A4).

Specific example group G2B includes, for example, the following substituted heterocyclic group containing a nitrogen atom (specific example group G2B1), the following substituted heterocyclic group containing an oxygen atom (specific example group G2B2), the following substituted heterocyclic group containing a sulfur atom (specific example group G2B3), and the following group in which one or more hydrogen atoms of the monovalent heterocyclic group derived from the ring structures represented by each of the following general formulas (TEMP-16) to (TEMP-33) are substituted by a substituent (specific example group G2B4).

Unsubstituted Heterocyclic Group Containing a Nitrogen Atom (Specific Example Group G2A1):

a pyrrolyl group,

an imidazolyl group,

a pyrazolyl group,

a triazolyl group,

a tetrazolyl group,

an oxazolyl group,

an isoxazolyl group,

an oxadiazolyl group,

a thiazolyl group,

an isothiazolyl group,

a thiadazolyl group,

a pyridyl group,

a pyridazinyl group,

a pyrimidinyl group,

a pyrazinyl group,

a triazinyl group,

an indolyl group,

an isoindolyl group,

an indolizinyl group,

a quinolizinyl group,

a quinolyl group,

an isoquinoyl group,

a cinnolyl group,

a phthalazinyl group,

a quinazolinyl group,

a quinoxalinyl group,

a benzimidazoyl group,

an indazolyl group,

a phenanthrolinyl group,

a phenanthridinyl group,

an acridinyl group,

a phenazinyl group,

a carbazolyl group,

a benzocarbazolyl group,

a morpholino group,

a phenoxazinyl group,

a phenothiazinyl group,

an azacarbazyoyl group, and

a diazacarbazolyl group.

Unsubstituted Heterocyclic Group Containing an Oxygen Atom (Specific Example Group G2A2):

a furyl group,

an oxazolyl group,

an isoxazolyl group,

an oxadiazolyl group,

a xanthenyl group,

a benzofuranyl group,

an isobenzofuranyl group,

a dibenzofuranyl group,

a naphthobenzofuranyl group,

a benzoxazolyl group,

a benzisoxazolyl group,

a phenoxazinyl group,

a morpholino group,

a dinaphthofuranyl group,

an azadibenzofuranyl group,

a diazadibenzofuranyl group,

an azanaphthobenzofuranyl group, and

a diazanaphthobenzofuranyl group.

Unsubstituted Heterocyclic Group Containing a Sulfur Atom (Specific Example Group G2A3):

a thienyl group,

a thiazolyl group,

an isothiazolyl group,

a thiadiazolyl group,

a benzothiophenyl group (benzothienyl group),

an isobenzothiophenyl group (isobenzothienyl group),

a dibenzothiophenyl group (dibenzothienyl group),

a naphthobenzothiophenyl group (naphthobenzothienyl group),

a benzothiazolyl group,

a benzisothiazolyl group,

a phenothiazinyl group,

a dinaphthothiophenyl group (dinaphthothienyl group),

an azadibenzothiophenyl group (azadibenzothienyl group),

a diazadibenzothiophenyl group (diazadibenzothienyl group),

an azanaphthobenzothiophenyl group (azanaphthobenzothienyl group), and

a diazanaphthobenzothiophenyl group (diazanaphthobenzothienyl group).

Monovalent Heterocyclic Group Derived by Removing One Hydrogen Atom from the Ring Structures Represented by Each of the Following General Formulas (TEMP-16) to (TEMP-33) (Specific Example Group G2A4):

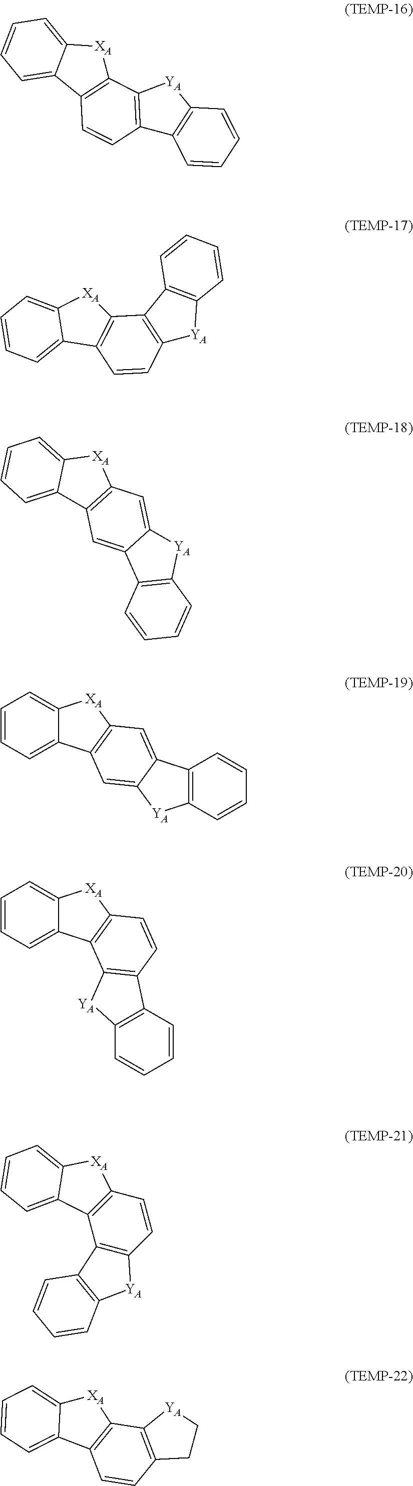

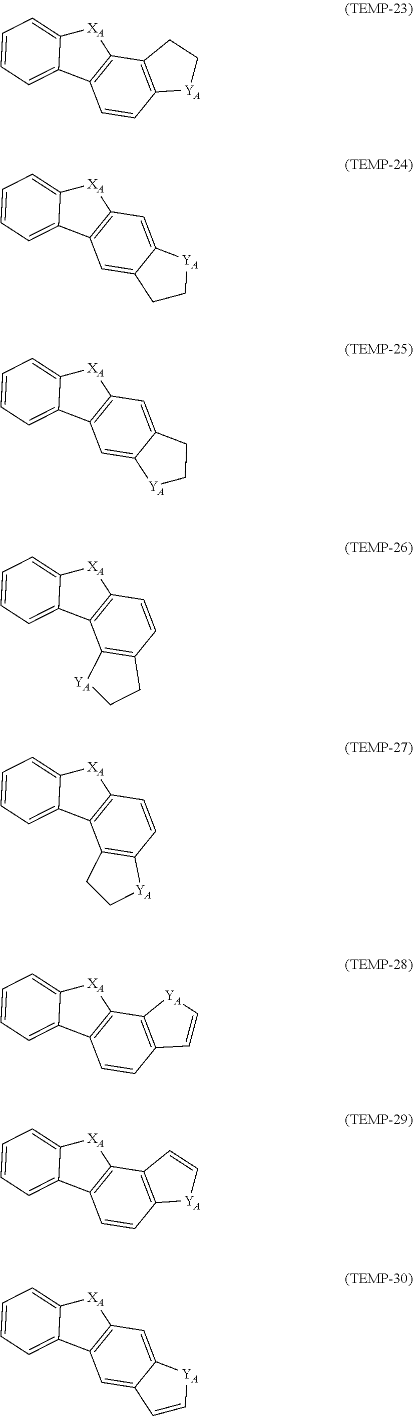

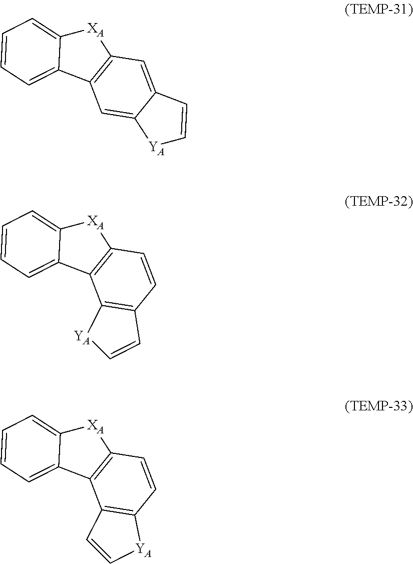

In the general formulas (TEMP-16) to (TEMP-33), X_{A} and Y_{A} are independently an oxygen atom, a sulfur atom, NH, or CH₂. Provided that at least one of X_{A} and Y_{A} is an oxygen atom, a sulfur atom, or NH.

In the general formulas (TEMP-16) to (TEMP-33), when at least one of X_{A} and Y_{A} is NH or CH₂, the monovalent heterocyclic group derived from the ring structures represented by each of the general formulas (TEMP-16) to (TEMP-33) includes a monovalent group derived by removing one hydrogen atom from these NH or CH₂.

Substituted Heterocyclic Group Containing a Nitrogen Atom (Specific Example Group G2B1):

a (9-phenyl)carbazolyl group,

a (9-biphenylyl)carbazolyl group,

a (9-phenyl)phenylcarbazolyl group,

a (9-naphthyl)carbazolyl group,

a diphenylcarbazol-9-yl group,

a phenylcarbazol-9-yl group,

a methylbenzimidazolyl group,

an ethylbenzimidazolyl group,

a phenyltriazinyl group,

a biphenylyltriazinyl group,

a diphenyltriazinyl group,

a phenylquinazolinyl group, and

a biphenylylquinazolinyl group.

Substituted Heterocyclic Group Containing an Oxygen Atom (Specific Example Group G2B2):

a phenyldibenzofuranyl group,

a methyldibenzofuranyl group,

a t-butyldibenzofuranyl group, and

a monovalent residue of spiro[9H-xanthene-9,9′-[9H]fluorene].

Substituted Heterocyclic Group Containing a Sulfur Atom (Specific Example Group G2B3):

a phenyldibenzothiophenyl group,

a methyldibenzothiophenyl group,

a t-butyldibenzothiophenyl group, and

a monovalent residue of spiro[9H-thioxanthene-9,9′-[9H]fluorene].

Group in which One or More Hydrogen Atoms of the Monovalent Heterocyclic Group Derived from the Ring Structures Represented by Each of the Following General Formulas (TEMP-16) to (TEMP-33) are Substituted by a Substituent (Specific Example Group G2B4):

The “one or more hydrogen atoms of the monovalent heterocyclic group” means one or more hydrogen atoms selected from hydrogen atoms bonded with ring carbon atoms of the monovalent heterocyclic group, a hydrogen atom bonded with a nitrogen atom when at least one of X_{A} and Y_{A} is NH, and hydrogen atoms of a methylene group when one of X_{A} and Y_{A} is CH₂.

“Substituted or Unsubstituted Alkyl Group”

Specific examples of the “substituted or unsubstituted alkyl group” (specific example group G3) described in this specification include the following unsubstituted alkyl groups (specific example group G3A) and the following substituted alkyl groups (specific example group G3B). (Here, the unsubstituted alkyl group refers to the case where the “substituted or unsubstituted alkyl group” is an “alkyl group unsubstituted by a substituent”, and the substituted alkyl group refers to the case where the “substituted or unsubstituted alkyl group” is an “alkyl group substituted by a substituent”.). In this specification, in the case where simply referred as an “alkyl group” includes both the “unsubstituted alkyl group” and the “substituted alkyl group.”

The “substituted alkyl group” means a group in which one or more hydrogen atoms in the “unsubstituted alkyl group” are substituted by a substituent. Specific examples of the “substituted alkyl group” include groups in which one or more hydrogen atoms in the following “unsubstituted alkyl group” (specific example group G3A) are substituted by a substituent, the following substituted alkyl group (specific example group G3B), and the like. In this specification, the alkyl group in the “unsubstituted alkyl group” means a linear alkyl group. Thus, the “unsubstituted alkyl group” includes a straight-chain “unsubstituted alkyl group” and a branched-chain “unsubstituted alkyl group”. It should be noted that the examples of the “unsubstituted alkyl group” and the examples of the “substituted alkyl group” enumerated in this specification are mere examples, and the “substituted alkyl group” described in this specification includes a group in which hydrogen atom of the alkyl group itself in the “substituted alkyl group” of the specific example group G3B is further substituted by a substituent, and a group in which hydrogen atom of a substituent in the “substituted alkyl group” of the specific example group G3B is further substituted by a substituent.

Unsubstituted Alkyl Group (Specific Example Group G3A):

a methyl group,

an ethyl group,

a n-propyl group,

an isopropyl group,

a n-butyl group,

an isobutyl group,

a s-butyl group, and

a t-butyl group.

Substituted Alkyl Group (Specific Example Group G3B):

a heptafluoropropyl group (including isomers),

a pentafluoroethyl group,

a 2,2,2-trifluoroethyl group, and

a trifluoromethyl group.

“Substituted or Unsubstituted Alkenyl Group”

Specific examples of the “substituted or unsubstituted alkenyl group” described in this specification (specific example group G4) include the following unsubstituted alkenyl group (specific example group G4A), the following substituted alkenyl group (specific example group G4B), and the like. (Here, the unsubstituted alkenyl group refers to the case where the “substituted or unsubstituted alkenyl group” is a “alkenyl group unsubstituted by a substituent”, and the “substituted alkenyl group” refers to the case where the “substituted or unsubstituted alkenyl group” is a “alkenyl group substituted by a substituent”). In this specification, in the case where simply referred as an “alkenyl group” includes both the “unsubstituted alkenyl group” and the “substituted alkenyl group.”

The “substituted alkenyl group” means a group in which one or more hydrogen atoms in the “unsubstituted alkenyl group” are substituted by a substituent. Specific examples of the “substituted alkenyl group” include a group in which the following “unsubstituted alkenyl group” (specific example group G4A) has a substituent, the following substituted alkenyl group (specific example group G4B), and the like. It should be noted that the examples of the “unsubstituted alkenyl group” and the examples of the “substituted alkenyl group” enumerated in this specification are mere examples, and the “substituted alkenyl group” described in this specification includes a group in which a hydrogen atom of the alkenyl group itself in the “substituted alkenyl group” of the specific example group G4B is further substituted by a substituent, and a group in which a hydrogen atom of a substituent in the “substituted alkenyl group” of the specific example group G4B is further substituted by a substituent.

Unsubstituted Alkenyl Group (Specific Example Group G4A):

a vinyl group,

an allyl group,

a 1-butenyl group,

a 2-butenyl group, and

a 3-butenyl group.

Substituted Alkenyl Group (Specific Example Group G4B):

a 1,3-butanedienyl group,

a 1-methylvinyl group,

a 1-methylallyl group,

a 1,1-dimethylallyl group,

a 2-methylally group, and

a 1,2-dimethylallyl group.

“Substituted or Unsubstituted Alkynyl Group”

Specific examples of the “substituted or unsubstituted alkynyl group” described in this specification (specific example group G5) include the following unsubstituted alkynyl group (specific example group G5A) and the like. (Here, the unsubstituted alkynyl group refers to the case where the “substituted or unsubstituted alkynyl group” is an “alkynyl group unsubstituted by a substituent”.). In this specification, in the case where simply referred as an “alkynyl group” includes both the “unsubstituted alkynyl group” and the “substituted alkynyl group.”

The “substituted alkynyl group” means a group in which one or more hydrogen atoms in the “unsubstituted alkynyl group” are substituted by a substituent. Specific examples of the “substituted alkynyl group” include a group in which one or more hydrogen atoms in the following “unsubstituted alkynyl group” (specific example group G5A) are substituted by a substituent, and the like.

Unsubstituted Alkynyl Group (Specific Example Group G5A):

an ethynyl group.

“Substituted or Unsubstituted Cycloalkyl Group”

Specific examples of the “substituted or unsubstituted cycloalkyl group” described in this specification (specific example group G6) include the following unsubstituted cycloalkyl group (specific example group G6A), the following substituted cycloalkyl group (specific example group G6B), and the like. (Here, the unsubstituted cycloalkyl group refers to the case where the “substituted or unsubstituted cycloalkyl group” is a “cycloalkyl group unsubstituted by a substituent”, and the substituted cycloalkyl group refers to the case where the “substituted or unsubstituted cycloalkyl group” is a “cycloalkyl group substituted by a substituent”.). In this specification, in the case where simply referred as a “cycloalkyl group” includes both the “unsubstituted cycloalkyl group” and the “substituted cycloalkyl group.”

The “substituted cycloalkyl group” means a group in which one or more hydrogen atoms in the “unsubstituted cycloalkyl group” are substituted by a substituent. Specific examples of the “substituted cycloalkyl group” include a group in which one or more hydrogen atoms in the following “unsubstituted cycloalkyl group” (specific example group G6A) are substituted by a substituent, and examples of the following substituted cycloalkyl group (specific example group G6B), and the like. It should be noted that the examples of the “unsubstituted cycloalkyl group” and the examples of the “substituted cycloalkyl group” enumerated in this specification are mere examples, and the “substituted cycloalkyl group” in this specification includes a group in which one or more hydrogen atoms bonded with the carbon atom of the cycloalkyl group itself in the “substituted cycloalkyl group” of the specific example group G6B are substituted by a substituent, and a group in which a hydrogen atom of a substituent in the “substituted cycloalkyl group” of specific example group G6B is further substituted by a substituent

Unsubstituted Cycloalkyl Group (Specific Example Group G6A):

a cyclopropyl group,

a cyclobutyl group,

a cyclopentyl group,

a cyclohexyl group,

a 1-adamantyl group,

a 2-adamantyl group,

a 1-norbornyl group, and

a 2-norbomyl group.

Substituted Cycloalkyl Group (Specific Example Group G6B):

a 4-methylcyclohexyl group.

“Group represented by —Si(R₉₀₁)(R₉₀₂)(R₉₀₃)”

Specific examples of the group represented by —Si(R₉₀₁)(R₉₀₂)(R₉₀₃) described in this specification (specific example group G7) include:

—Si(G1)(G1)(G1),

—Si(G1)(G2)(G2),

—Si(G1)(G1)(G2),

—Si(G2)(G2)(G2),

—Si(G3)(G3)(G3), and

—Si(G6)(G6)(G6).

G1 is the “substituted or unsubstituted aryl group” described in the specific example group G1. G2 is the “substituted or unsubstituted heterocyclic group” described in the specific example group G2.

G3 is the “substituted or unsubstituted alkyl group” described in the specific example group

G3.

G6 is the “substituted or unsubstituted cycloalkyl group” described in the specific example group G6.

Plural G1s in —Si(G1)(G1)(G1) are the same or different.

Plural G2's in —Si(G1)(G2)(G2) are the same or different.

Plural GIs in —Si(G1)(G1)(G2) are the same or different.

Plural G2's in —Si(G2)(G2)(G2) are be the same or different.

Plural G3's in —Si(G3)(G3)(G3) are the same or different.

Plural G6's in —Si(G6)(G6)(G6) are be the same or different.

“Group represented by —O—(R₉₀₄)”

Specific examples of the group represented by —O—(R₉₀₄) in this specification (specific example group G8) include:

—O(G1),

—O(G2),

—O(G3), and

—O(G6).

G1 is the “substituted or unsubstituted aryl group” described in the specific example group G1. G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

“Group represented by —S—(R₉₀₅)”

Specific examples of the group represented by —S—(R₉₀₅) in this specification (specific example group G9) include:

—S(G1),

—S(G2),

—S(G3), and

—S(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

“Group represented by —N(R₉₀₆)(R₉₀₇)”

Specific examples of the group represented by —N(R₉₀₆)(R₉₀₇) in this specification (specific example group G10) include:

—N(G1)(G1),

—N(G2)(G2),

—N(G1)(G2),

—N(G3)(G3), and

—N(G6)(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

Plural G1s in —N(G1)(G1) are the same or different.

Plural G2's in —N(G2)(G2) are the same or different.

Plural G3's in —N(G3)(G3) are the same or different.

Plural G6's in —N(G6)(G6) are the same or different.

“Halogen Atom”

Specific examples of the “halogen atom” described in this specification (specific example group G11) include a fluorine atom, a chlorine atom, a bromine atom, an iodine atom, and the like.

“Substituted or Unsubstituted Fluoroalkyl Group”

The “substituted or unsubstituted fluoroalkyl group” described in this specification is a group in which at least one hydrogen atom bonded with a carbon atom constituting the alkyl group in the “substituted or unsubstituted alkyl group” is substituted by a fluorine atom, and includes a group in which all hydrogen atoms bonded with a carbon atom constituting the alkyl group in the “substituted or unsubstituted alkyl group” are substituted by a fluorine atom (a perfluoro group). The number of carbon atoms of the “unsubstituted fluoroalkyl group” is 1 to 50, preferably 1 to 30, more preferably 1 to 18, unless otherwise specified in this specification. The “substituted fluoroalkyl group” means a group in which one or more hydrogen atoms of the “fluoroalkyl group” are substituted by a substituent. The “substituted fluoroalkyl group” described in this specification also includes a group in which one or more hydrogen atoms bonded with a carbon atom of the alkyl chains in the “substituted fluoroalkyl group” are further substituted by a substituent, and a group in which one or more hydrogen atom of a substituent in the “substituted fluoroalkyl group” are further substituted by a substituent. Specific examples of the “unsubstituted fluoroalkyl group” include a group in which one or more hydrogen atoms in the “alkyl group” (specific group G3) are substituted by a fluorine atom, and the like.

“Substituted or Unsubstituted Haloalkyl Group”

The “substituted or unsubstituted haloalkyl group” described in this specification is a group in which at least one hydrogen atom bonded with a carbon atom constituting the alkyl group in the “substituted or unsubstituted alkyl group” is substituted by a halogen atom, and also includes a group in which all hydrogen atoms bonded with a carbon atom constituting the alkyl group in the “substituted or unsubstituted alkyl group” are substituted by a halogen atom. The number of carbon atoms of the “unsubstituted haloalkyl group” is 1 to 50, preferably 1 to 30, more preferably 1 to 18, unless otherwise specified in this specification. The “substituted haloalkyl group” means a group in which one or more hydrogen atoms of the “haloalkyl group” are substituted by a substituent. The “substituted haloalkyl group” described in this specification also includes a group in which one or more hydrogen atoms bonded with a carbon atom of the alkyl chain in the “substituted haloalkyl group” are further substituted by a substituent, and a group in which one or more hydrogen atoms of a substituent in the “substituted haloalkyl group” are further substituted by a substituent. Specific examples of the “unsubstituted haloalkyl group” include a group in which one or more hydrogen atoms in the “alkyl group” (specific example group G3) are substituted by a halogen atom, and the like. A haloalkyl group is sometimes referred to as an alkyl halide group.

“Substituted or Unsubstituted Alkoxy Group”

Specific examples of the “substituted or unsubstituted alkoxy group” described in this specification include a group represented by —O(G3), wherein G3 is the “substituted or unsubstituted alkyl group” described in the specific example group G3. The number of carbon atoms of the “unsubstituted alkoxy group” is 1 to 50, preferably 1 to 30, more preferably 1 to 18, unless otherwise specified in this specification.

“Substituted or Unsubstituted Alkylthio Group”

Specific examples of the “substituted or unsubstituted alkylthio group” described in this specification include a group represented by —S(G3), wherein G3 is the “substituted or unsubstituted alkyl group” described in the specific example group G3. The number of carbon atoms of the “unsubstituted alkylthio group” is 1 to 50, preferably 1 to 30, more preferably 1 to 18, unless otherwise specified in this specification.

“Substituted or Unsubstituted Aryloxy Group”

Specific examples of the “substituted or unsubstituted aryloxy group” described in this specification include a group represented by —O(G1), wherein G1 is the “substituted or unsubstituted aryl group” described in the specific example group G1. The number of ring carbon atoms of the “unsubstituted aryloxy group” is 6 to 50, preferably 6 to 30, more preferably 6 to 18, unless otherwise specified in this specification.

“Substituted or Unsubstituted Arylthio Group”

Specific examples of the “substituted or unsubstituted arylthio group” described in this specification include a group represented by —S(G1), wherein G1 is a “substituted or unsubstituted aryl group” described in the specific example group G1. The number of ring carbon atoms of the “unsubstituted arylthio group” is 6 to 50, preferably 6 to 30, more preferably 6 to 18, unless otherwise specified in this specification.

“Substituted or Unsubstituted Trialkylsilyl Group”

Specific examples of the “trialkylsilyl group” described in this specification include a group represented by —Si(G3)(G3)(G3), where G3 is the “substituted or unsubstituted alkyl group” described in the specific example group G3. Plural G3's in —Si(G3)(G3)(G3) are the same or different. The number of carbon atoms in each alkyl group of the “trialkylsilyl group” is 1 to 50, preferably 1 to 20, more preferably 1 to 6, unless otherwise specified in this specification.

“Substituted or Unsubstituted Aralkyl Group”

Specific examples of the “substituted or unsubstituted aralkyl group” described in this specification is a group represented by -(G3)-(G1), wherein G3 is the “substituted or unsubstituted alkyl group” described in the specific example group G3, and G1 is the “substituted or unsubstituted aryl group” described in the specific example group G1. Therefore, the “aralkyl group” is a group in which a hydrogen atom of the “alkyl group” is substituted by an “aryl group” as a substituent, and is one form of the “substituted alkyl group.” The “unsubstituted aralkyl group” is the “unsubstituted alkyl group” substituted by the “unsubstituted aryl group”, and the number of carbon atoms of the “unsubstituted aralkyl group” is 7 to 50, preferably 7 to 30, more preferably 7 to 18, unless otherwise specified in this specification.

Specific examples of the “substituted or unsubstituted aralkyl group” include a benzyl group, a 1-phenylethyl group, a 2-phenylethyl group, a 1-phenylisopropyl group, a 2-phenylisopropyl group, a phenyl-t-butyl group, an a-naphthylmethyl group, a 1-α-naphthylethyl group, a 2-α-naphthylethyl group, a 1-α-naphthylisopropyl group, a 2-α-naphthylisopropyl group, a p-naphthylmethyl group, a 1-ρ-naphthylethyl group, a 2-β-naphthylethyl group, a 1-β-naphthylisopropyl group, a 2-β-naphthylisopropyl group, and the like.

Unless otherwise specified in this specification, examples of the substituted or unsubstituted aryl group described in this specification preferably include a phenyl group, a p-biphenyl group, a m-biphenyl group, an o-biphenyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-terphenyl-4-yl group, an o-terphenyl-3-yl group, an o-terphenyl-2-yl group, a 1-naphthyl group, a 2-naphthyl group, an anthryl group, a phenanthryl group, a pyrenyl group, a chrysenyl group, a triphenylenyl group, a fluorenyl group, a 9,9′-spirobifluorenyl group, 9,9-dimethylfluorenyl group, 9,9-diphenylfluorenyl group, and the like.

Unless otherwise specified in this specification, examples of the substituted or unsubstituted heterocyclic groups described in this specification preferably include a pyridyl group, a pyrimidinyl group, a triazinyl group, a quinolyl group, an isoquinolyl group, a quinazolinyl group, a benzimidazolyl group, a phenanthrolinyl group, a carbazolyl group (a 1-carbazolyl group, a 2-carbazolyl group, a 3-carbazolyl group, a 4-carbazolyl group, or a 9-carbazolyl group), a benzocarbazolyl group, an azacarbazolyl group, a diazacarbazolyl group, a dibenzofuranyl group, a naphthobenzofuranyl group, an azadibenzofuranyl group, a diazadibenzofuranyl group, a dibenzothiophenyl group, a naphthobenzothiophenyl group, an azadibenzothiophenyl group, a diazadibenzothiophenyl group, a (9-phenyl)carbazolyl group (a (9-phenyl)carbazol-1-yl group, a (9-phenyl)carbazol-2-yl group, a (9-phenyl)carbazol-3-yl group, or a (9-phenyl)carbazol-4-yl group), a (9-biphenylyl)carbazolyl group, a (9-phenyl)phenylcarbazolyl group, a diphenylcarbazol-9-yl group, a phenylcarbazol-9-yl group, a phenyltriazinyl group, a biphenylyltriazinyl group, a diphenyltriazinyl group, a phenyldibenzofuranyl group, a phenyldibenzothiophenyl group, and the like.

In this specification, the carbazolyl group is specifically each of the following groups, unless otherwise specified in this specification.

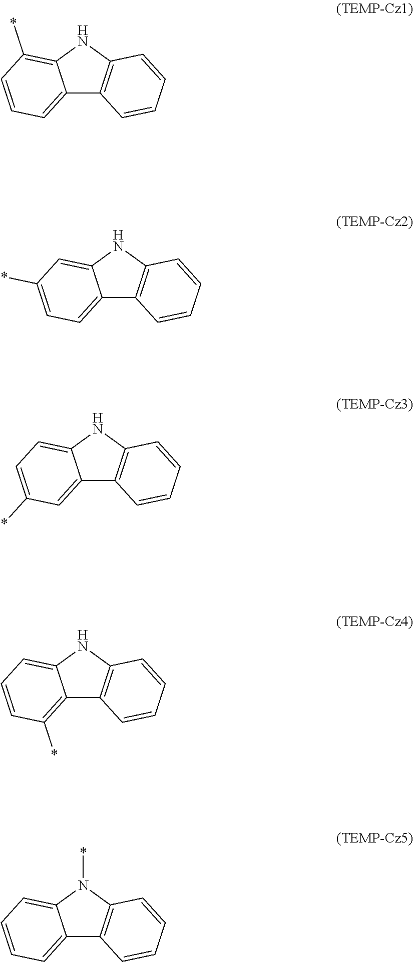 [SMILES: *c1cccc2c1[nH]c1ccccc12 ; *c1ccc2c(c1)[nH]c1ccccc12 ; *c1ccc2[nH]c3ccccc3c2c1 ; *c1cccc2[nH]c3ccccc3c12 ; *n1c2ccccc2c2ccccc21]

In this specification, the (9-phenyl)carbazolyl group is specifically any of the following groups, unless otherwise specified in this specification.

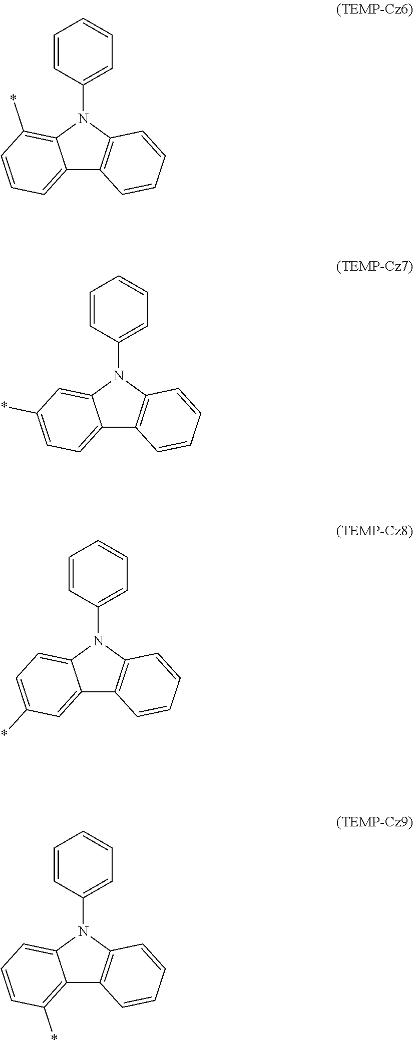 [SMILES: *c1cccc2c3ccccc3n(-c3ccccc3)c12 ; *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1]

In the general formulas (TEMP-Cz1) to (TEMP-Cz9), * represents a bonding site.

In this specification, the dibenzofuranyl group and the dibenzothiophenyl group are specifically any of the following groups, unless otherwise specified in this specification.

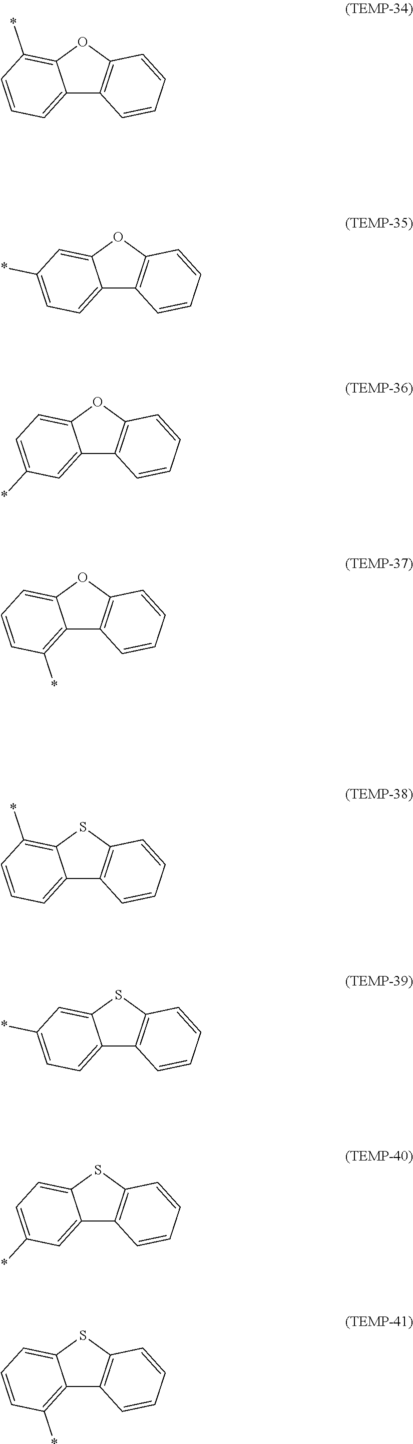

In the general formulas (TEMP-34) to (TEMP-41), * represents a bonding site.

The substituted or unsubstituted alkyl group described in this specification is preferably a methyl group, an ethyl group, a propyl group, an isopropyl group, a n-butyl group, an isobutyl group, a t-butyl group, or the like, unless otherwise specified in this specification.

“Substituted or Unsubstituted Arylene Group”

The “substituted or unsubstituted arylene group” described in this specification is a divalent group derived by removing one hydrogen atom on the aryl ring of the “substituted or unsubstituted aryl group”, unless otherwise specified. Specific examples of the “substituted or unsubstituted arylene group” (specific example group G12) include a divalent group derived by removing one hydrogen atom on the aryl ring of the “substituted or unsubstituted aryl group” described in the specific example group G1, and the like.

“Substituted or Unsubstituted Divalent Heterocyclic Group”

The “substituted or unsubstituted divalent heterocyclic group” described in this specification is a divalent group derived by removing one hydrogen atom on the heterocycle of the “substituted or unsubstituted heterocyclic group”, unless otherwise specified. Specific examples of the “substituted or unsubstituted divalent heterocyclic group” (specific example group G13) include a divalent group derived by removing one hydrogen atom on the heterocycle of the “substituted or unsubstituted heterocyclic group” described in the specific example group G2, and the like.

“Substituted or Unsubstituted Alkylene Group”

The “substituted or unsubstituted alkylene group” described in this specification is a divalent group derived by removing one hydrogen atom on the alkyl chain of the “substituted or unsubstituted alkyl group”, unless otherwise specified. Specific examples of the “substituted or unsubstituted alkylene group” (specific example group G14) include a divalent group derived by removing one hydrogen atom on the alkyl chain of the “substituted or unsubstituted alkyl group” described in the specific example group G3, and the like.

The substituted or unsubstituted arylene group described in this specification is preferably any group of the following general formulas (TEMP-42) to (TEMP-68), unless otherwise specified in this specification.

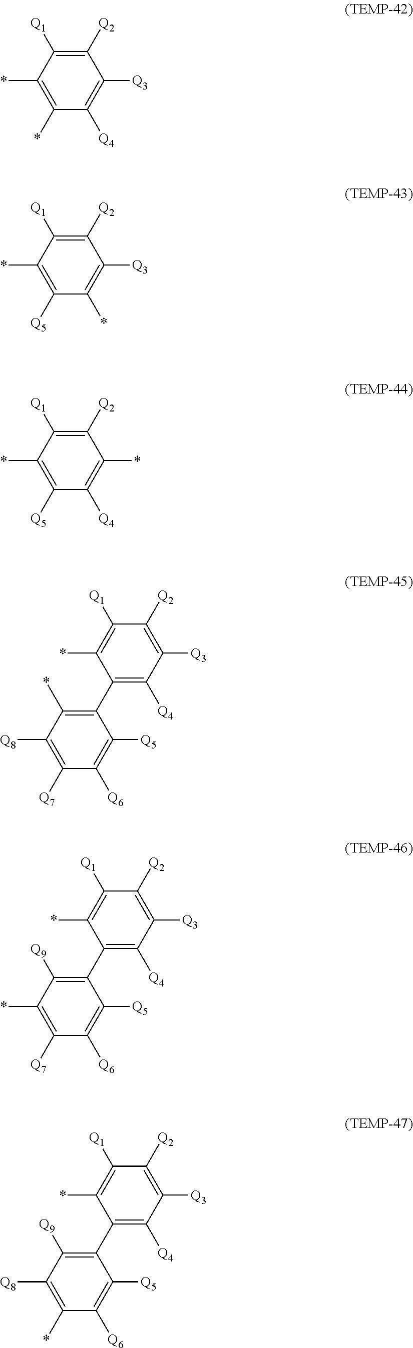

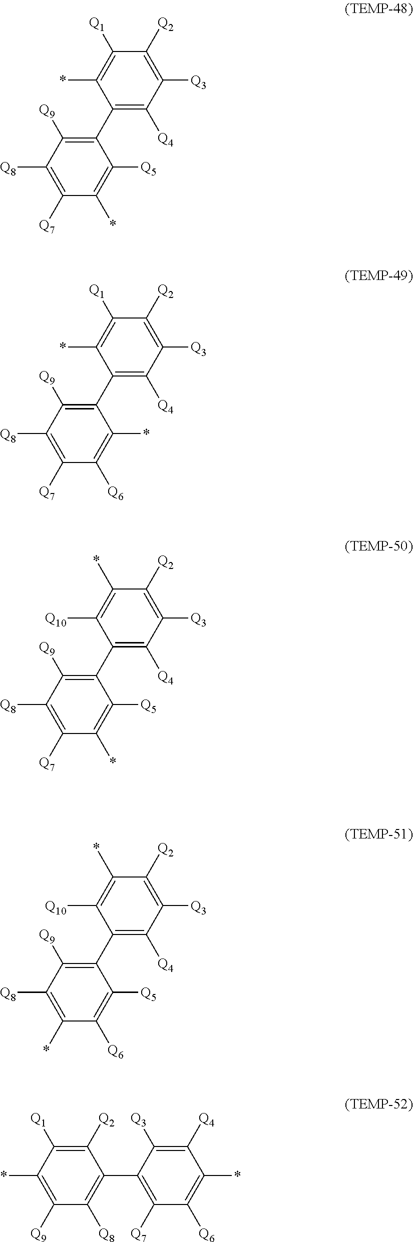

In the general formulas (TEMP-42) to (TEMP-52), Q₁ to Q₁₀ are independently a hydrogen atom or a substituent.

In the general formulas (TEMP-42) to (TEMP-52), * represents a bonding site.

$$Chemistry$$

In the general formulas (TEMP-53) to (TEMP-62), Q₁ to Q₁₀ are independently a hydrogen atom or a substituent.

Q₉ and Q₁₀ may be bonded with each other via a single bond to form a ring.

In the general formulas (TEMP-53) to (TEMP-62), * represents a bonding site.

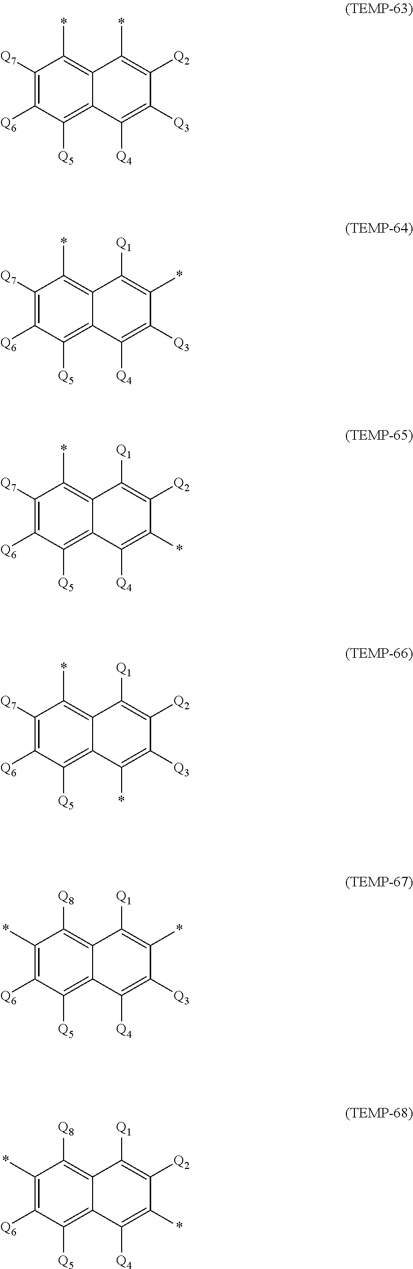

In the general formulas (TEMP-63) to (TEMP-68), Q₁ to Q₈ are independently a hydrogen atom or a substituent.

In the general formulas (TEMP-63) to (TEMP-68), * represents a bonding site.

The substituted or unsubstituted divalent heterocyclic group described in this specification is preferably any group of the following general formulas (TEMP-69) to (TEMP-102), unless otherwise specified in this specification.

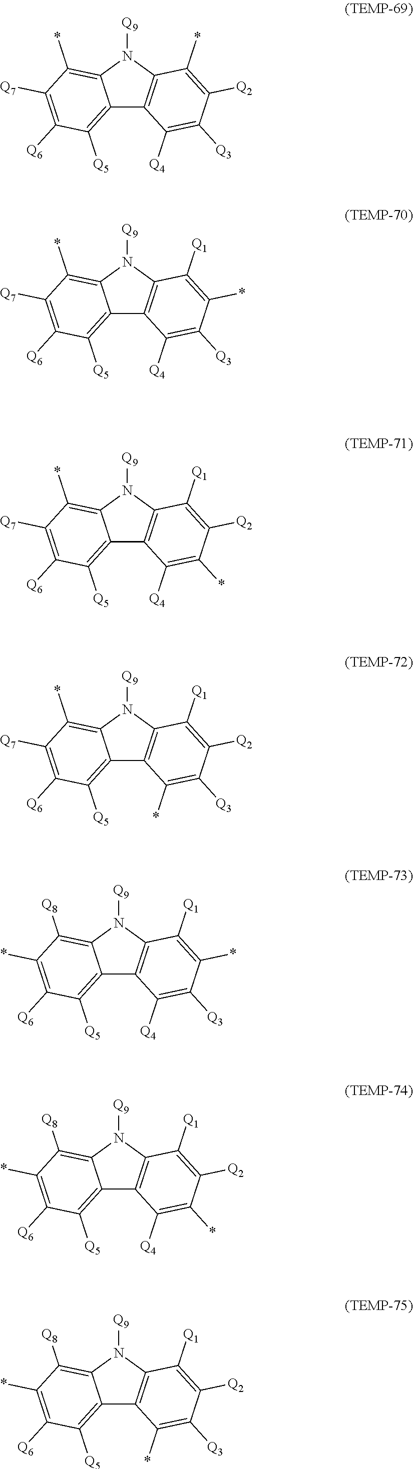

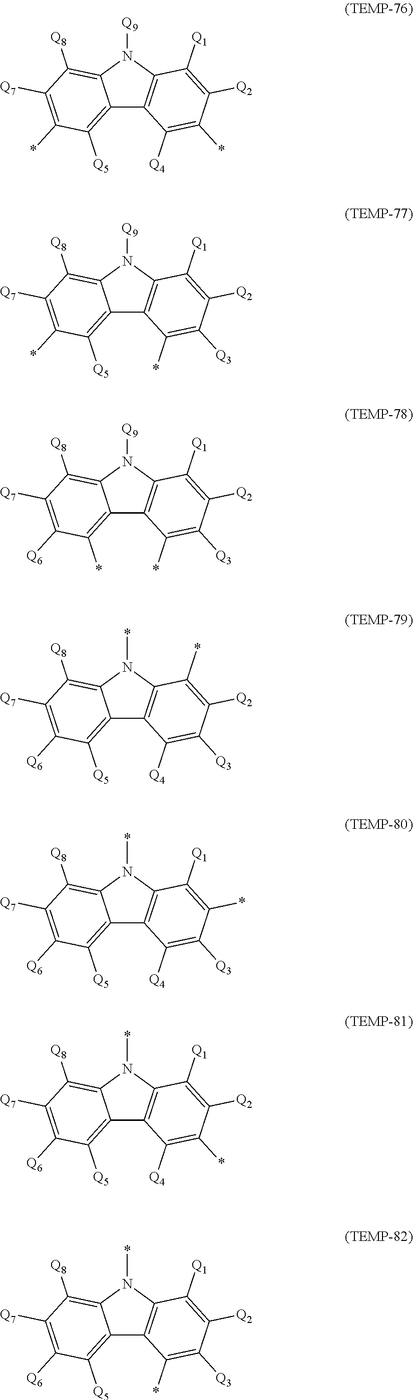

In the general formulas (TEMP-69) to (TEMP-82), Q₁ to Q₉ are independently a hydrogen atom or a substituent.

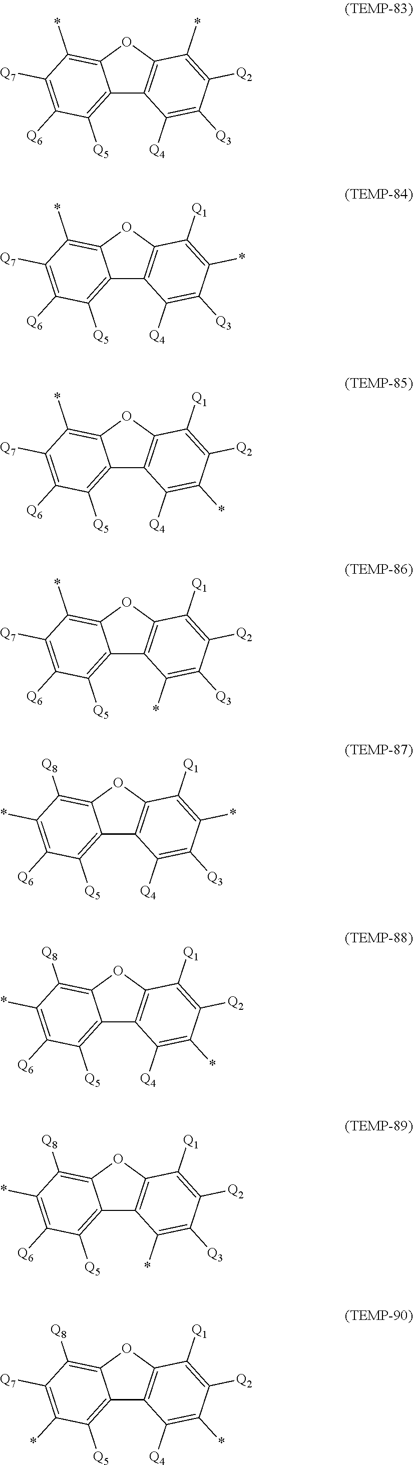

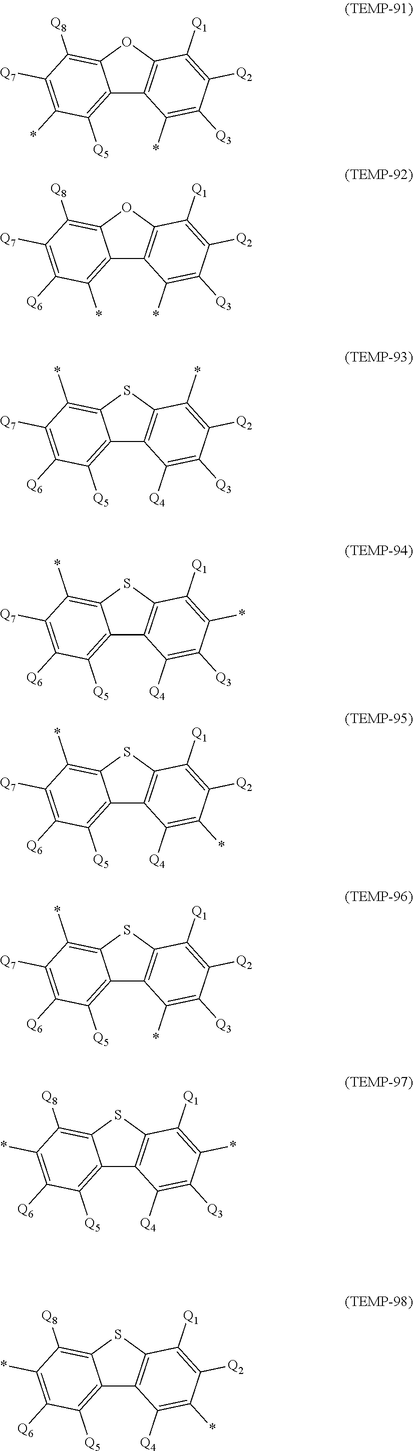

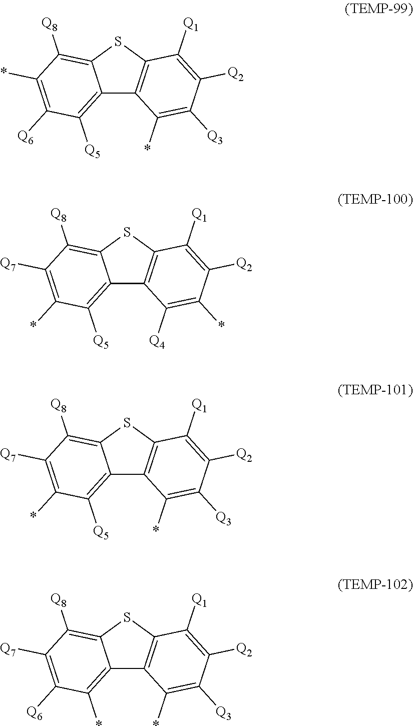

In the general formulas (TEMP-83) to (TEMP-102), Q₁ to Q₈ are independently a hydrogen atom or a substituent.

The above is the explanation of the “Substituent described in this specification.”

“The Case where Bonded with Each Other to Form a Ring”

In this specification, the case where “one or more sets of adjacent two or more form a substituted or unsubstituted monocycle by bonding with each other, form a substituted or unsubstituted fused ring by bonding with each other, or do not bond with each other” means the case where “one or more sets of adjacent two or more form a substituted or unsubstituted monocycle by bonding with each other”; the case where “one or more sets of adjacent two or more form a substituted or unsubstituted fused ring by bonding with each other”; and the case where “one or more sets of adjacent two or more do not bond with each other.”

The case where “one or more sets of adjacent two or more form a substituted or unsubstituted monocycle by bonding with each other” and the case where “one or more sets of adjacent two or more form a substituted or unsubstituted fused ring by bonding with each other” in this specification (these cases may be collectively referred to as “the case where forming a ring by bonding with each other”) will be described below. The case of an anthracene compound represented by the following general formula (TEMP-103) in which the mother skeleton is an anthracene ring will be described as an example.

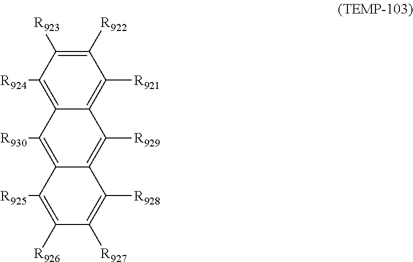

For example, in the case where “one or more sets of adjacent two or more among R₉₂₁ to R₉₃₀ form a ring by bonding with each other”, the one set of adjacent two includes a pair of R₉₂₁ and R₉₂₂, a pair of R₉₂₂ and R₉₂₃, a pair of R₉₂₃ and R₉₂₄, a pair of R₉₂₄ and R₉₃₀, a pair of R₉₃₀ and R₉₂₅, a pair of R₉₂₅ and R₉₂₆, a pair of R₉₂₆ and R₉₂₇, a pair of R₉₂₇ and R₉₂₈, a pair of R₉₂₈ and R₉₂₉, and a pair of R₉₂₉ and R₉₂₁.

The “one or more sets” means that two or more sets of the adjacent two or more sets may form a ring at the same time. For example, R₉₂₁ and R₉₂₂ form a ring Q_{A} by bonding with each other, and at the same, time R₉₂₅ and R₉₂₆ form a ring Q_{B} by bonding with each other, the anthracene compound represented by the general formula (TEMP-103) is represented by the following general formula (TEMP-104).

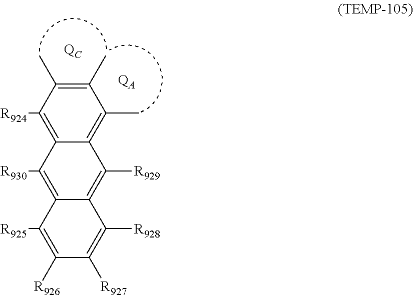

The case where the “set of adjacent two or more” form a ring includes not only the case where the set (pair) of adjacent “two” is bonded with as in the above-mentioned examples, but also the case where the set of adjacent “three or more” are bonded with each other. For example, it means the case where R₉₂₁ and R₉₂₂ form a ring Q_{A} by bonding with each other, and R₉₂₂ and R₉₂₃ form a ring Q_{C} by bonding with each other, and adjacent three (R₉₂₁, R₉₂₂ and R₉₂₃) form rings by bonding with each other and together fused to the anthracene mother skeleton. In this case, the anthracene compound represented by the general formula (TEMP-103) is represented by the following general formula (TEMP-105). In the following general formula (TEMP-105), the ring Q_{A} and the ring Q_{C} share R₉₂₂.

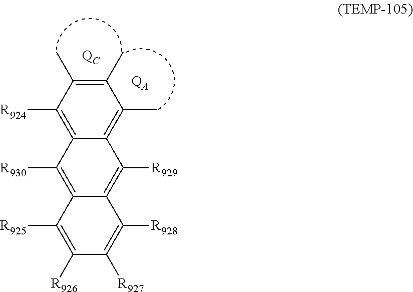

The “monocycle” or “fused ring” formed may be a saturated ring or an unsaturated ring, as a structure of the formed ring alone. Even when the “one pair of adjacent two” forms a “monocycle” or a “fused ring”, the “monocycle” or the “fused ring” may form a saturated ring or an unsaturated ring. For example, the ring Q_{A} and the ring Q_{B} formed in the general formula (TEMP-104) are independently a “monocycle” or a “fused ring.” The ring Q_{A} and the ring Q_{C} formed in the general formula (TEMP-105) are “fused ring.” The ring Q_{A} and ring Q_{C} of the general formula (TEMP-105) are fused ring by fusing the ring Q_{A} and the ring Q_{C} together. When the ring Q_{A} of the general formula (TMEP-104) is a benzene ring, the ring Q_{A} is a monocycle. When the ring Q_{A} of the general formula (TMEP-104) is a naphthalene ring, the ring Q_{A} is a fused ring.

The “unsaturated ring” includes, in addition to an aromatic hydrocarbon ring and an aromatic heterocycle, an aliphatic hydrocarbon ring with an unsaturated bond, i.e., double and/or triple bonds in the ring structure (e.g., cyclohexene, cyclohexadiene, etc.), and a non-aromatic heterocycle with an unsaturated bond (e.g., dihydropyran, imidazoline, pyrazoline, quinolizine, indoline, isoindoline, etc.). The “saturated ring” includes an aliphatic hydrocarbon ring without an unsaturated bond and a non-aromatic heterocycle without ab unsaturated bond.

Specific examples of the aromatic hydrocarbon ring include a structure in which the group listed as a specific example in the specific example group G1 is terminated by a hydrogen atom.

Specific examples of the aromatic heterocycle include a structure in which the aromatic heterocyclic group listed as a specific example in the example group G2 is terminated by a hydrogen atom.

Specific examples of the aliphatic hydrocarbon ring include a structure in which the group listed as a specific example in the specific example group G6 is terminated by a hydrogen atom.

The term “to form a ring” means forming a ring only with plural atoms of the mother skeleton, or with plural atoms of the mother skeleton and one or more arbitrary atoms in addition. For example, the ring Q_{A} shown in the general formula (TEMP-104), which is formed by bonding R₉₂₁ and R₉₂₂ with each other, is a ring formed from the carbon atom of the anthracene skeleton with which R₉₂₁ is bonded, the carbon atom of the anthracene skeleton with which R₉₂₂ is bonded, and one or more arbitrary atoms. For example, in the case where the ring Q_{A} is formed with R₉₂₁ and R₉₂₂, when a monocyclic unsaturated ring is formed with the carbon atom of the anthracene skeleton with which R₉₂₁ is bonded, the carbon atom of the anthracene skeleton with which R₉₂₂ is bonded, and four carbon atoms, the ring formed with R₉₂₁ and R₉₂₂ is a benzene ring.

Here, the “arbitrary atom” is preferably at least one atom selected from the group consisting of a carbon atom, a nitrogen atom, an oxygen atom, and a sulfur atom, unless otherwise specified in this specification. In the arbitrary atom (for example, a carbon atom or a nitrogen atom), a bond which does not form a ring may be terminated with a hydrogen atom or the like, or may be substituted with “arbitrary substituent” described below. When an arbitrary atom other than a carbon atom is contained, the ring formed is a heterocycle.

The number of “one or more arbitrary atom(s)” constituting a monocycle or a fused ring is preferably 2 or more and 15 or less, more preferably 3 or more and 12 or less, and still more preferably 3 or more and 5 or less, unless otherwise specified in this specification.

The “monocycle” is preferable among the “monocycle” and the “fused ring”, unless otherwise specified in this specification.

The “unsaturated ring” is preferable among the “saturated ring” and the “unsaturated ring”, unless otherwise specified in this specification.

Unless otherwise specified in this specification, the “monocycle” is preferably a benzene ring.

Unless otherwise specified in this specification, the “unsaturated ring” is preferably a benzene ring.

Unless otherwise specified in this specification, when “one or more sets of adjacent two or more” are “bonded with each other to form a substituted or unsubstituted monocycle” or “bonded with each other to form a substituted or unsubstituted fused ring”, this specification, one or more sets of adjacent two or more are preferably bonded with each other to form a substituted or unsubstituted “unsaturated ring” from plural atoms of the mother skeleton and one or more and 15 or less atoms which is at least one kind selected from a carbon atom, a nitrogen atom, an oxygen atom, and a sulfur atom.

The substituent in the case where the above-mentioned “monocycle” or “fused ring” has a substituent is, for example, an “arbitrary substituent” described below. Specific examples of the substituent which the above-mentioned “monocycle” or “fused ring” has include the substituent described above in the “Substituent described in this specification” section.

The substituent in the case where the above-mentioned “saturated ring” or “unsaturated ring” has a substituent is, for example, an “arbitrary substituent” described below. Specific examples of the substituent which the above-mentioned “monocycle” or “fused ring” has include the substituent described above in the “Substituent described in this specification” section.

The foregoing describes the case where “one or more sets of adjacent two or more form a substituted or unsubstituted monocycle by bonding with each other” and the case where “one or more sets of adjacent two or more form a substituted or unsubstituted fused ring by bonding with each other” (the case where “forming a ring by bonding with each other”).

Substituent in the Case of “Substituted or Unsubstituted”

In one embodiment in this specification, the substituent (in this specification, sometimes referred to as an “arbitrary substituent”) in the case of “substituted or unsubstituted” is, for example, a group selected from the group consisting of:

an unsubstituted alkyl group including 1 to 50 carbon atoms,

an unsubstituted alkenyl group including 2 to 50 carbon atoms,

an unsubstituted alkynyl group including 2 to 50 carbon atoms,

an unsubstituted cycloalkyl group including 3 to 50 ring carbon atoms,

—Si(R₉₀₁)(R₉₀₂)(R₉₀₃),

—O—(R₉₀₄),

—S—(R₉₀₅),

—N(R₉₀₆)(R₉₀₇),

a halogen atom, a cyano group, a nitro group,

an unsubstituted aryl group including 6 to 50 ring carbon atoms, and

an unsubstituted heterocyclic group including 5 to 50 ring atoms,

wherein, R₉₀₁ to R₉₀₇ are independently

a hydrogen atom,

a substituted or unsubstituted alkyl group including 1 to 50 carbon atoms,

a substituted or unsubstituted cycloalkyl group including 3 to 50 ring carbon atoms,

a substituted or unsubstituted aryl group including 6 to 50 ring carbon atoms, or

a substituted or unsubstituted heterocyclic group including 5 to 50 ring atoms.

When two or more R₉₀₁'s are present, the two or more R₉₀₁'s may be the same or different.

When two or more R₉₀₂'s are present, the two or more R₉₀₂'s may be the same or different.

When two or more R₉₀₃'s are present, the two or more R₉₀₃'s may be the same or different.

When two or more R₉₀₄'s are present, the two or more R₉₀₄'s may be the same or different.

When two or more R₉₀₅'s are present, the two or more R₉₀₅'s may be the same or different.

When two or more R₉₀₆'S are present, the two or more R₉₀₆'S may be the same or different.

When two or more R₉₀₇s are present, the two or more R₉₀₇s may be the same or different.

In one embodiment, the substituent in the case of “substituted or unsubstituted” is a group selected from the group consisting of:

an alkyl group including 1 to 50 carbon atoms,

an aryl group including 6 to 50 ring carbon atoms, and

a heterocyclic group including 5 to 50 ring atoms.

In one embodiment, the substituent in the case of “substituted or unsubstituted” is a group selected from the group consisting of:

an alkyl group including 1 to 18 carbon atoms,

an aryl group including 6 to 18 ring carbon atoms, and

a heterocyclic group including 5 to 18 ring atoms.

Specific examples of each of the arbitrary substituents include specific examples of substituent described in the section “Substituent described in this specification” above.

Unless otherwise specified in this specification, adjacent arbitrary substituents may form a “saturated ring” or an “unsaturated ring”, preferably form a substituted or unsubstituted saturated 5-membered ring, a substituted or unsubstituted saturated 6-membered ring, a substituted or unsubstituted unsaturated 5-membered ring, or a substituted or unsubstituted unsaturated 6-membered ring, more preferably form a benzene ring.

Unless otherwise specified in this specification, the arbitrary substituent may further have a substituent. The substituent which the arbitrary substituent further has is the same as that of the above-mentioned arbitrary substituent.

In this specification, the numerical range represented by “AA to BB” means the range including the numerical value AA described on the front side of “AA to BB” as the lower limit and the numerical value BB described on the rear side of “AA to BB” as the upper limit.

### [Organic EL Device]

An organic EL device according to an aspect of the invention has a cathode, an anode, an emitting layer disposed between the cathode and the anode, and a first layer disposed between the emitting layer and the cathode, wherein the emitting layer contains a host compound, and the first layer contains a first compound and a second compound.

The organic EL device according to an aspect of the invention satisfies the following Conditions 1 and 2.

### (Condition 1)

the electron affinity Af_{H} of the host compound and the electron affinity Af_{ETA} of the first compound satisfy the following expressions (1-1) and (1-2):

Af_{H}<Af_{ETA} (1-1)

|Af_{H}−Af_{ETA}|≤0.10 (1-2)

### (Condition 2)

the electron affinity Af_{H} of the host compound and the electron affinity Af_{ETB} of the second compound satisfy the following expressions (2-1) and (2-2):

Af_{H}>Af_{ETB} (2-1)

|Af_{H}−Af_{ETB}≡1≤0.10 (2-2)

The organic EL device according to an aspect of the invention has the above-described configuration, whereby excellent carrier balance in the electron-transporting zone can be realized, pool of electrons at the interface between the emitting layer and the electron-transporting zone can be suppressed, and higher device performance can be realized. As a specific effect, an organic EL device having high luminous efficiency and low driving voltage can be realized.

Although it is obvious from Conditions 1 and 2, the first compound and the second compound are different compounds.

Hereinafter, each configuration of the organic EL device according to an aspect of the invention will be described.

### (Condition 1)

As the expressions (1-1) and (1-2) show, as the first compound, a compound having an electron affinity Af_{ETA} higher than the electron affinity Af_{H} of the host compound and having a difference in their electron affinities of 0.10 or less is used. The electron affinity is measured by a method described in Examples.

The absolute value of difference between Af_{ETA} and Af_{H} may be 0.09 or less. This can also be written with the following expression (1-2-1).

|Af_{H}−Af_{ETA}|≤0.09 (1-2-1)

### (Condition 2)

As the expressions (2-1) and (2-2) show, as the second compound, a compound having an electron affinity Af_{ETB} lower than the electron affinity Af_{H} of the host compound and having a difference in their electron affinities of 0.10 or less is used.

The absolute value of difference between Af_{ETB} and Af_{H} may be 0.09 or less. This can also be written with the following expression (2-2-1).

|Af_{H}−Af_{ETB}|≤0.09 (2-2-1)

The effect of the organic EL device according to an aspect of the invention can be obtained, as described with Conditions 1 and 2, by the respective relative values between the electron affinity of the host compound and the electron affinity of the first compound or the second compound being within a specific range. Therefore, although there is no particular limitation on the actual electron affinity value, for example, Af_{H} may be within a range of 1.9 to 2.2, Af_{ETA} may be within a range of 2.0 to 2.3, and Af_{ETB} may be within a range of 1.8 to 2.1.

### (First Compound)

The first compound is not particularly limited as long as the above Conditions are satisfied. The first compound may contain a deuterium atom or may not contain a deuterium atom.

As the first compound, for example, a compound represented by the following formula (1) can be used.

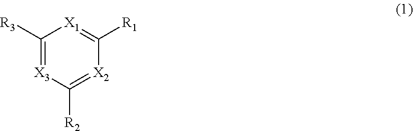

wherein in the formula (1),

X₁ to X₃ are independently CR₄ or N;

at least one of X₁ to X₃ is N;

R₄ is a hydrogen atom or a substituent R;

when two or more R₄'s are present, the two or more R₄'s may be the same as or different from each other,

R₁ to R₃ are independently a hydrogen atom or a substituent R;

the substituent R is

a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms, —Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

when two or more of the substituent R's are present, the two or more of the substituent R's may be the same as or different from each other, and

R₉₀₁ to R₉₀₇ are independently

a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and

when two or more of each of R₉₀₁ to R₉₀₇ are present, the two or more of each of R₉₀₁ to R₉₀₇ may be the same as or different from each other.

In one embodiment, the compound represented by the formula (1) is a compound represented by the following formula (11):

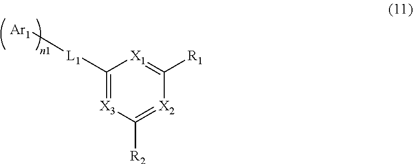

wherein in the formula (11),

X₁ to X₃, R₁, and R₂ are as defined in the formula (1);

L₁ is

a single bond,
a substituted or unsubstituted aromatic hydrocarbon group including 6 to 50 ring carbon atoms, or
a substituted or unsubstituted heterocyclic group including 5 to 50 ring atoms;

Ar₁ is

a substituted or unsubstituted aryl group including 6 to 50 ring carbon atoms, or
a substituted or unsubstituted monovalent heterocyclic group including 5 to 50 ring atoms;

n1 is an integer of 1 to 3; when n1 is 2 or more, two or more Ar₁'s may be the same as or different from each other.

In the formula (11), n1 of Ar₁'s are respectively bonded with L₁. For example, when n1 is 2, L₁ is a substituted or unsubstituted trivalent aromatic hydrocarbon group including 6 to 50 ring carbon atoms or a substituted or unsubstituted trivalent heterocyclic group including 5 to 50 ring atoms, and two Ar₁'s are respectively bonded with L₁.

In one embodiment, An in the formula (11) is a group represented by the following formula (12):

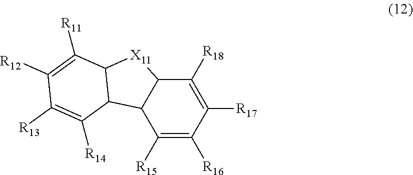

wherein in the formula (12),

X₁₁ is O, S, N(R₂₁), or C(R₂₂)(R₂₃);

one of R₁₁ to R₁₈ and R₂₁ to R₂₃ is a single bond which bonds with L₁;

one or more sets of adjacent two or more of R₁₁ to R₁₈ which are not the single bond which bonds with L₁ form a substituted or unsubstituted, saturated or unsaturated ring by bonding with each other, or do not form a substituted or unsubstituted, saturated or unsaturated ring;

R₁₁ to R₁₈ which are not the single bond which bonds with L₁ and which do not form the substituted or unsubstituted, saturated or unsaturated ring and R₂₁ to R₂₃ which are not the single bond which bonds with L₁ are independently a hydrogen atom or a substituent R; and

the substituent R is as defined in the formula (1).

In one embodiment, X₁₁ in the formula (12) is O or S.

In one embodiment, X₁₁ in the formula (12) is N(R₂₁).

In one embodiment, the compound represented by the formula (1) is a compound represented by the following formula (21):

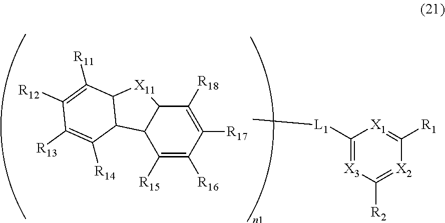

wherein in the formula (21),

X₁ to X₃, R₁, and R₂ are as defined in the formula (1);

L₁ is as defined in the formula (11);

X₁₂ is O or S;

one of R₁₁ to R₁₈ is a single bond which bonds with L₁;

one or more sets of adjacent two or more of R₁₁ to R₁₈ which are not the single bond which bonds with L₁ form a substituted or unsubstituted, saturated or unsaturated ring by bonding with each other, or do not form a substituted or unsubstituted, saturated or unsaturated ring;

R₁₁ to R₁₈ which are not the single bond which bonds with L₁ and which do not form the substituted or unsubstituted, saturated or unsaturated ring are independently a hydrogen atom or a substituent R;

n1 is an integer of 1 to 3; when n1 is 2 or more, two or more of the structures in parentheses may be the same as or different from each other, and

the substituent R is as defined in the formula (1).

In one embodiment, the compound represented by the formula (1) is a compound represented by the following formula (22):

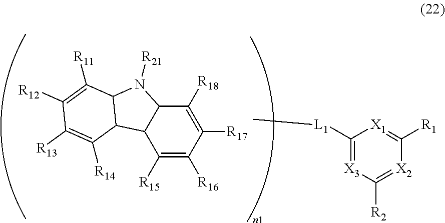

wherein in the formula (22),

X₁ to X₃, Ru, R₂, L₁, R₁₁ to R₁₈ and n1 are as defined in the formula (21);

R₂₁ is a hydrogen atom or a substituent R; and

the substituent R is as defined in the formula (1).

In one embodiment, L₁ is

a single bond, or
an unsubstituted arylene group including 6 to 50 ring carbon atoms; and

the substituent R is

an unsubstituted alkyl group including 1 to 50 carbon atoms,
an unsubstituted alkenyl group including 2 to 50 carbon atoms,
an unsubstituted alkynyl group including 2 to 50 carbon atoms,
an unsubstituted cycloalkyl group including 3 to 50 ring carbon atoms,
—Si(R₉₁₁)(R₉₁₂)(R₉₁₃),

### —O—(R₉₁₄),

### —S—(R₉₁₅),

—N(R₉₁₆)(R₉₁₇),
a halogen atom, a cyano group, a nitro group, or
an unsubstituted aryl group including 6 to 50 ring carbon atoms; and

R₉₁₁ to R₉₁₇ are independently

a hydrogen atom,
an unsubstituted alkyl group including 1 to 50 carbon atoms,
an unsubstituted cycloalkyl group having 3 to 50 ring carbon atoms, or
an unsubstituted aryl group including 6 to 50 ring carbon atoms.

In one embodiment, two of X₁ to X₃ are N's.

As described in [Definition], a term “hydrogen atom” used in this specification includes a protium atom, a deuterium atom, and a tritium atom. Accordingly, the first compound may have a naturally derived deuterium atom.

Further, a deuterium atom may be intentionally introduced into the first compound by replacing part or all of the raw material compounds with their deuterated compounds. Accordingly, in one embodiment, the first compound has at least one deuterium atom. In other words, the compound of this embodiment may be a compound represented by the formula (1), wherein at least one of hydrogen atoms possessed by the compound is a deuterium atom.

In one embodiment, one or more of R₁ to R₄ which are hydrogen atoms, and hydrogen atoms possessed by R₁ to R₄ which are the substituent R's are deuterium atoms.

The deuteration rate of a compound depends on the deuteration rate of its raw material compounds used. Even if a raw material having a predetermined deuteration rate is used, it may be contain a naturally derived protium isotope therein at a certain ratio. Therefore, the deuteration rate is obtained by taking a ratio of small amount of the naturally derived isotope into consideration, relative to the ratio obtained by merely counting the number of deuterium atoms in the chemical formula.

In one embodiment, the deuteration rate of the first compound is, for example, 1% or more, 3% or more, 5% or more, 10% or more, or 50% or more.

The compound represented by the formula (1) can be synthesized by using a known alternative reaction or raw material tailored to the target compound.

Specific examples of the first compound will be described below, but are illustrative only, and the first compound is not limited to the following specific examples.

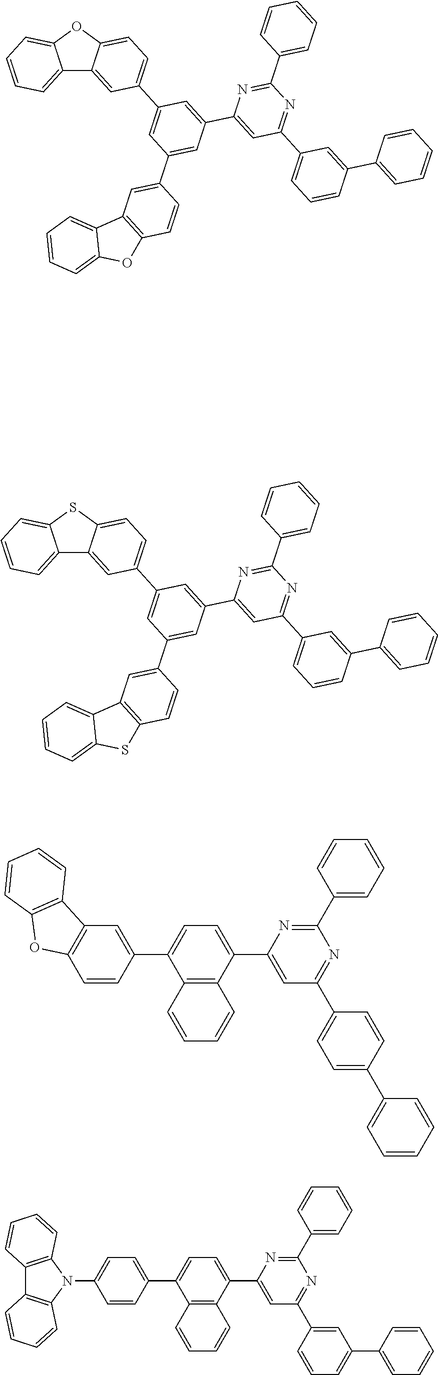 [SMILES: c1ccc(-c2cccc(-c3cc(-c4cc(-c5ccc6oc7ccccc7c6c5)cc(-c5ccc6oc7ccccc7c6c5)c4)nc(-c4ccccc4)n3)c2)cc1 ; c1ccc(-c2cccc(-c3cc(-c4cc(-c5ccc6sc7ccccc7c6c5)cc(-c5ccc6sc7ccccc7c6c5)c4)nc(-c4ccccc4)n3)c2)cc1 ; c1ccc(-c2ccc(-c3cc(-c4ccc(-c5ccc6oc7ccccc7c6c5)c5ccccc45)nc(-c4ccccc4)n3)cc2)cc1 ; c1ccc(-c2cccc(-c3cc(-c4ccc(-c5ccc(-n6c7ccccc7c7ccccc76)cc5)c5ccccc45)nc(-c4ccccc4)n3)c2)cc1]

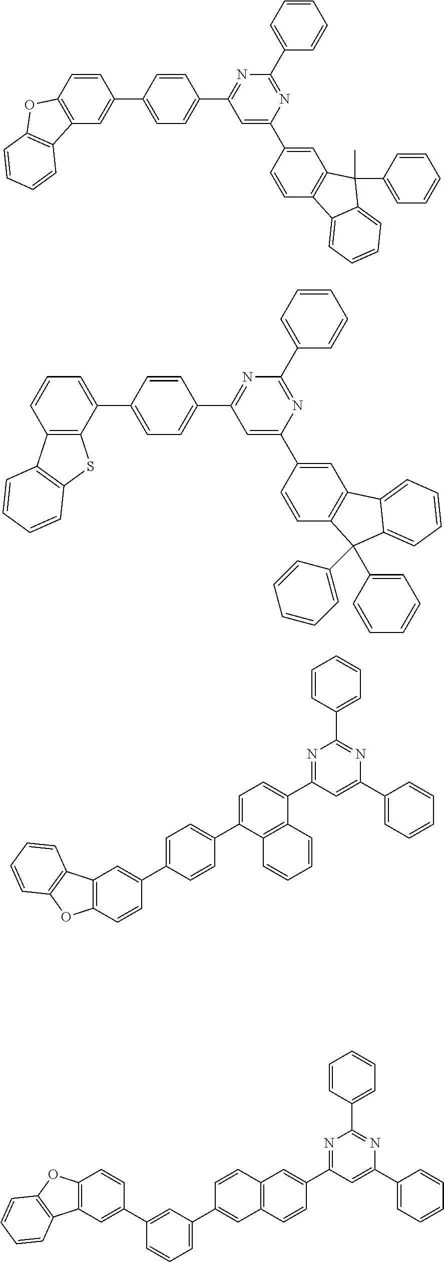

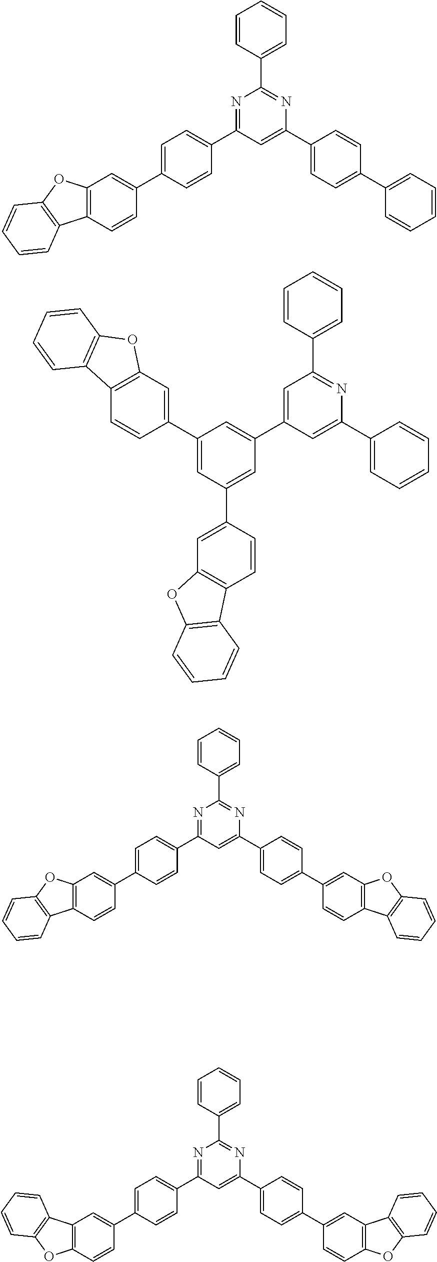 [SMILES: c1ccc(-c2ccc(-c3cc(-c4ccc(-c5ccc6c(c5)oc5ccccc56)cc4)nc(-c4ccccc4)n3)cc2)cc1 ; c1ccc(-c2cc(-c3cc(-c4ccc5c(c4)oc4ccccc45)cc(-c4ccc5c(c4)oc4ccccc45)c3)cc(-c3ccccc3)n2)cc1 ; c1ccc(-c2nc(-c3ccc(-c4ccc5c(c4)oc4ccccc45)cc3)cc(-c3ccc(-c4ccc5c(c4)oc4ccccc45)cc3)n2)cc1 ; c1ccc(-c2nc(-c3ccc(-c4ccc5oc6ccccc6c5c4)cc3)cc(-c3ccc(-c4ccc5oc6ccccc6c5c4)cc3)n2)cc1]

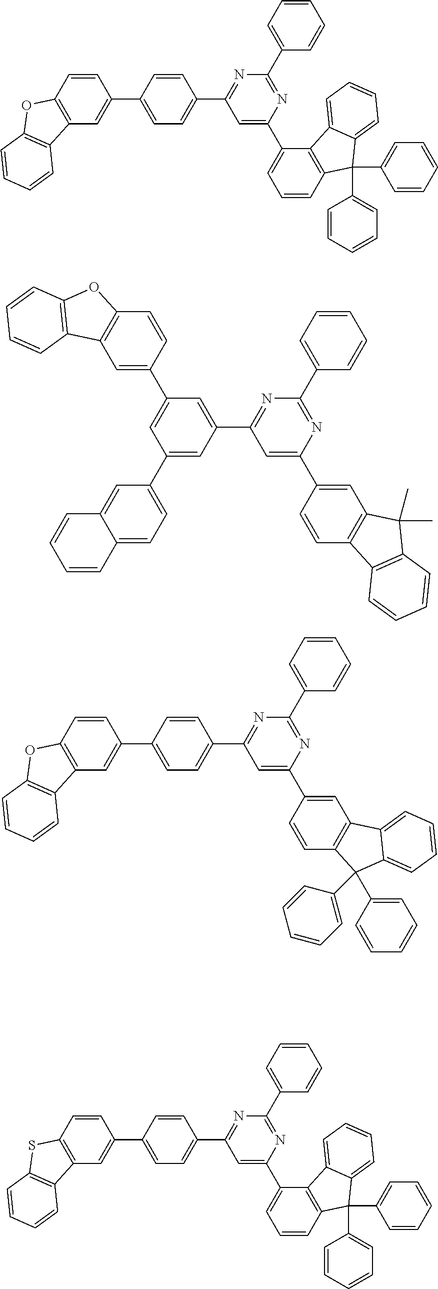 [SMILES: c1ccc(-c2nc(-c3ccc(-c4ccc5oc6ccccc6c5c4)cc3)cc(-c3cccc4c3-c3ccccc3C4(c3ccccc3)c3ccccc3)n2)cc1 ; CC1(C)c2ccccc2-c2ccc(-c3cc(-c4cc(-c5ccc6ccccc6c5)cc(-c5ccc6oc7ccccc7c6c5)c4)nc(-c4ccccc4)n3)cc21 ; c1ccc(-c2nc(-c3ccc(-c4ccc5oc6ccccc6c5c4)cc3)cc(-c3ccc4c(c3)-c3ccccc3C4(c3ccccc3)c3ccccc3)n2)cc1 ; c1ccc(-c2nc(-c3ccc(-c4ccc5sc6ccccc6c5c4)cc3)cc(-c3cccc4c3-c3ccccc3C4(c3ccccc3)c3ccccc3)n2)cc1]

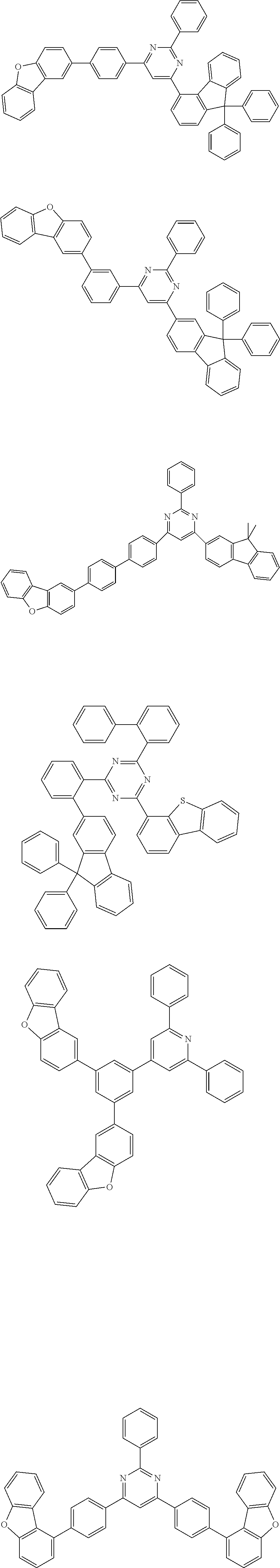

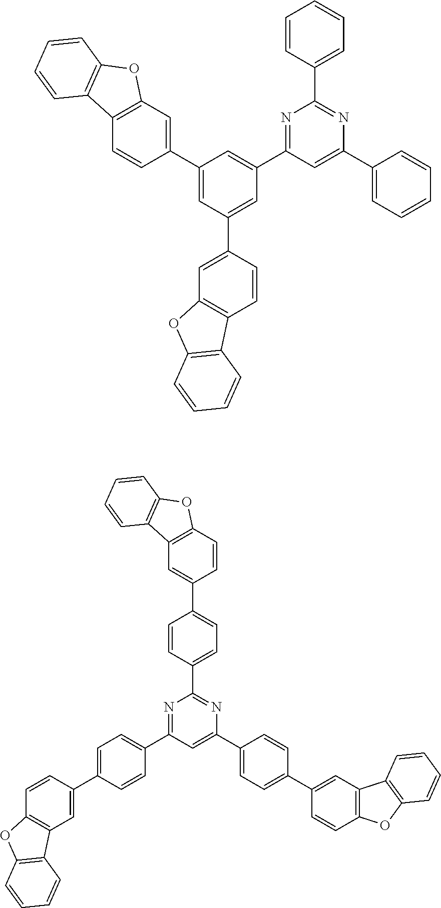 [SMILES: c1ccc(-c2cc(-c3cc(-c4ccc5c(c4)oc4ccccc45)cc(-c4ccc5c(c4)oc4ccccc45)c3)nc(-c3ccccc3)n2)cc1 ; c1ccc2c(c1)oc1ccc(-c3ccc(-c4cc(-c5ccc(-c6ccc7oc8ccccc8c7c6)cc5)nc(-c5ccc(-c6ccc7oc8ccccc8c7c6)cc5)n4)cc3)cc12]

### (Second Compound)

The second compound is not particularly limited as long as the above Conditions are satisfied. The second compound may contain a deuterium atom or may not contain a deuterium atom.

As the second compound, for example, a compound represented by the following formula (51) can be used.

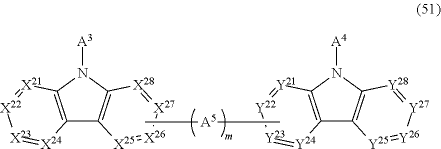

wherein in the formula (51),

A³ and A⁴ are independently

a substituted or unsubstituted aryl group including 6 to 30 ring carbon atoms, or
a substituted or unsubstituted monovalent heterocyclic group including 5 to 30 ring atoms;

A⁵ is

a substituted or unsubstituted monocyclic hydrocarbon group including 3 to 6 ring carbon atoms, or
a substituted or unsubstituted monocyclic heterocyclic group including 3 to 6 ring atoms;

m is an integer of 0 to 3;

when m is 0, (A⁵)ₘ represents a single bond;

one of X²⁵ to X²⁸ is a carbon atom which is bonded with A⁵;

X²¹ to X²⁴, and X²⁵ to X²⁸ which are not the carbon atom which is bonded with A⁵ are independently N or CR^{a};

one of Y²¹ to Y²⁴ is a carbon atom which is bonded with A⁵;

Y²⁵ to Y²⁸, and Y²¹ to Y²⁴ which are not the carbon atom which is bonded with A⁵ are independently N or CR^{a};

one or more sets of adjacent two or more R^{a}'s form a substituted or unsubstituted, saturated or unsaturated ring by bonding with each other, or do not form the substituted or unsubstituted, saturated or unsaturated ring;

R^{a}'s which do not form the substituted or unsubstituted, saturated or unsaturated ring are independently a hydrogen atom or a substituent R;

the substituent R is selected from the group consisting of

a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇)
a halogen atom, a cyano group, a nitro group,
a substituted or unsubstituted aryl group including 6 to 50 ring carbon atoms, and
a substituted or unsubstituted monovalent heterocyclic group including 5 to 50 ring atoms;

R₉₀₁ to R₉₀₇ are independently

a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and

when two or more of each of R₉₀₁ to R₉₀₇ are present, the two or more of each of R₉₀₁ to R₉₀₇ may be the same as or different from each other,

when two or more of the substituent R's are present, the two or more of the substituent R's may be the same as or different from each other, and

provided that the compound represented by the formula (51) satisfies either or both of the following Conditions (i) and (ii);

Condition (i): at least one of A³ and A⁴ is
a substituted aryl group including 6 to 30 ring carbon atoms having a cyano group, or
a monovalent heterocyclic group including 5 to 30 ring atoms that has a cyano group; and
Condition (ii): at least one of X²¹ to X²⁸ and Y²¹ to Y²⁸ is CR^{a}, and at least one R^{a} among the at least one CR^{a} is
a substituted aryl group including 6 to 30 ring carbon atoms that has a cyano group, or
a monovalent heterocyclic group including 5 to 30 ring atoms that has a cyano group.

In one embodiment, m in the formula (51) is 0.

In one embodiment, the compound represented by the formula (51) is a compound represented by the following formula (61), (62), or (63):

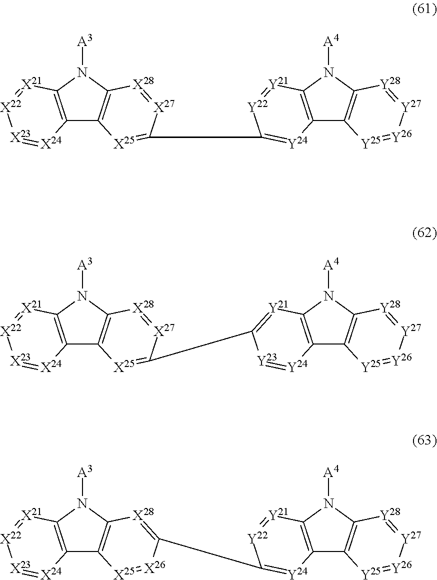

wherein in the formulas (61) to (63), X²¹ to X²⁸, Y²¹ to Y²⁸, A³, and A⁴ are as defined in the formula (51).

In one embodiment, the compound represented by the formula (51) is a compound represented by the following formula (71):

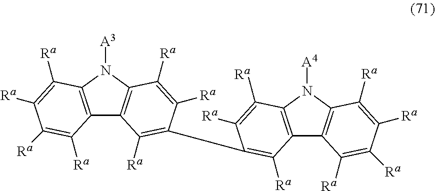

wherein in the formula (71), R^{a}, A³, and A⁴ are as defined in the formula (51).

In one embodiment, the compound represented by the formula (51) is a compound represented by the following formula (72):

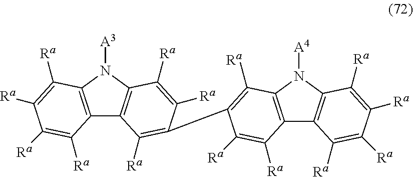

wherein in the formula (72), R^{a}, A³, and A⁴ are as defined in the formula (51).

In one embodiment, the compound represented by the formula (51) is a compound represented by the following formula (73):

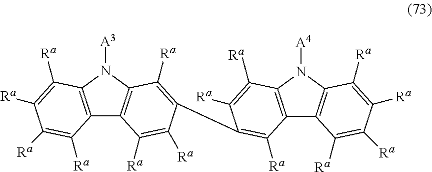

wherein in the formula (73), R^{a}, A³, and A⁴ are as defined in the formula (51).

In one embodiment, the substituted aryl group including 6 to 30 ring carbon atoms that has a cyano group in the Conditions (i) and (ii) is a group selected from groups represented by each of the following formulas (2-1) to (2-5):

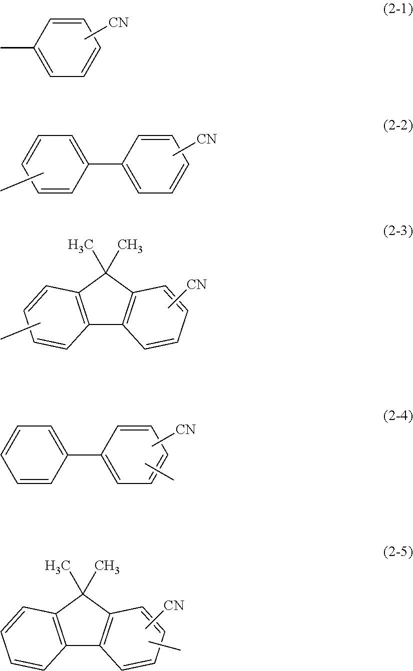

In one embodiment, the substituted monovalent heterocyclic group including 5 to 30 ring atoms that has a cyano group in the Conditions (i) and (ii) is a group selected from groups represented by each of the following formulas (2-6) to (2-9):

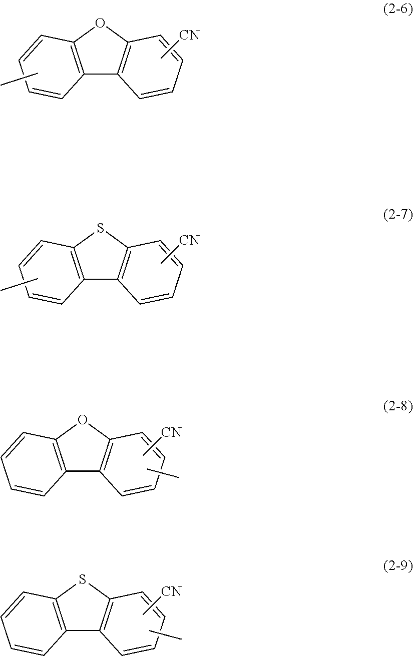

In one embodiment, the compound represented by the formula (51) satisfies the Condition (i) but not the Condition (ii).

In one embodiment, the compound represented by the formula (51) satisfies either or both of the following Conditions (ia) and (iia):

Condition (ia): at least one of A³ and A⁴ is
a substituted aryl group including 6 to 30 ring carbon atoms that has a cyano group but no other substituent, or
a monovalent heterocyclic group including 5 to 30 ring atoms that has a cyano group but no other substituent;
Condition (iia): at least one of X²¹ to X²⁸ and Y²¹ to Y²⁸ is CR^{a} and at least one R^{a} among the at least one CR^{a} is
a substituted aryl group including 6 to 30 ring carbon atoms that has a cyano group but no other substituent, or a monovalent heterocyclic group including 5 to 30 ring atoms that has a cyano group but no other substituent.

In one embodiment, the compound represented by the formula (51)

satisfies the Condition (i) or (ia) but not the Conditions (ii) and (iia),

X²¹ to X²⁴, X²⁵ to X²⁸ which are not the carbon atom which is bonded with A⁵, Y²⁵ to Y²⁸, and Y²¹ to Y²⁴ which are not the carbon atom which is bonded with A⁵ are all CR^{a}'s;

m is 0; and

A³ and A⁴ are independently a substituted or unsubstituted aryl group including 6 to 12 ring carbon atoms.

As described in [Definition], a term “hydrogen atom” used in this specification includes a protium atom, a deuterium atom, and a tritium atom. Accordingly, the second compound may have a naturally derived deuterium atom.

Further, a deuterium atom may be intentionally introduced into the second compound by replacing part or all of the raw material compounds with their deuterated compounds. Accordingly, in one embodiment, the second compound has at least one deuterium atom. In other words, the compound of this embodiment may be a compound represented by the formula (51), wherein at least one of hydrogen atoms possessed by the compound is a deuterium atom.

In one embodiment, one or more of

hydrogen atoms possessed by A³ to A⁵,
hydrogen atoms possessed by the substituted or unsubstituted, saturated or unsaturated ring formed by
bonding one or more sets of adjacent two or more R^{a}'s with each other,
R^{a} which is a hydrogen atom, and
hydrogen atoms possessed by R^{a} which is a substituent R
are deuterium atoms.

In one embodiment, the deuteration rate of the second compound is, for example, 1% or more, 3% or more, 5% or more, 10% or more, or 50% or more.

The compound represented by the formula (51) can be synthesized by using a known alternative reaction or raw material tailored to the target compound.

Specific examples of the second compound will be described below, but are illustrative only, and the second compound is not limited to the following specific examples.

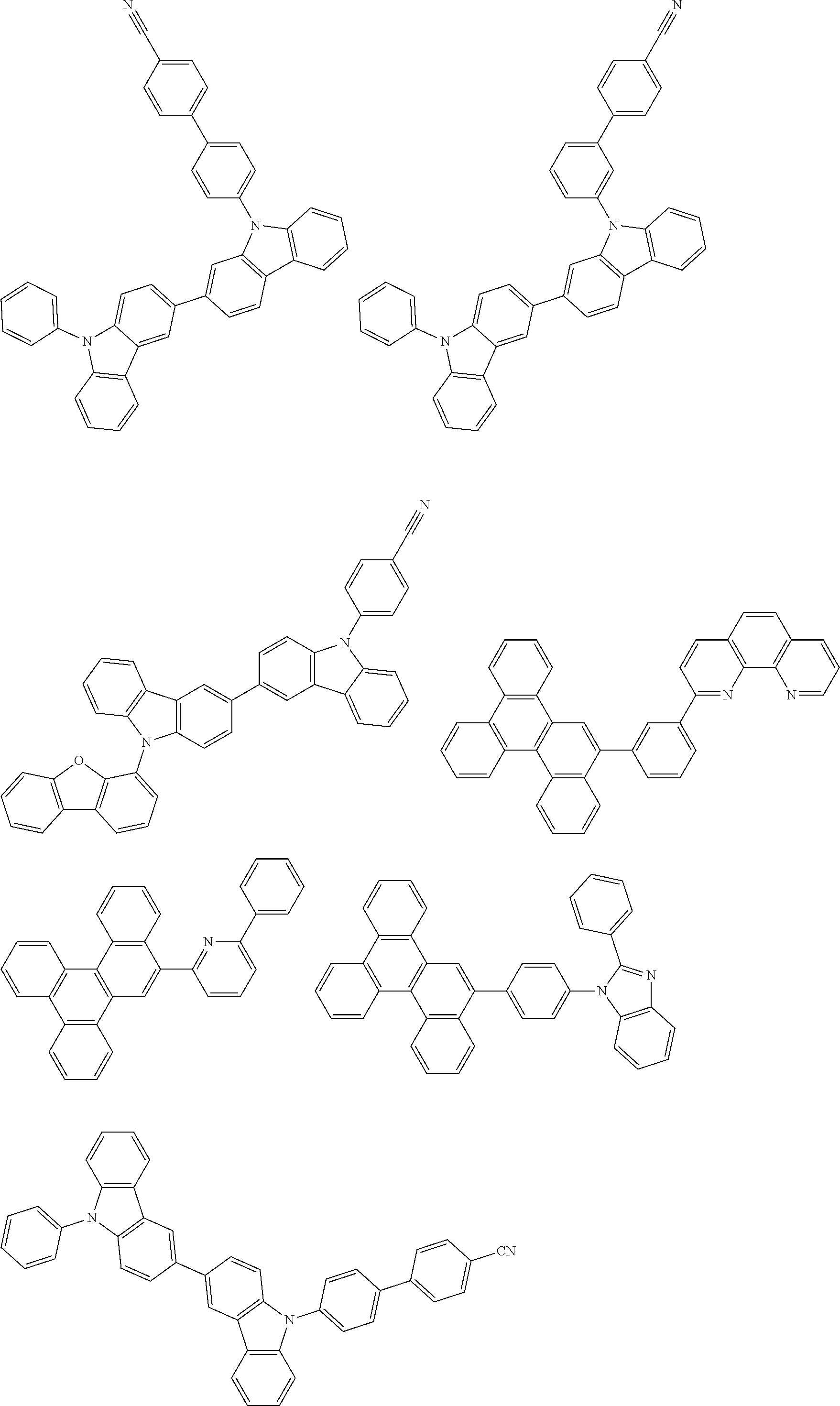

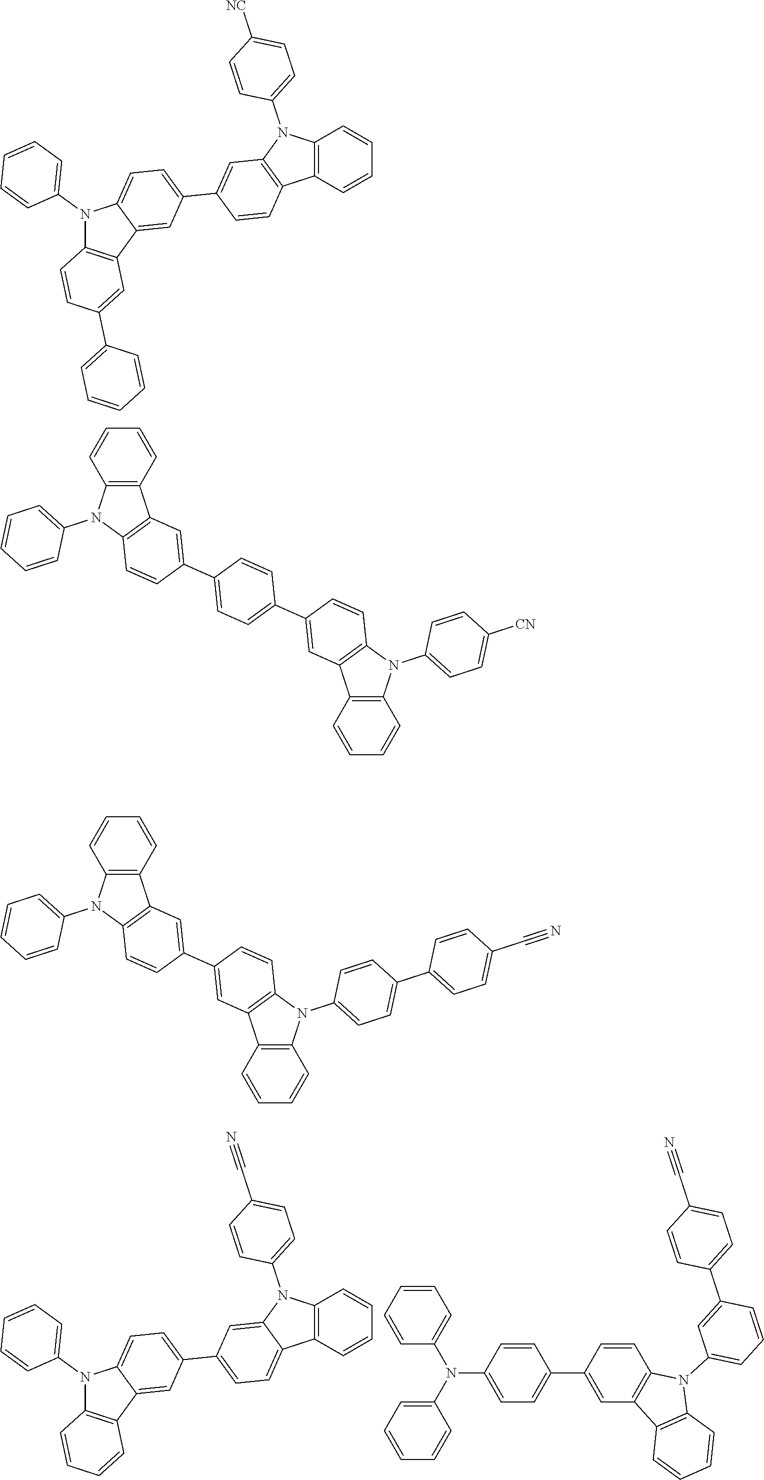

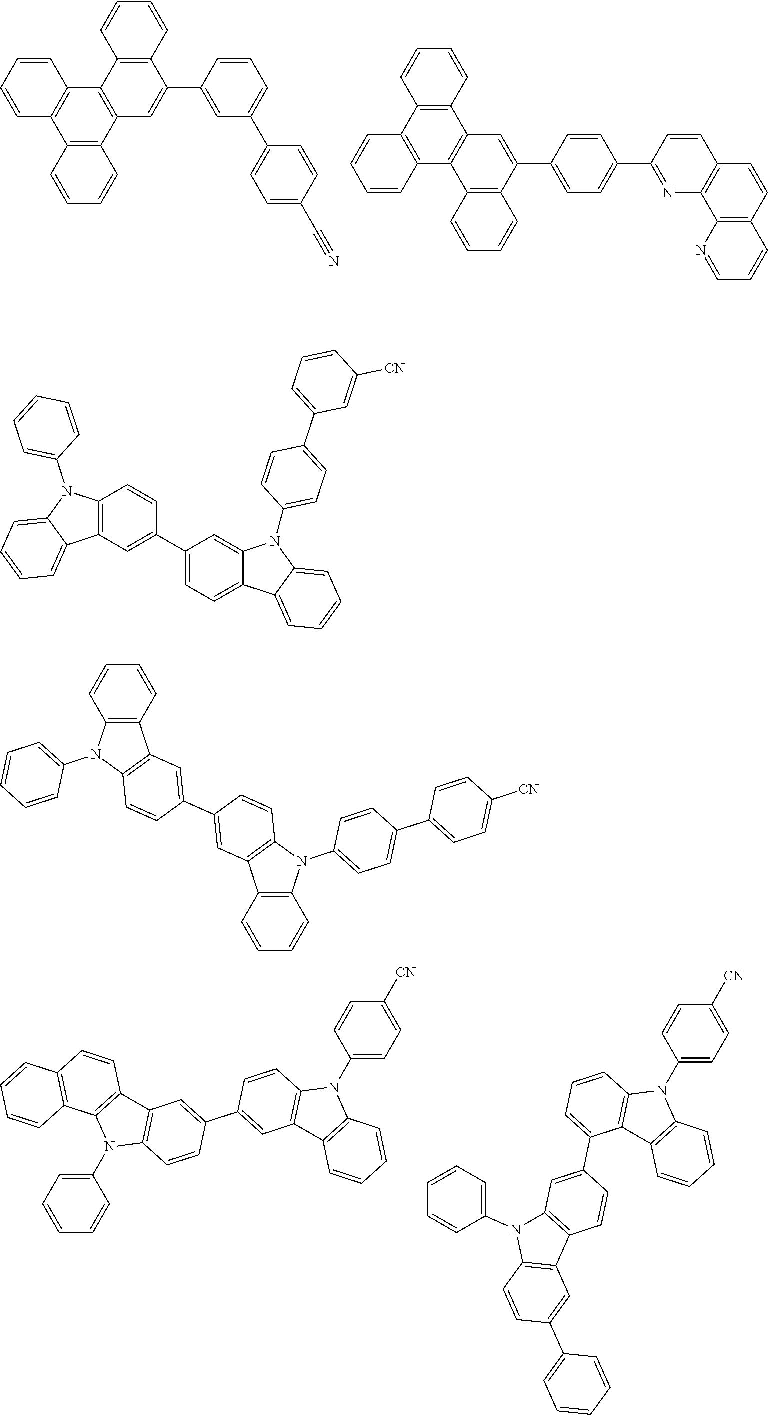

### (Combination of First Compound and Second Compound)

The combination of the first compound and the second compound is not particularly limited as long as the above-described Conditions 1 and 2 described above are satisfied, and the first compound and the second compound can be used in an appropriate combination.

Some examples of the combination of the first compound and the second compound are shown below, but the combination is not limited thereto.

Combination 1

The first compound is 1-1 and the second compound is 2-1.

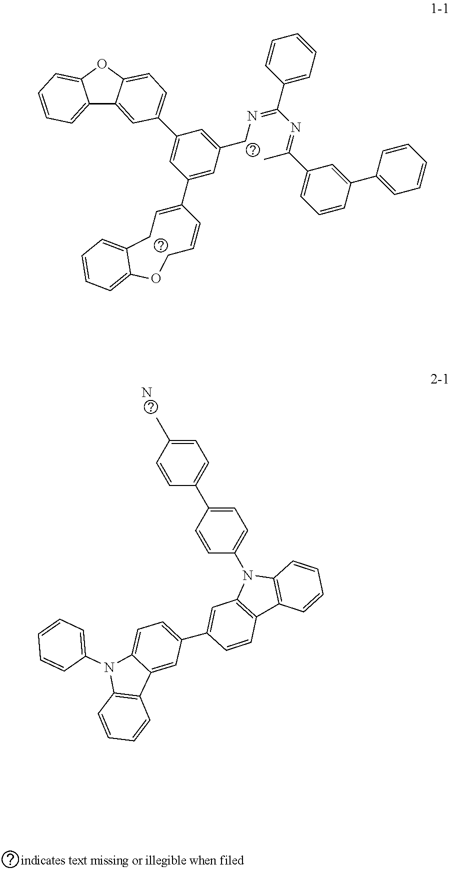

Combination 2

The first compound is 1-2 and the second compound is 2-1.

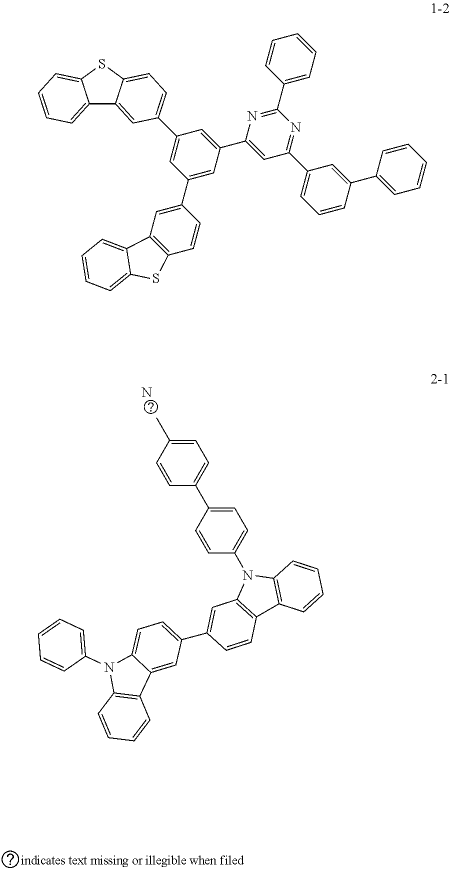

Combination 3

The first compound is 1-3 and the second compound is 2-1.

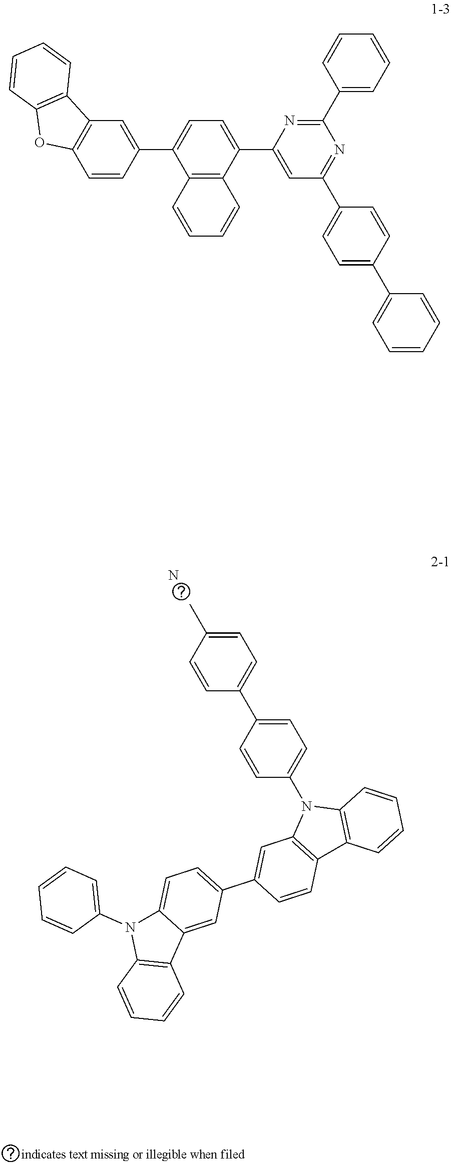

Combination 4

The first compound is 1-4 and the second compound is 2-1.

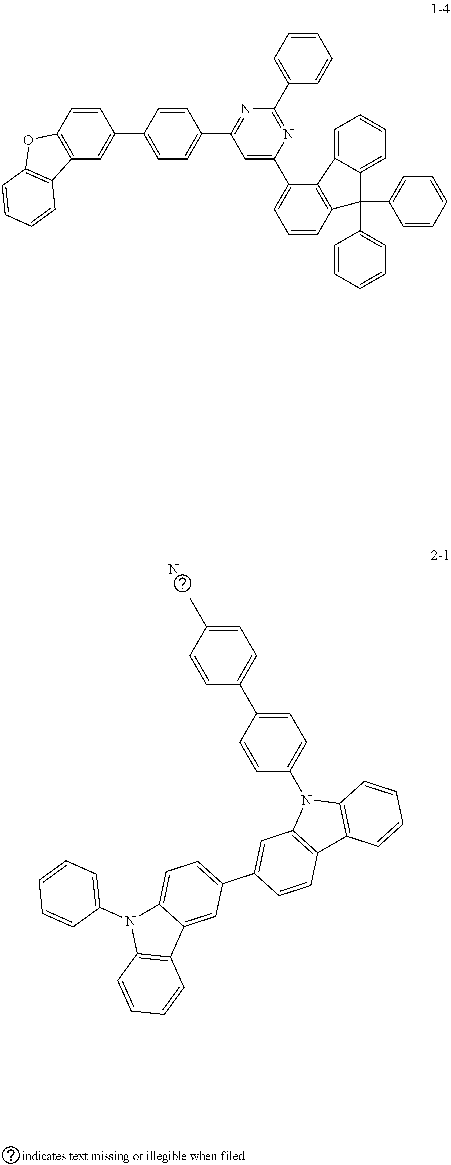

Combination 5

The first compound is 1-5 and the second compound is 2-1.

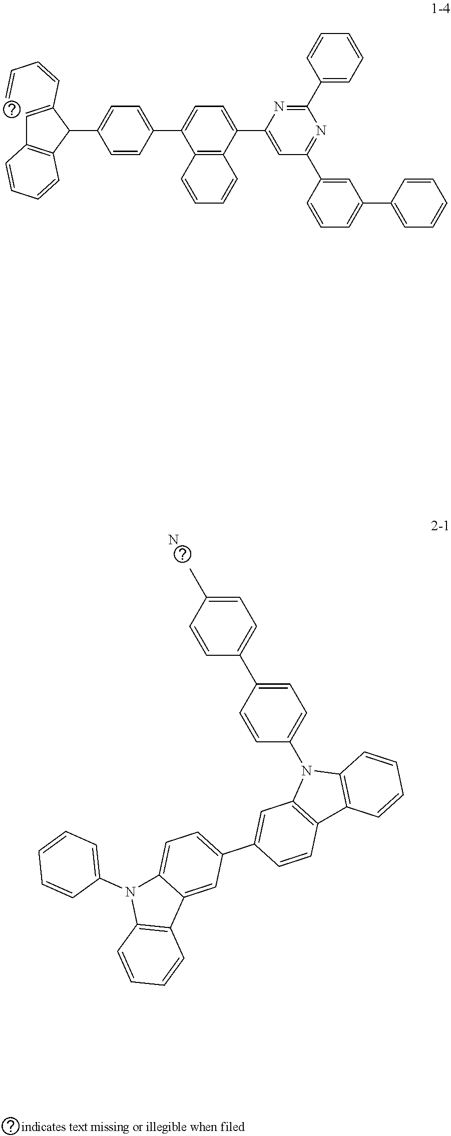

Combination 6

The first compound is 1-6 and the second compound is 2-1.

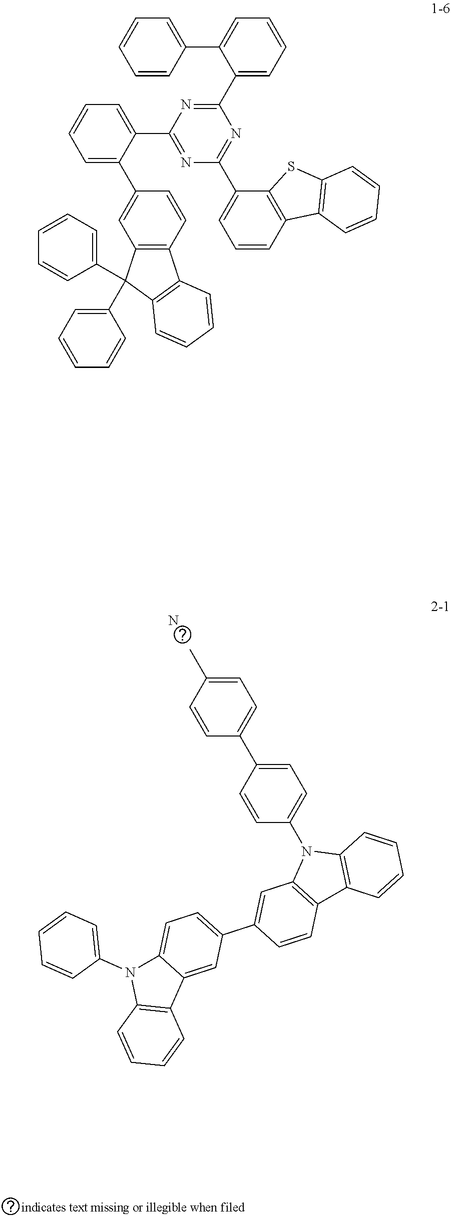

Combination 7

The first compound is 1-7 and the second compound is 2-1.

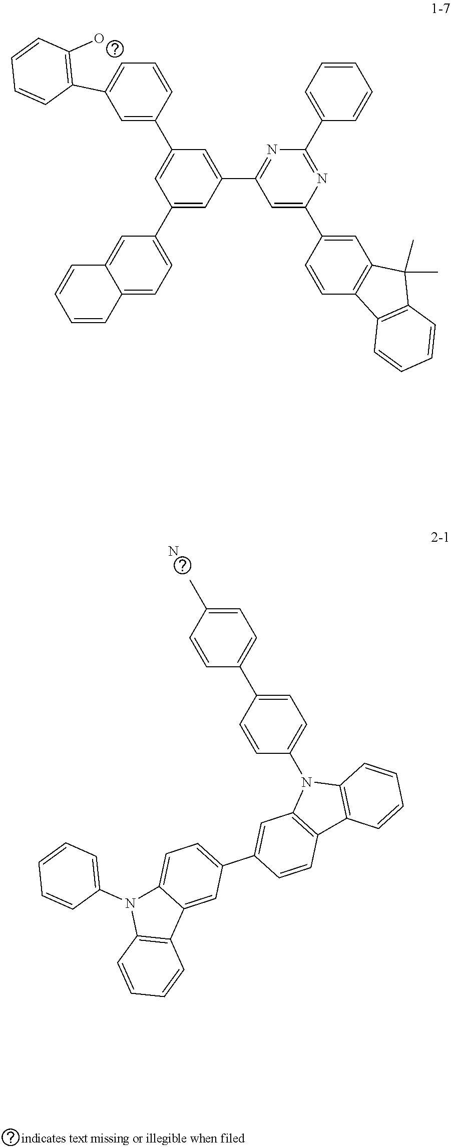

Combination 8

The first compound is 1-8 and the second compound is 2-1.

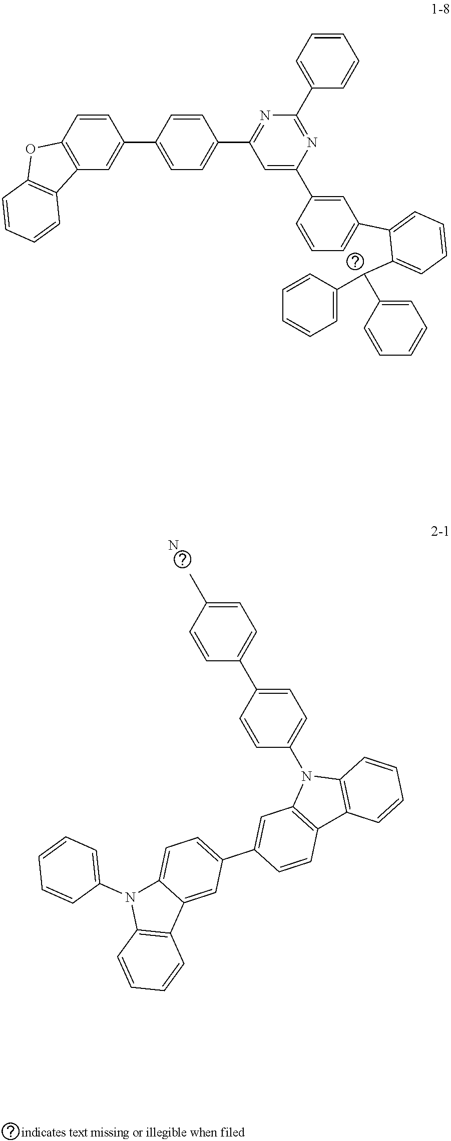

Combination 9

The first compound is 1-1 and the second compound is 2-2.

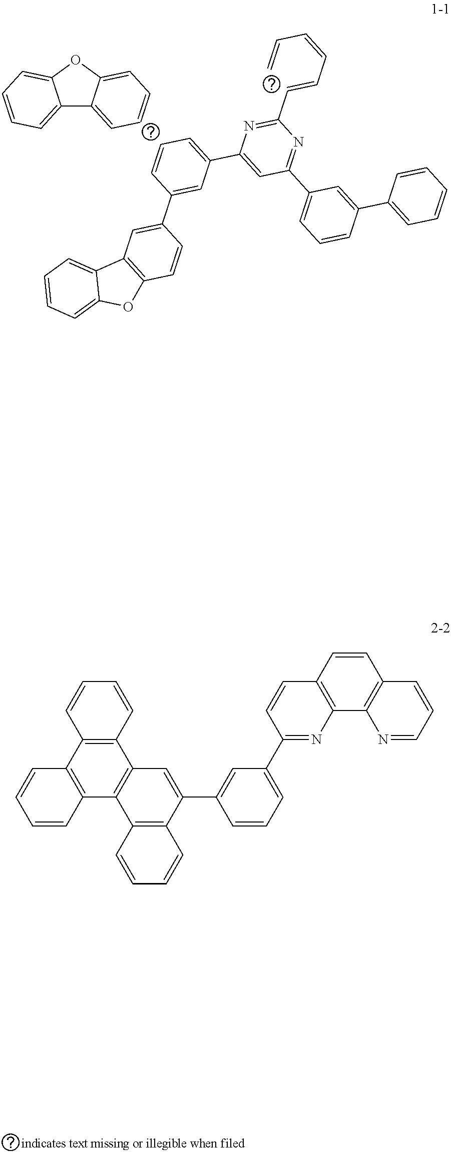

Combination 10

The first compound is 1-2 and the second compound is 2-2.

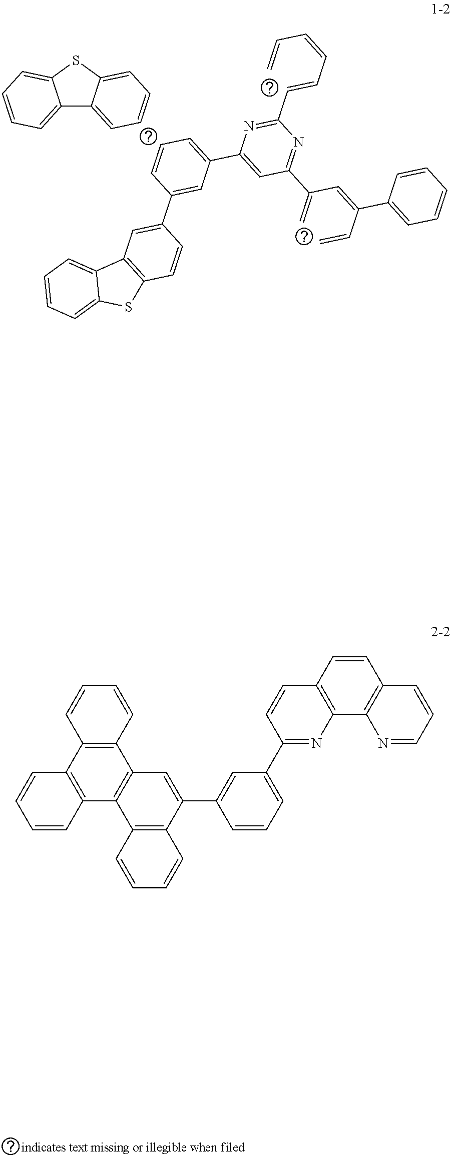

Combination 11

The first compound is 1-3 and the second compound is 2-2.

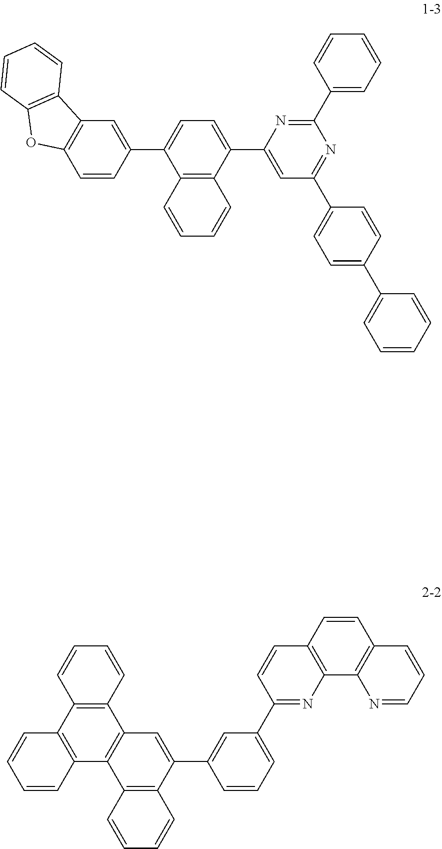 [SMILES: c1ccc(-c2ccc(-c3cc(-c4ccc(-c5ccc6oc7ccccc7c6c5)c5ccccc45)nc(-c4ccccc4)n3)cc2)cc1 ; c1cc(-c2ccc3ccc4cccnc4c3n2)cc(-c2cc3c4ccccc4c4ccccc4c3c3ccccc23)c1]

Combination 12

The first compound is 1-4 and the second compound is 2-2.

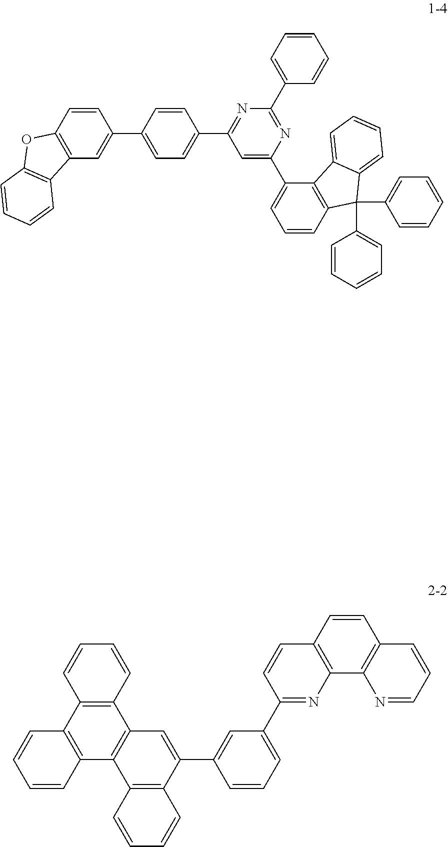 [SMILES: c1ccc(-c2nc(-c3ccc(-c4ccc5oc6ccccc6c5c4)cc3)cc(-c3cccc4c3-c3ccccc3C4(c3ccccc3)c3ccccc3)n2)cc1 ; c1cc(-c2ccc3ccc4cccnc4c3n2)cc(-c2cc3c4ccccc4c4ccccc4c3c3ccccc23)c1]

Combination 13

The first compound is 1-5 and the second compound is 2-2.

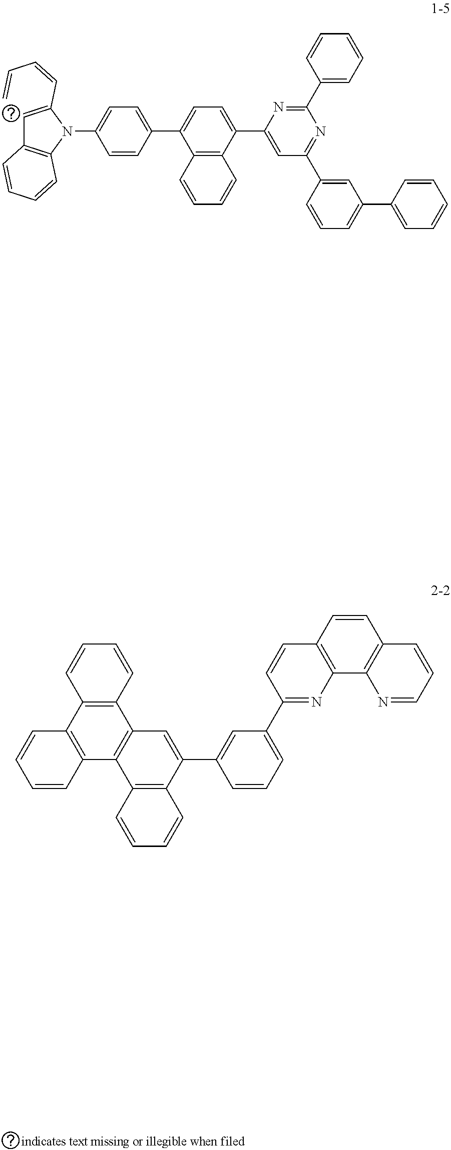 [SMILES: C=C/C=C\c1cc2ccccc2n1-c1ccc(-c2ccc(-c3cc(-c4cccc(-c5ccccc5)c4)nc(-c4ccccc4)n3)c3ccccc23)cc1 ; c1cc(-c2ccc3ccc4cccnc4c3n2)cc(-c2cc3c4ccccc4c4ccccc4c3c3ccccc23)c1]

Combination 14

The first compound is 1-6 and the second compound is 2-2.

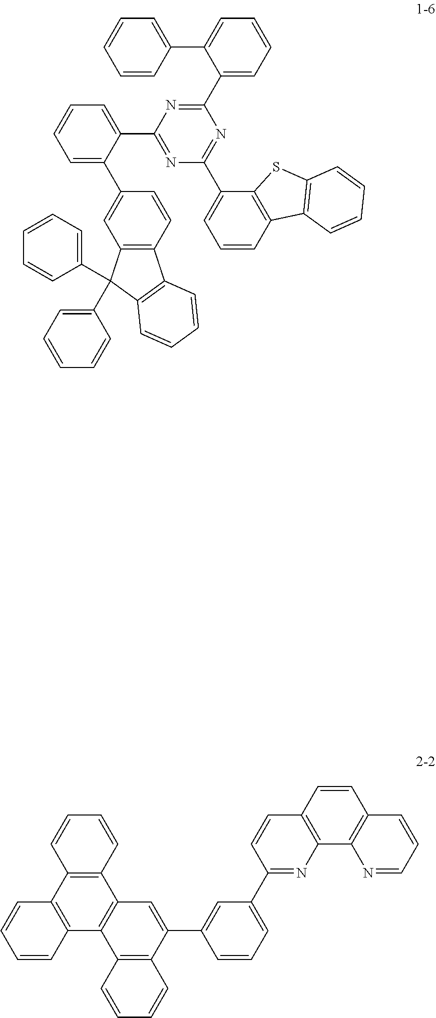 [SMILES: c1ccc(-c2ccccc2-c2nc(-c3ccccc3-c3ccc4c(c3)C(c3ccccc3)(c3ccccc3)c3ccccc3-4)nc(-c3cccc4c3sc3ccccc34)n2)cc1 ; c1cc(-c2ccc3ccc4cccnc4c3n2)cc(-c2cc3c4ccccc4c4ccccc4c3c3ccccc23)c1]

Combination 15

The first compound is 1-7 and the second compound is 2-2

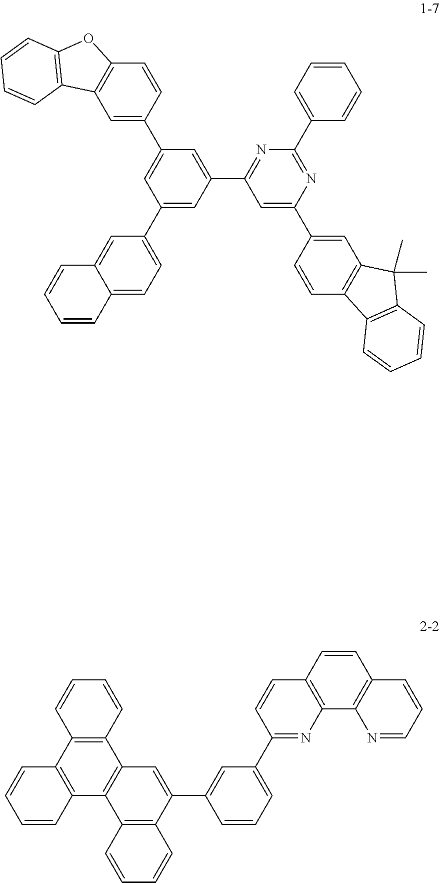 [SMILES: CC1(C)c2ccccc2-c2ccc(-c3cc(-c4cc(-c5ccc6ccccc6c5)cc(-c5ccc6oc7ccccc7c6c5)c4)nc(-c4ccccc4)n3)cc21 ; c1cc(-c2ccc3ccc4cccnc4c3n2)cc(-c2cc3c4ccccc4c4ccccc4c3c3ccccc23)c1]

Combination 16

The first compound is 1-8 and the second compound is 2-2.

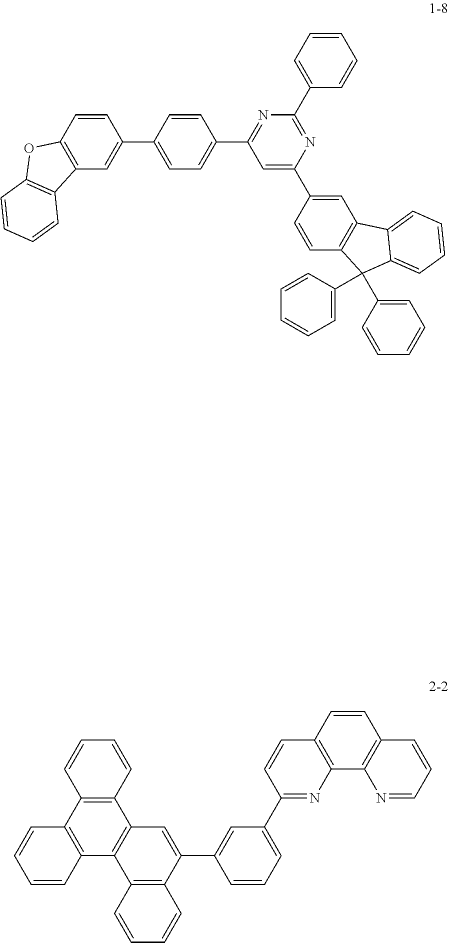 [SMILES: c1ccc(-c2nc(-c3ccc(-c4ccc5oc6ccccc6c5c4)cc3)cc(-c3ccc4c(c3)-c3ccccc3C4(c3ccccc3)c3ccccc3)n2)cc1 ; c1cc(-c2ccc3ccc4cccnc4c3n2)cc(-c2cc3c4ccccc4c4ccccc4c3c3ccccc23)c1]

### (Host Compound)

The host compound used in the emitting layer of the organic EL device according to an aspect of the invention is not particularly limited as long as the above Conditions are satisfied. The host compound may contain a deuterium atom or may not contain a deuterium atom.

As the host compound used in the emitting layer of the organic EL device according to an aspect of the invention, for example, an anthracene derivative can be used.

In one embodiment, the host compound is a compound represented by the following formula (101):

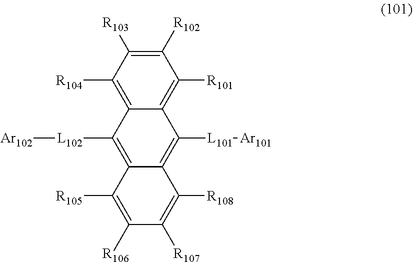

wherein in the formula (101),

one or more sets of adjacent two or more of R₁₀₁ to R₁₀₆ form a substituted or unsubstituted, saturated or unsaturated ring by bonding with each other, or do not form the substituted or unsubstituted, saturated or unsaturated ring;

R₁₀₁ to R₁₀₆ which do not form the substituted or unsubstituted, saturated or unsaturated ring are independently a hydrogen atom or a substituent R;

L₁₀₁ and L₁₀₂ are independently

a single bond,
a substituted or unsubstituted arylene group including 6 to 50 ring carbon atoms, or
a substituted or unsubstituted divalent heterocyclic group including 5 to 50 ring atoms;

Ar₁₀₁ and Ar₁₀₂ are independently

a substituted or unsubstituted aryl group including 6 to 50 ring carbon atoms, or
a substituted or unsubstituted monovalent heterocyclic group including 5 to 50 ring atoms;

the substituent R is

a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

when two or more of the substituent R's are present, the two or more of the substituent R's may be the same as or different from each other, and

R₉₀₁ to R₉₀₇ are independently

a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and
when two or more of each of R₉₀₁ to R₉₀₇ are present, the two or more of each of R₉₀₁ to R₉₀₇ may be the same as or different from each other.

In one embodiment, the host compound is a compound represented by the following formula (102):

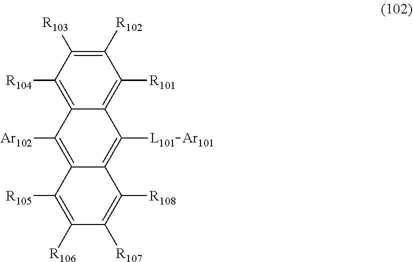

wherein in the formula (102), R₁₀₁ to R₁₀₆, L₁₀₁, Ar₁₀₁, and Ar₁₀₂ are as defined in the formula (101).

In one embodiment, the host compound is a compound represented by the following formula (103):

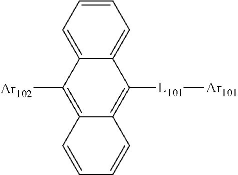

wherein in the formula (103), L₁₀₁, Ar₁₀₁, and Ar₁₀₂ are as defined in the formula (101).

As described in [Definition], a term “hydrogen atom” used in this specification includes a protium atom, a deuterium atom, and a tritium atom. Accordingly, the host compound may have a naturally derived deuterium atom.

Further, a deuterium atom may be intentionally introduced into the host compound by replacing part or all of the raw material compounds with their deuterated compounds. Accordingly, in one embodiment, the host compound has at least one deuterium atom. In other words, the compound of this embodiment may be a compound represented by the formula (101), wherein at least one of hydrogen atoms possessed by the compound is a deuterium atom.

In one embodiment, one or more of hydrogen atoms possessed by the substituted or unsubstituted, saturated or unsaturated ring formed by bonding one or more sets of adjacent two or more of R₁₀₁ to R₁₀₆ with each other,

R₁₀₁ to R₁₀₆ which are hydrogen atoms,

hydrogen atoms possessed by R₁₀₁ to R₁₀₆ which are the substituent R's,
hydrogen atoms possessed by L₁₀₁,
hydrogen atoms possessed by L₁₀₂,
hydrogen atoms possessed by Ar₁₀₁, and
hydrogen atoms possessed by Ar₁₀₂ are deuterium atoms.
In one embodiment, the deuteration rate of the host compound is, for example, 1% or more, 3% or more, 5% or more, 10% or more, or 50% or more.

The compound represented by the formula (101) can be synthesized by using a known alternative reaction or raw material tailored to the target compound.

Specific examples of the host compound will be described below, but are illustrative only, and the host compound is not limited to the following specific examples.

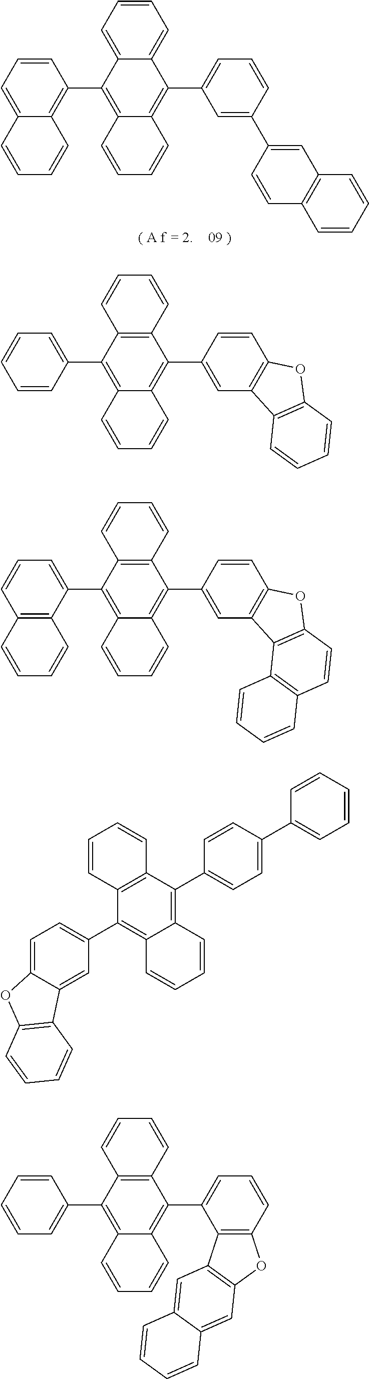

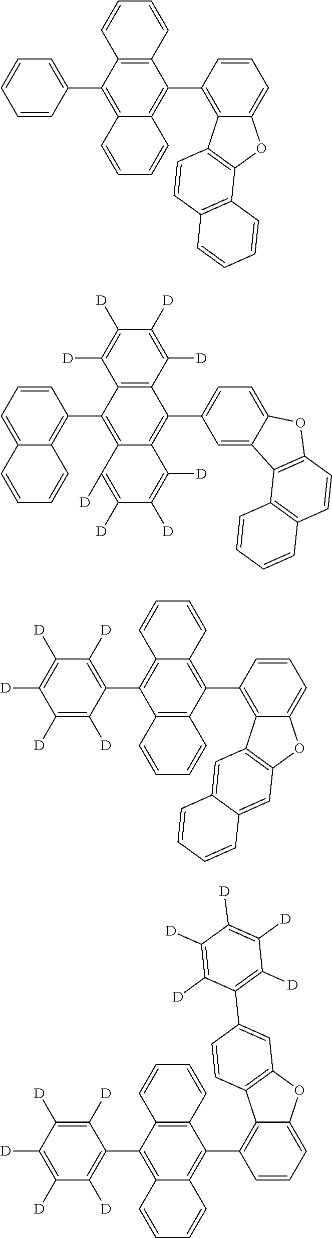

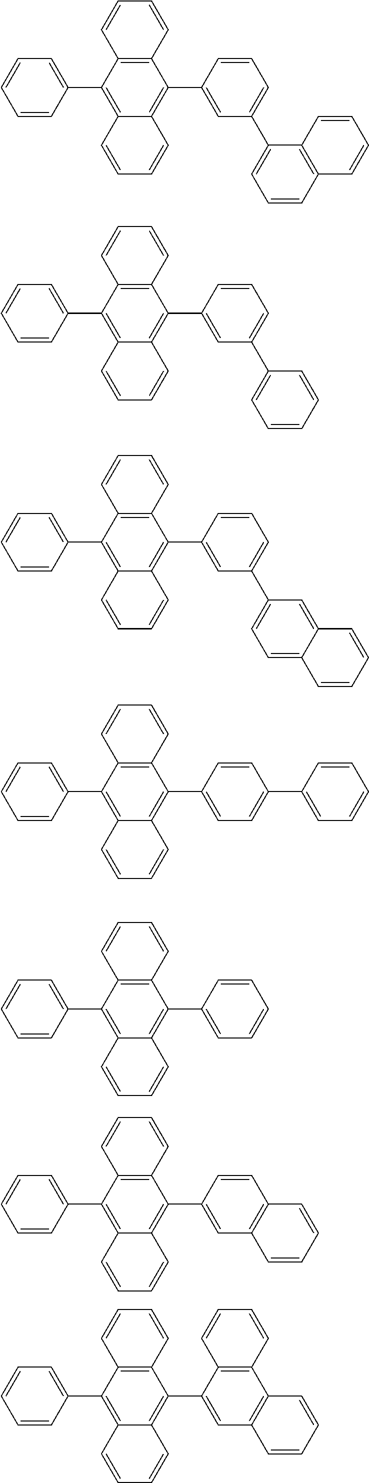

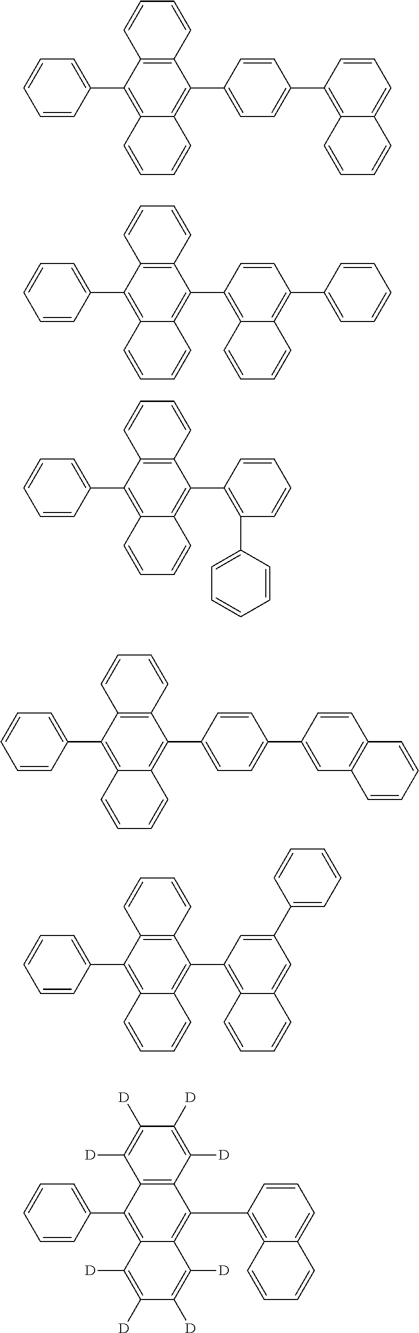

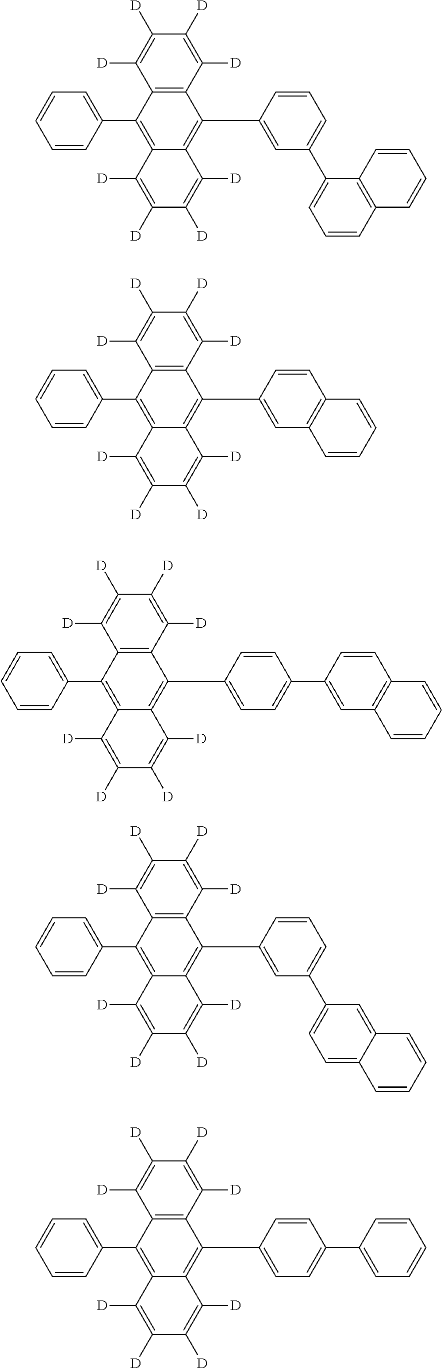

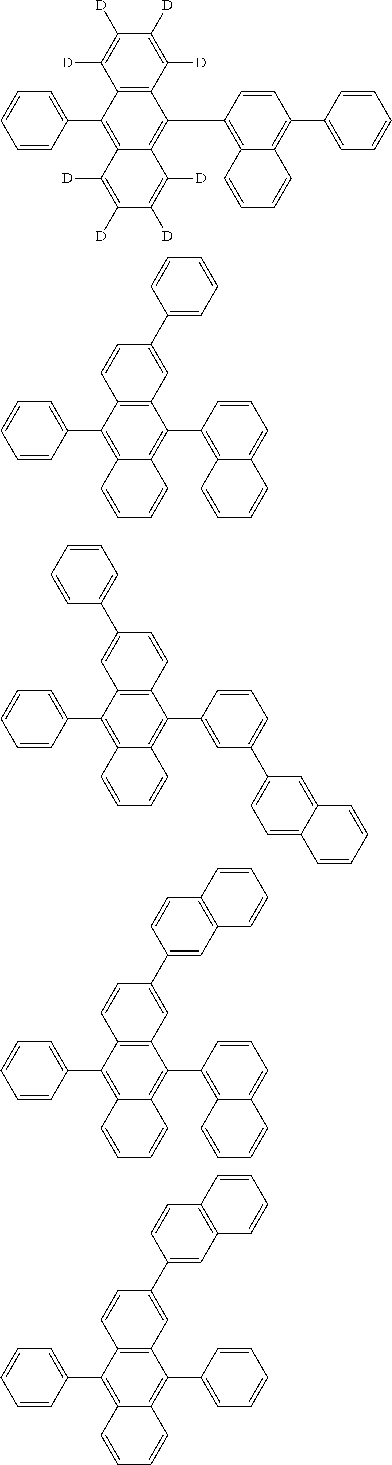

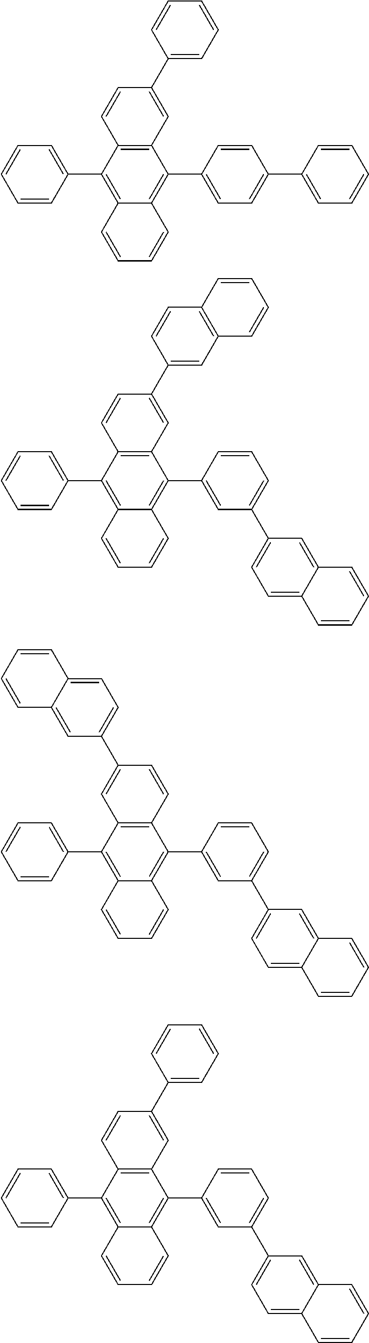

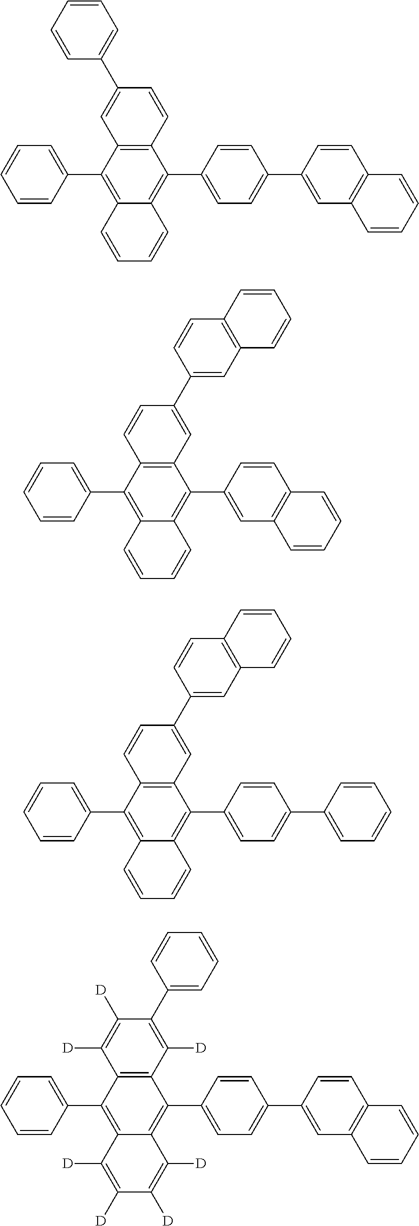

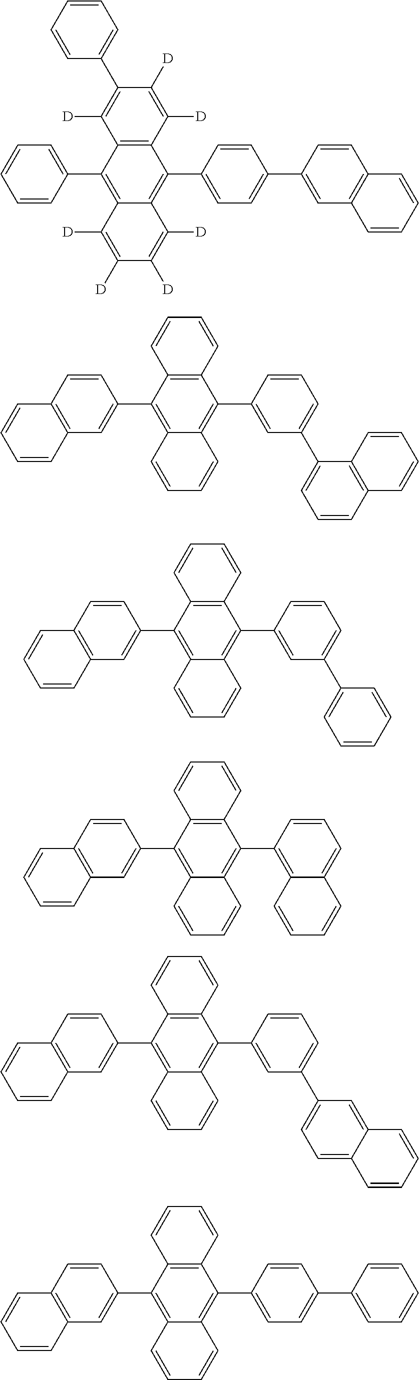

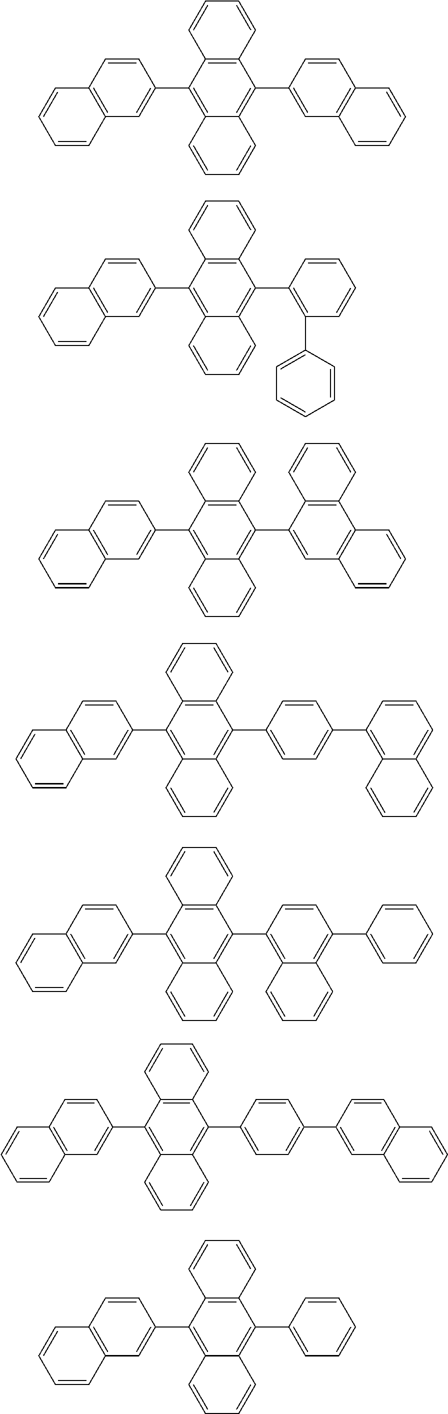

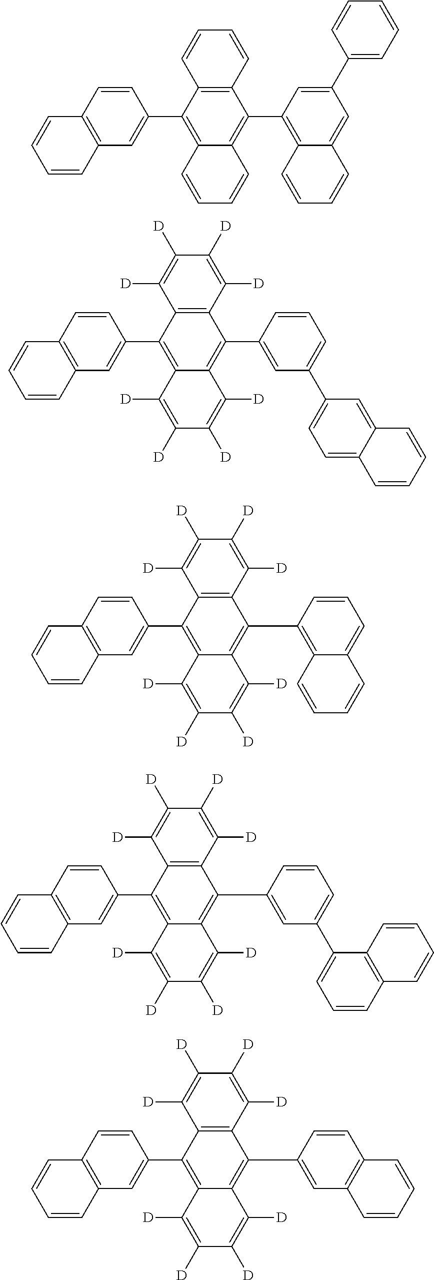

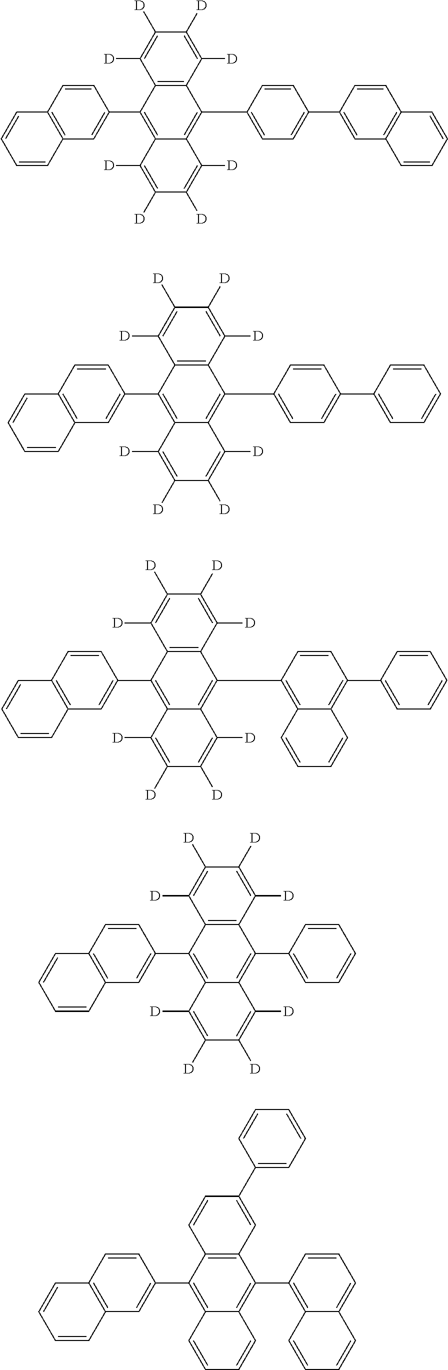

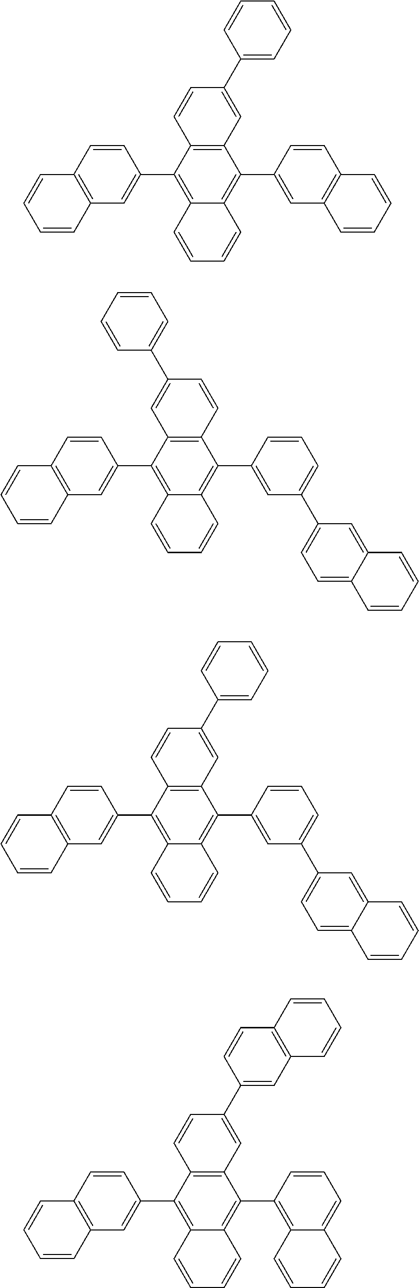

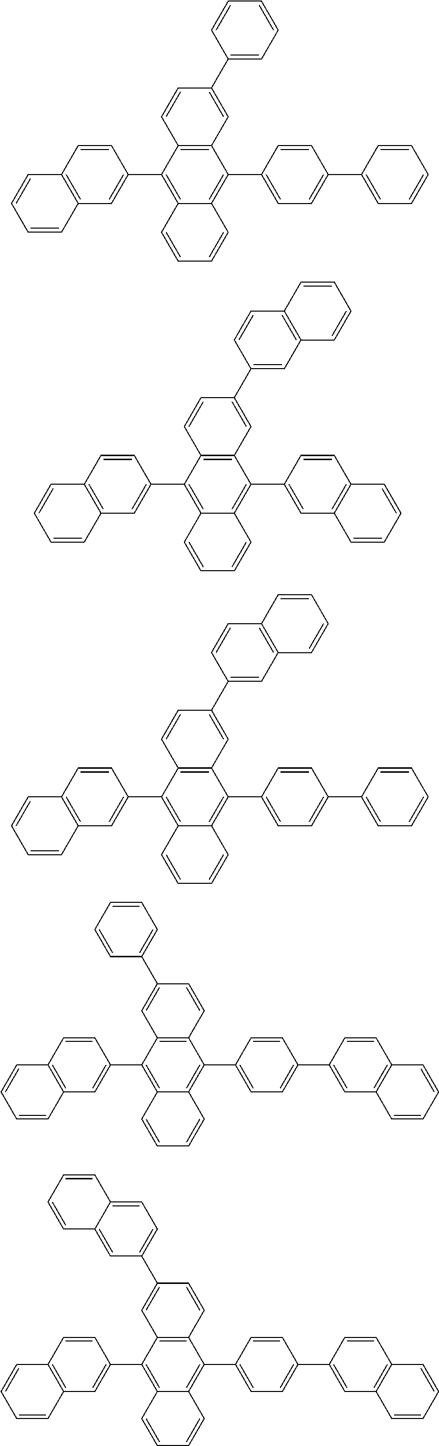

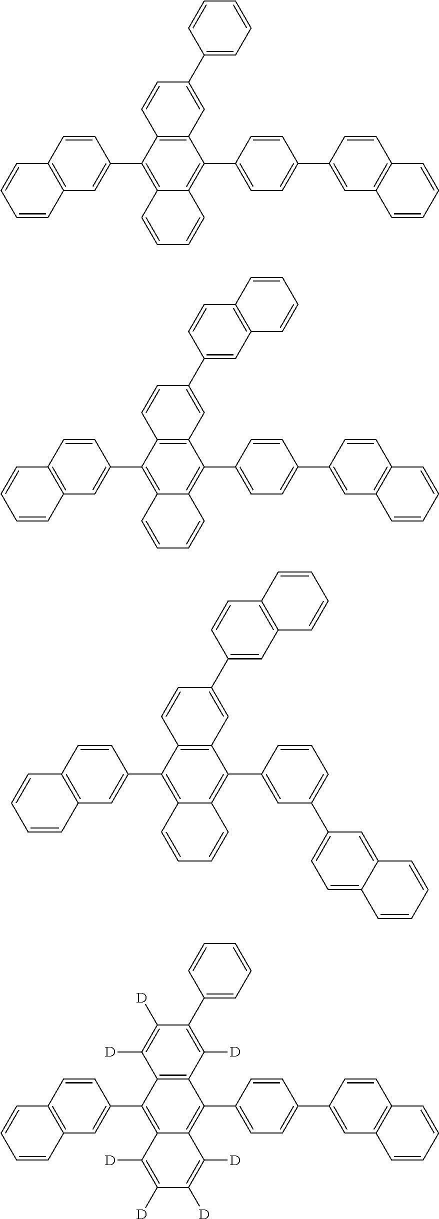

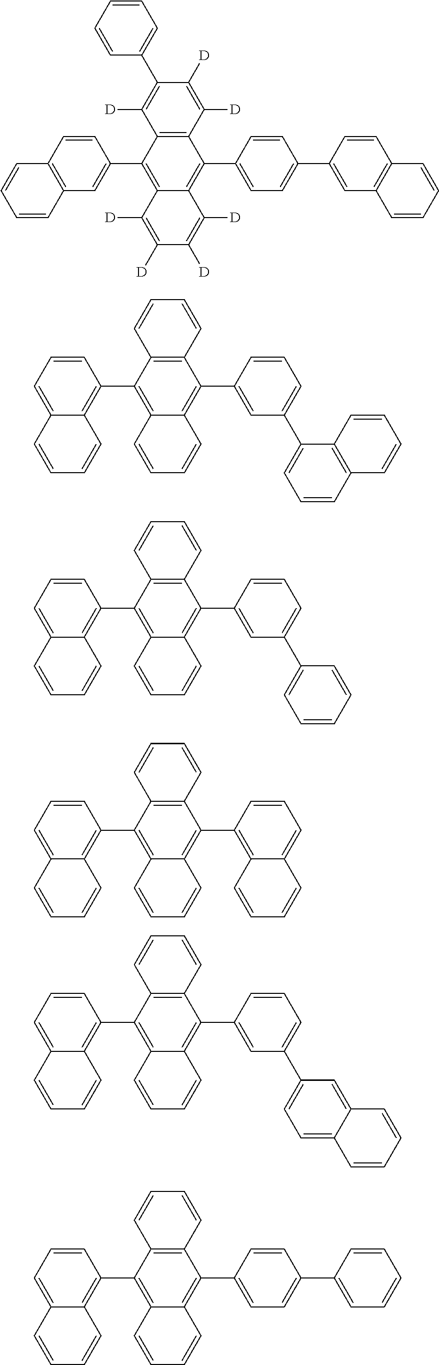

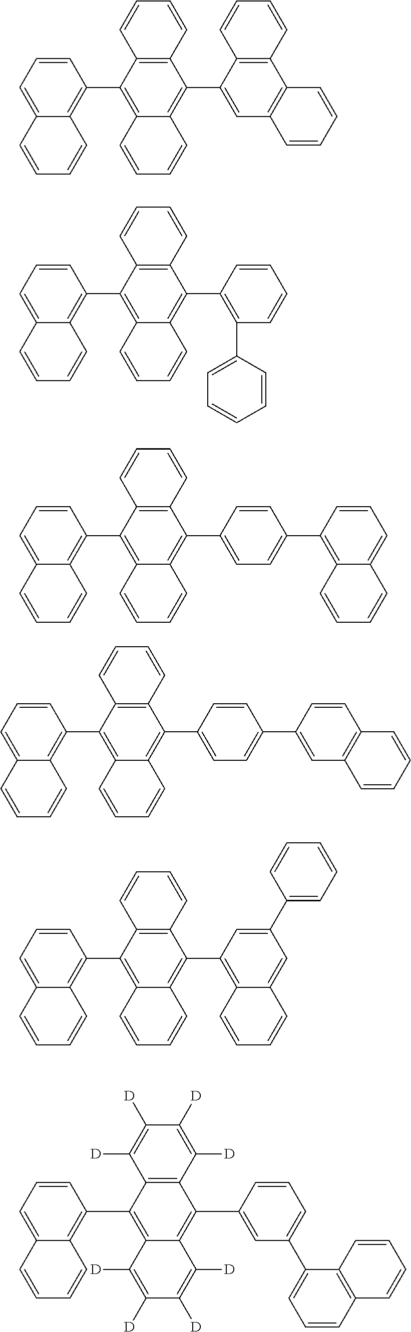

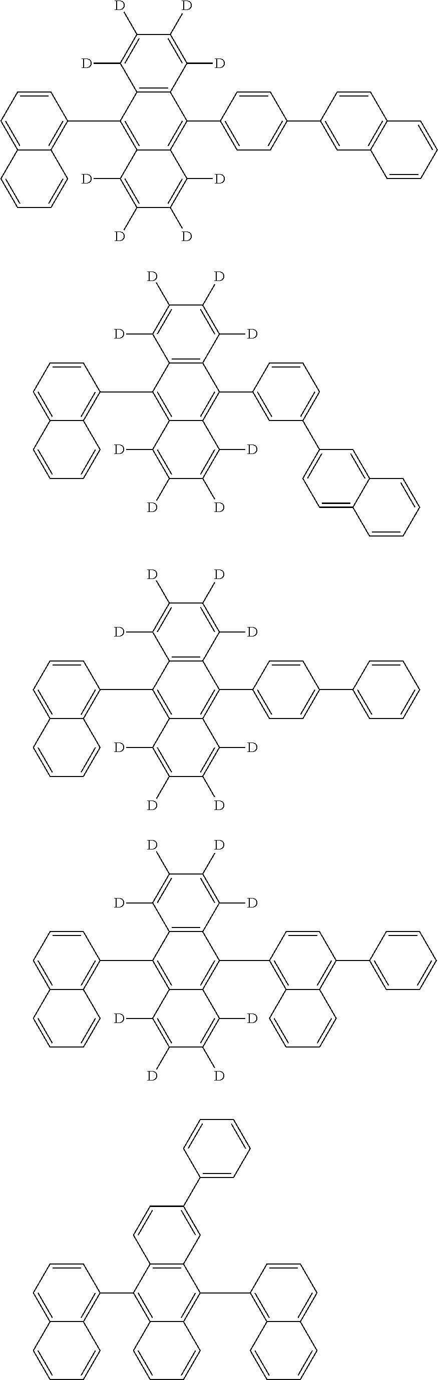

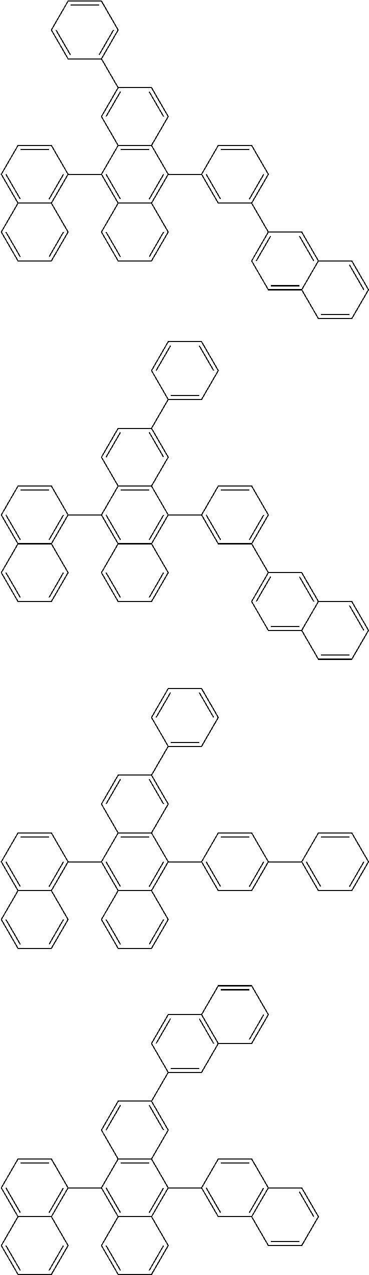

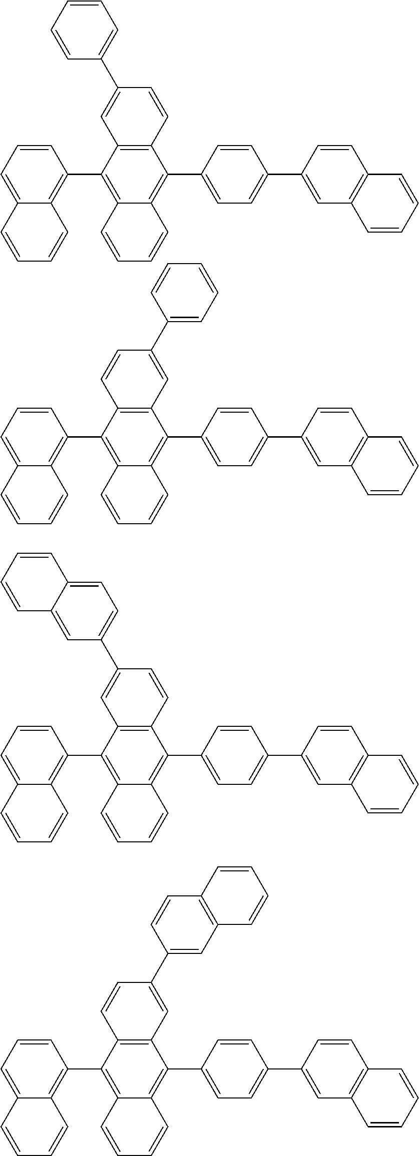

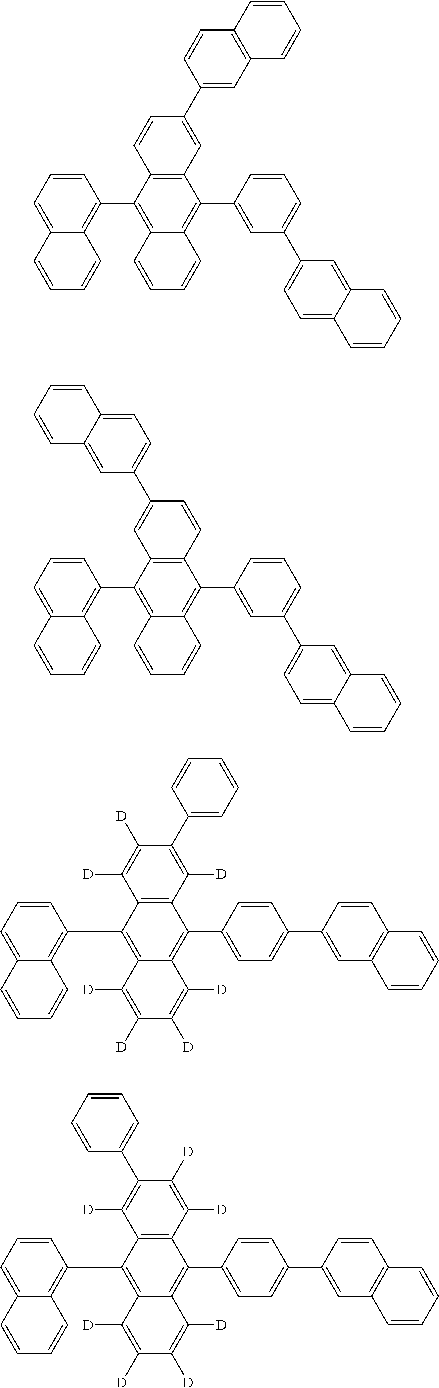

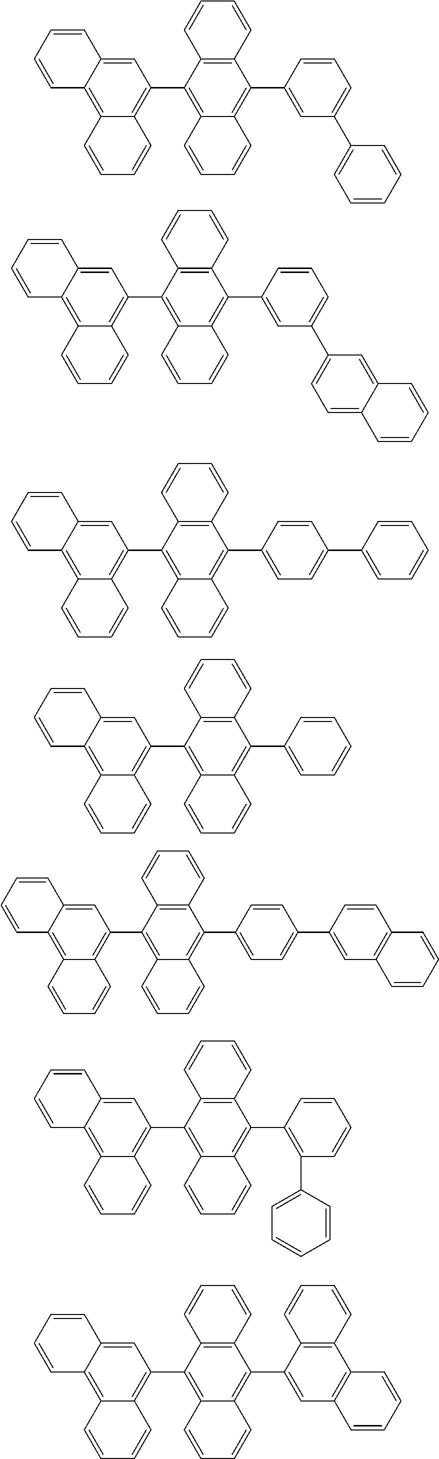

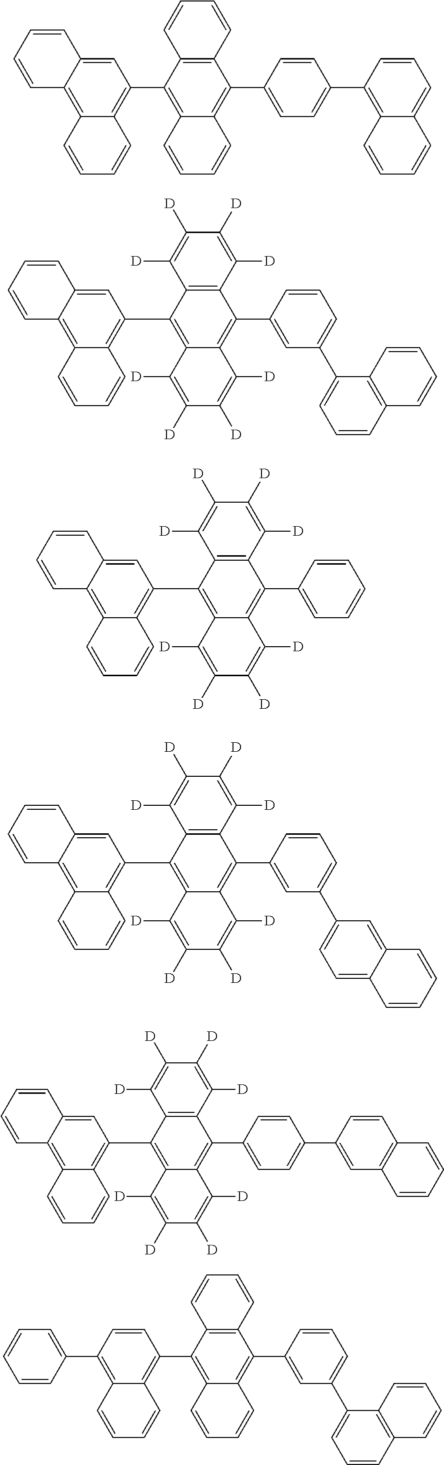

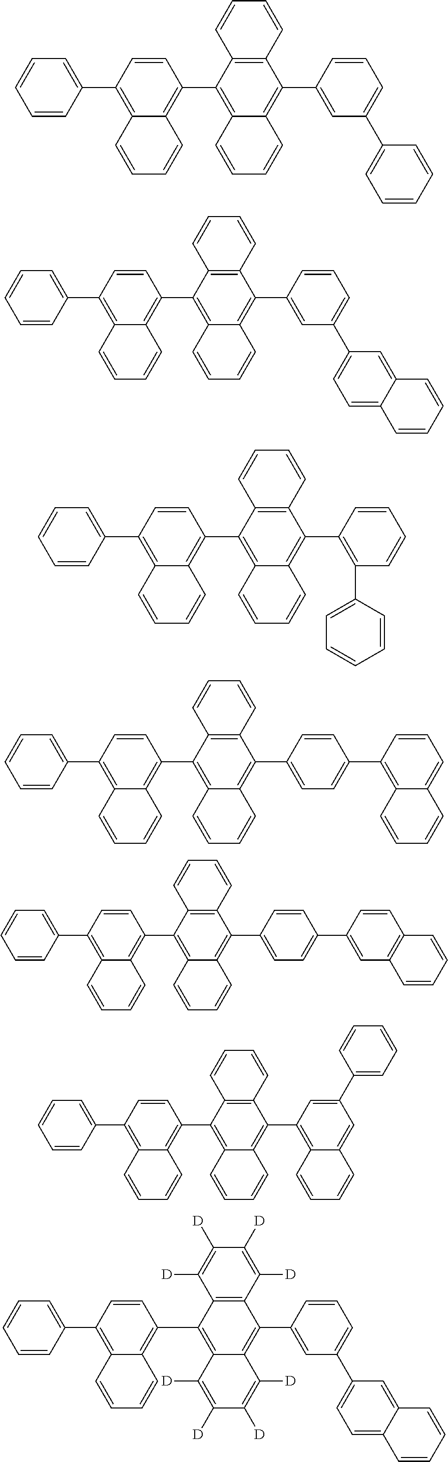

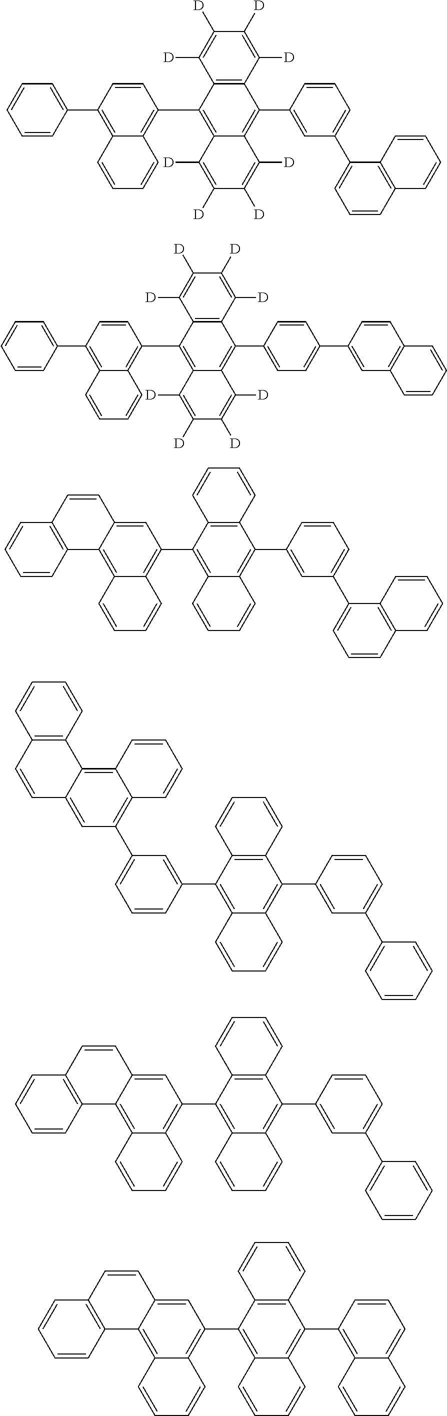

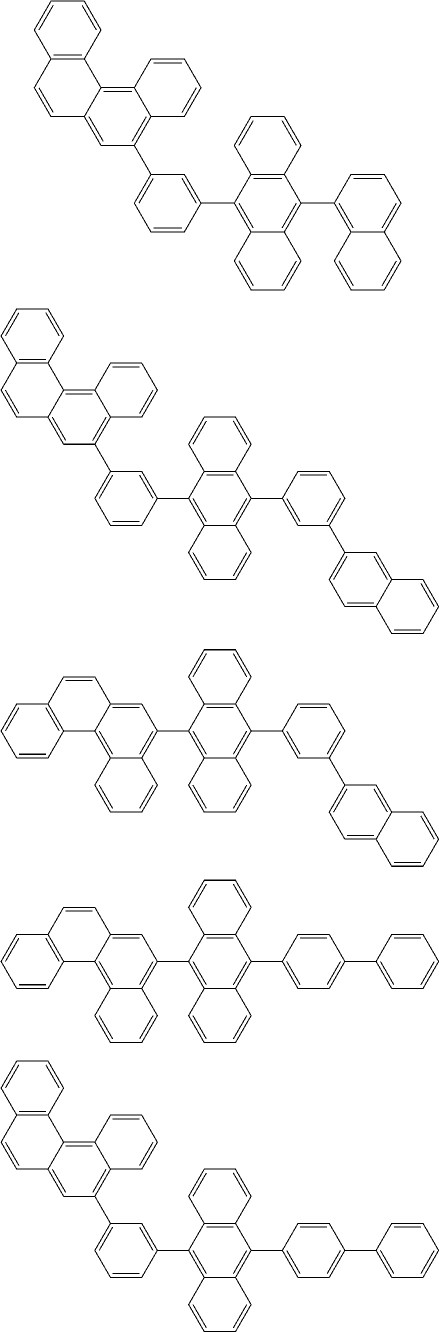

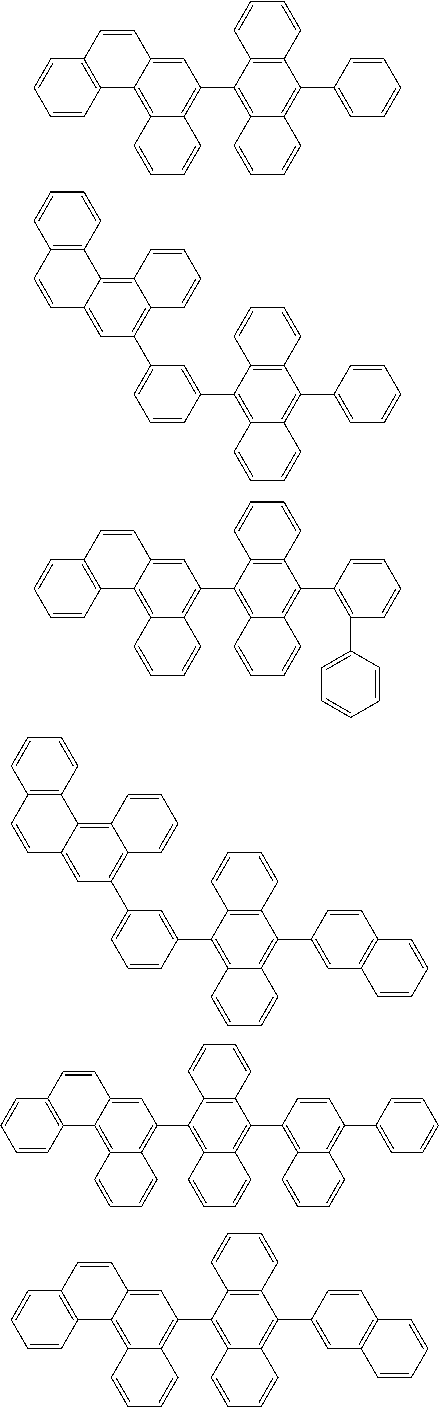

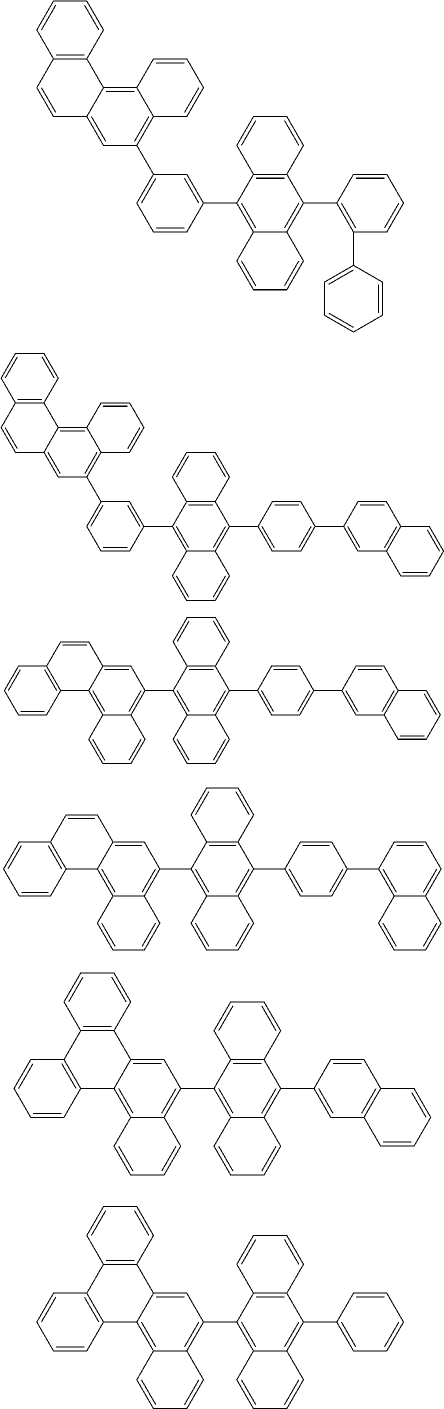

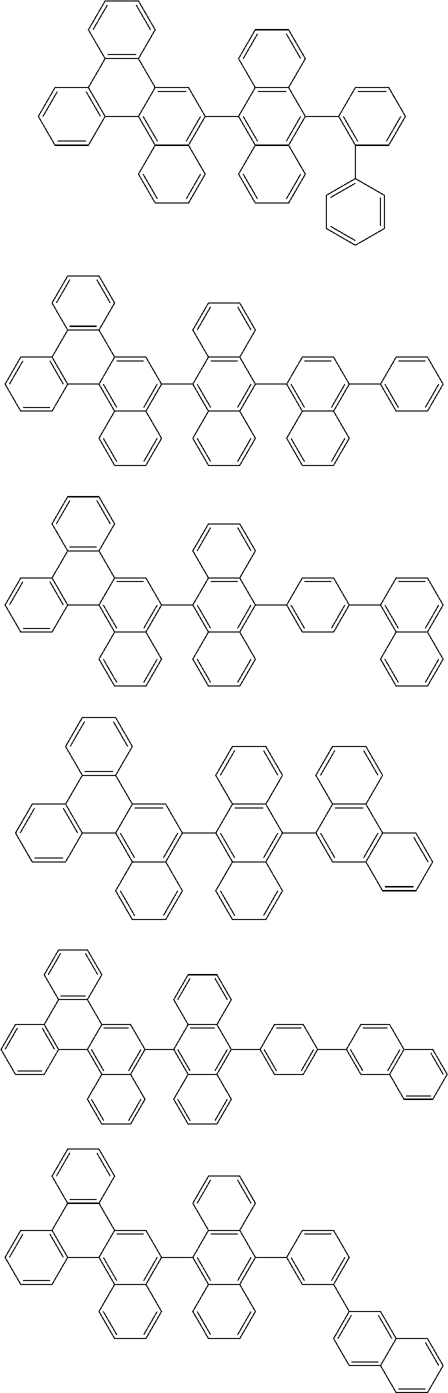

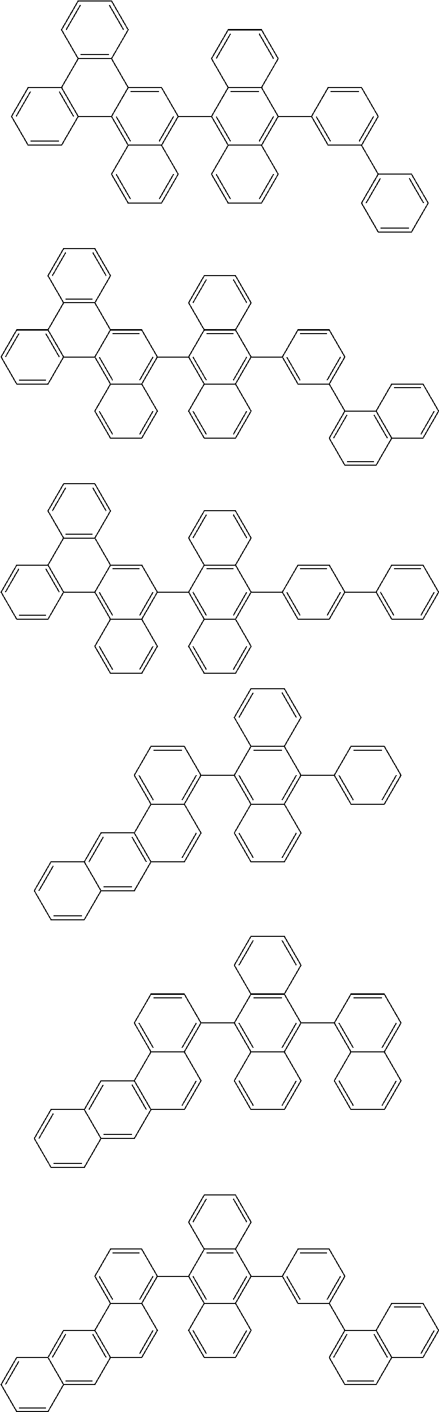

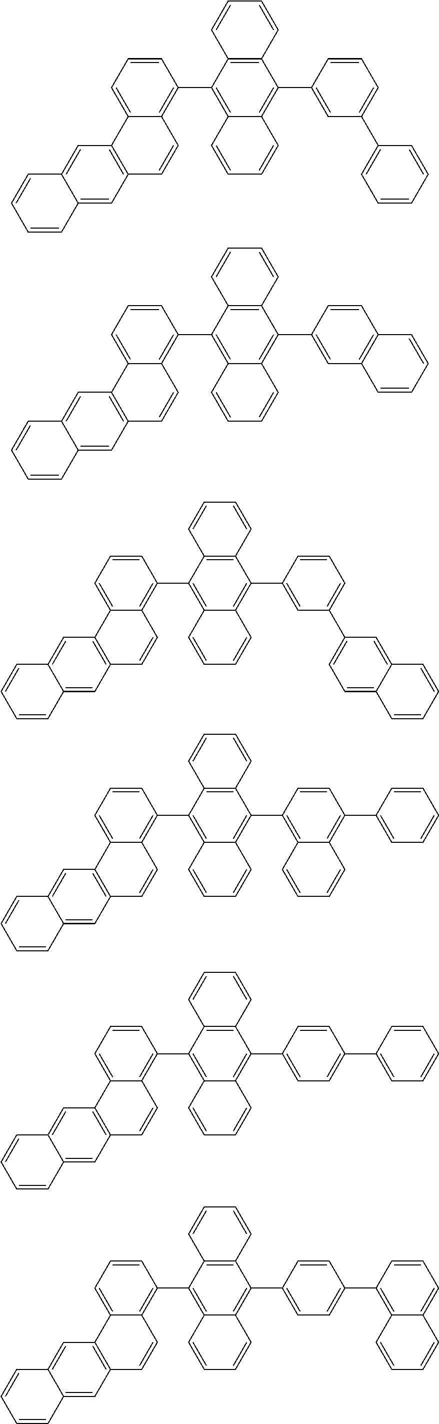

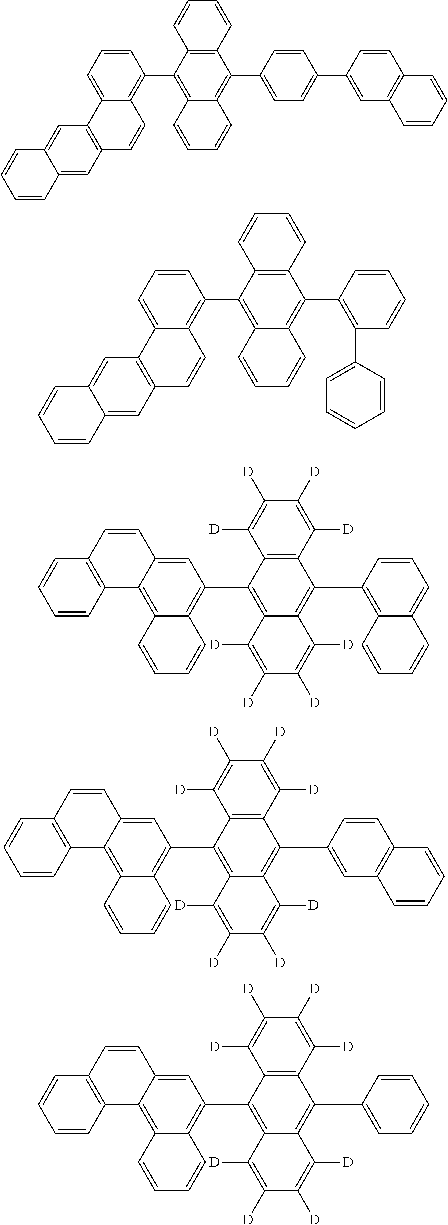

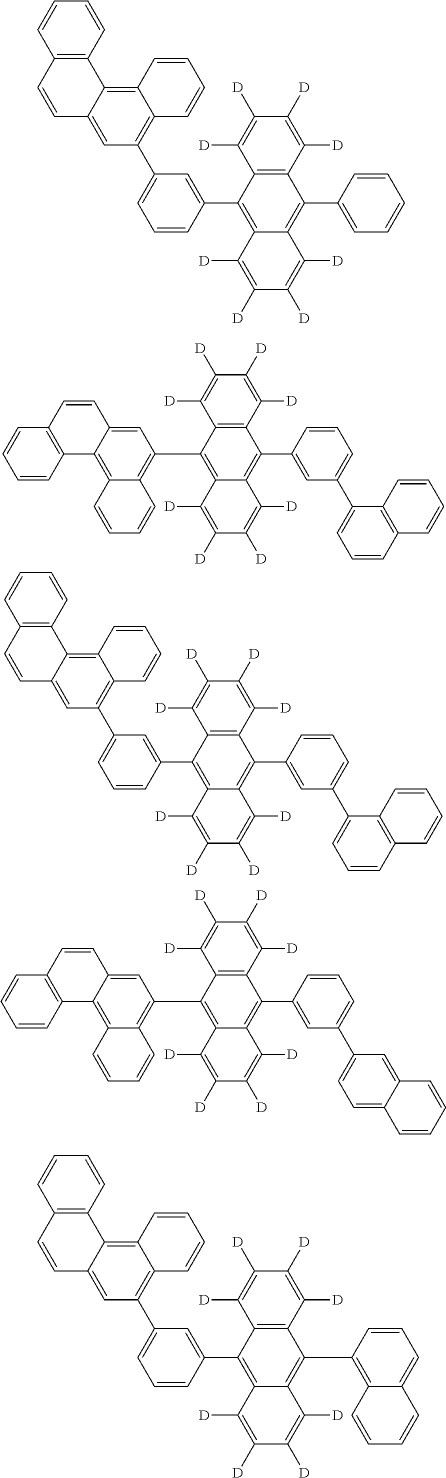

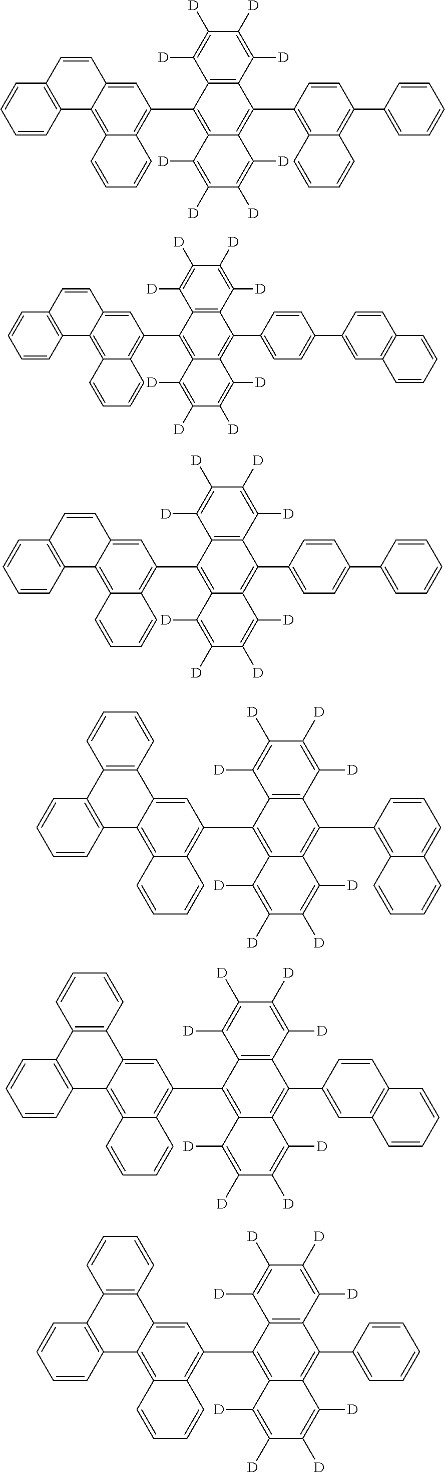

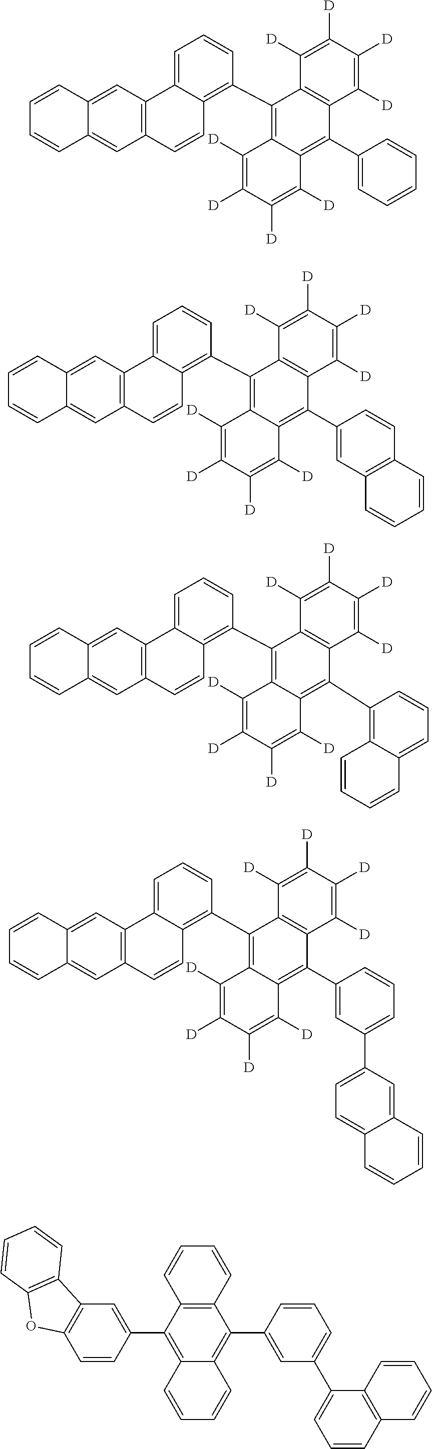

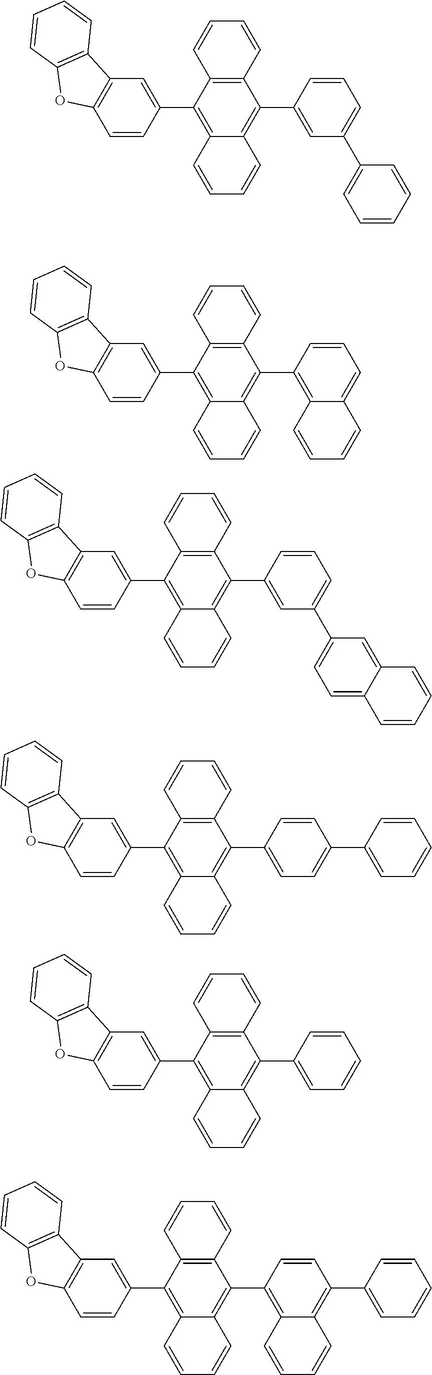

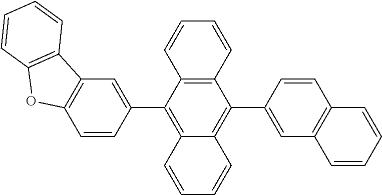 [SMILES: c1ccc2cc(-c3c4ccccc4c(-c4ccc5oc6ccccc6c5c4)c4ccccc34)ccc2c1]

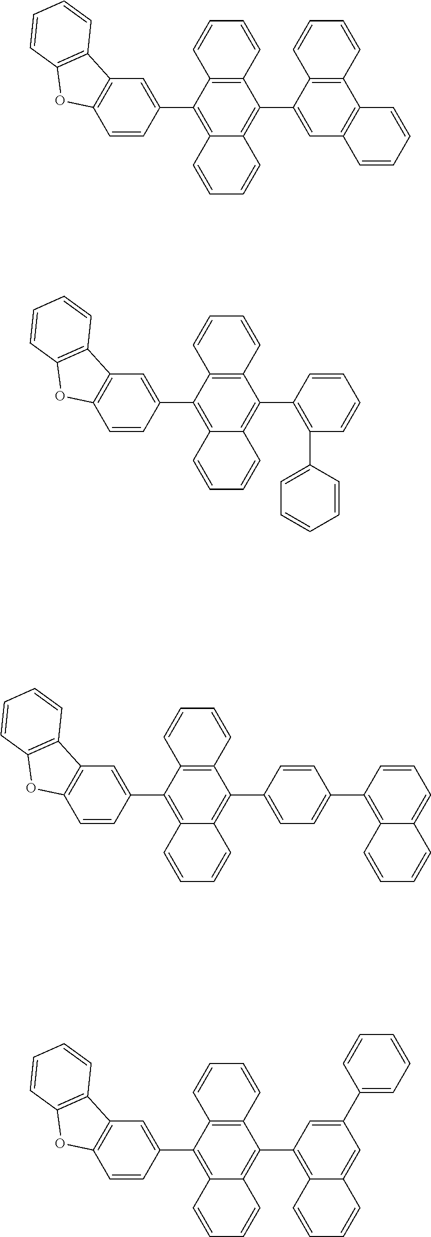 [SMILES: c1ccc2c(c1)cc(-c1c3ccccc3c(-c3ccc4oc5ccccc5c4c3)c3ccccc13)c1ccccc12 ; c1ccc(-c2ccccc2-c2c3ccccc3c(-c3ccc4oc5ccccc5c4c3)c3ccccc23)cc1 ; c1ccc2c(-c3ccc(-c4c5ccccc5c(-c5ccc6oc7ccccc7c6c5)c5ccccc45)cc3)cccc2c1 ; c1ccc(-c2cc(-c3c4ccccc4c(-c4ccc5oc6ccccc6c5c4)c4ccccc34)c3ccccc3c2)cc1]

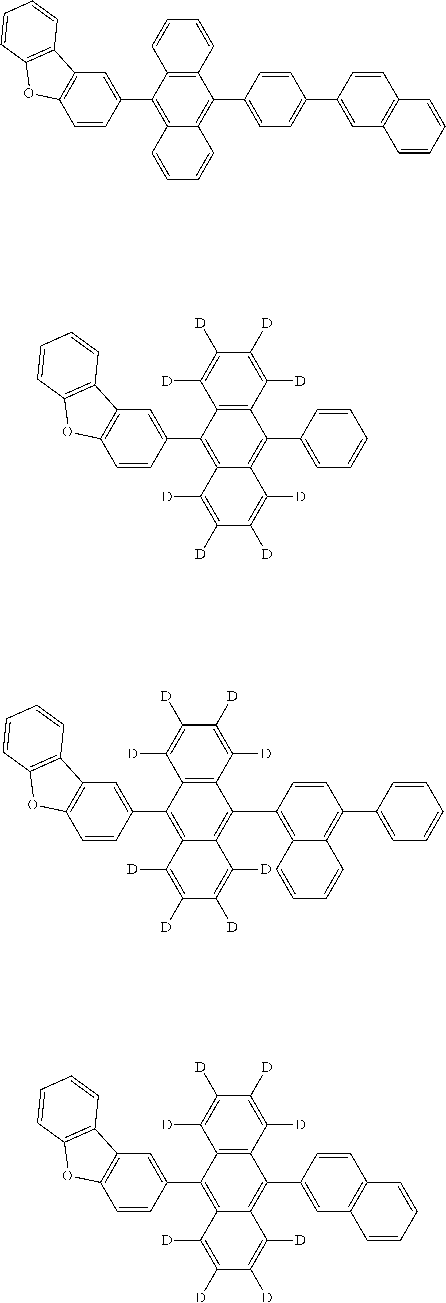 [SMILES: c1ccc2cc(-c3ccc(-c4c5ccccc5c(-c5ccc6oc7ccccc7c6c5)c5ccccc45)cc3)ccc2c1 ; [2H]c1c([2H])c([2H])c2c(-c3ccc4oc5ccccc5c4c3)c3c([2H])c([2H])c([2H])c([2H])c3c(-c3ccccc3)c2c1[2H] ; [2H]c1c([2H])c([2H])c2c(-c3ccc(-c4ccccc4)c4ccccc34)c3c([2H])c([2H])c([2H])c([2H])c3c(-c3ccc4oc5ccccc5c4c3)c2c1[2H] ; [2H]c1c([2H])c([2H])c2c(-c3ccc4oc5ccccc5c4c3)c3c([2H])c([2H])c([2H])c([2H])c3c(-c3ccc4ccccc4c3)c2c1[2H]]

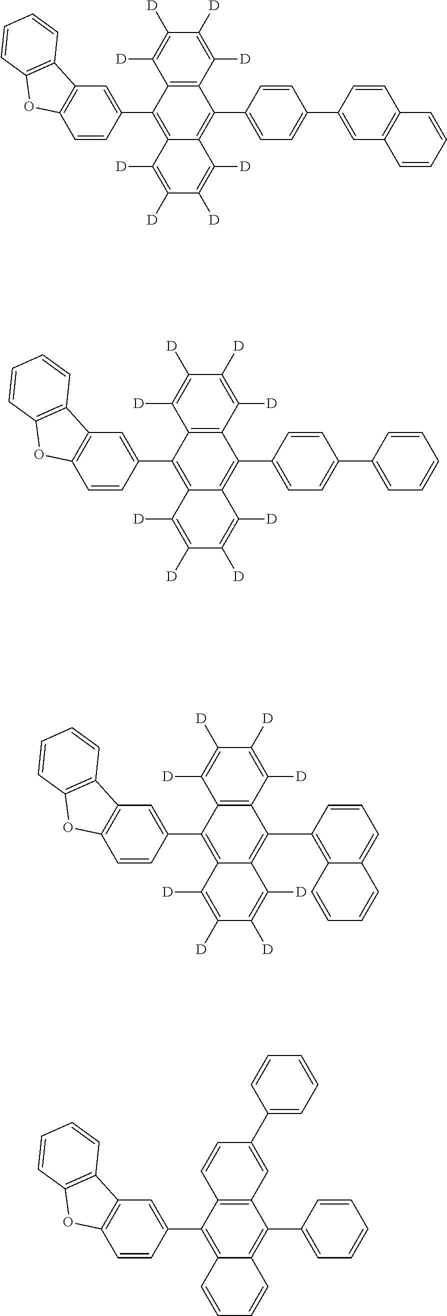 [SMILES: [2H]c1c([2H])c([2H])c2c(-c3ccc4oc5ccccc5c4c3)c3c([2H])c([2H])c([2H])c([2H])c3c(-c3ccc(-c4ccc5ccccc5c4)cc3)c2c1[2H] ; [2H]c1c([2H])c([2H])c2c(-c3ccc4oc5ccccc5c4c3)c3c([2H])c([2H])c([2H])c([2H])c3c(-c3ccc(-c4ccccc4)cc3)c2c1[2H] ; [2H]c1c([2H])c([2H])c2c(-c3cccc4ccccc34)c3c([2H])c([2H])c([2H])c([2H])c3c(-c3ccc4oc5ccccc5c4c3)c2c1[2H] ; c1ccc(-c2ccc3c(-c4ccc5oc6ccccc6c5c4)c4ccccc4c(-c4ccccc4)c3c2)cc1]

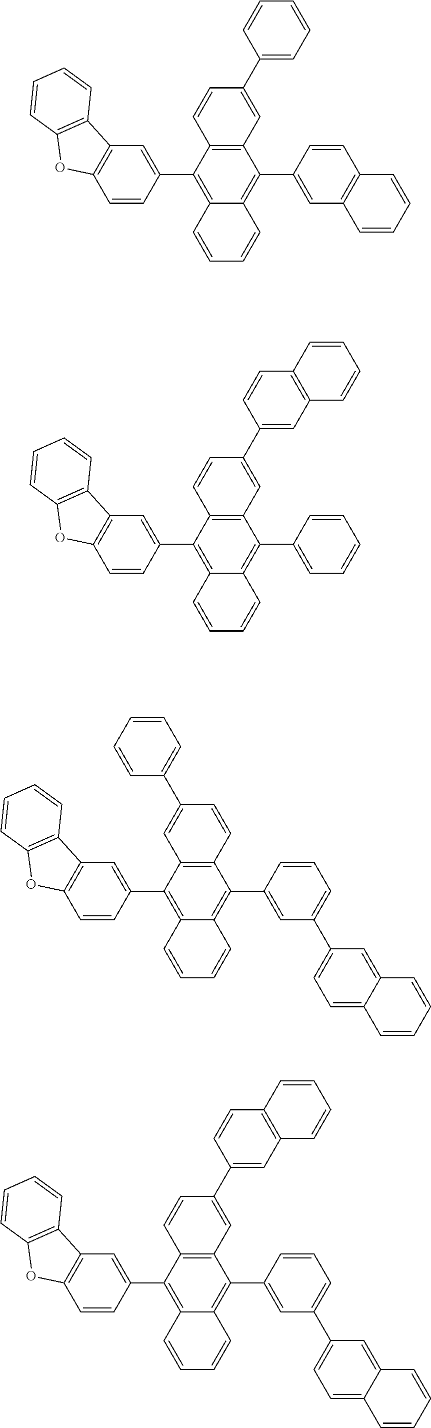 [SMILES: c1ccc(-c2ccc3c(-c4ccc5oc6ccccc6c5c4)c4ccccc4c(-c4ccc5ccccc5c4)c3c2)cc1 ; c1ccc(-c2c3ccccc3c(-c3ccc4oc5ccccc5c4c3)c3ccc(-c4ccc5ccccc5c4)cc23)cc1 ; c1ccc(-c2ccc3c(-c4cccc(-c5ccc6ccccc6c5)c4)c4ccccc4c(-c4ccc5oc6ccccc6c5c4)c3c2)cc1 ; c1cc(-c2ccc3ccccc3c2)cc(-c2c3ccccc3c(-c3ccc4oc5ccccc5c4c3)c3ccc(-c4ccc5ccccc5c4)cc23)c1]

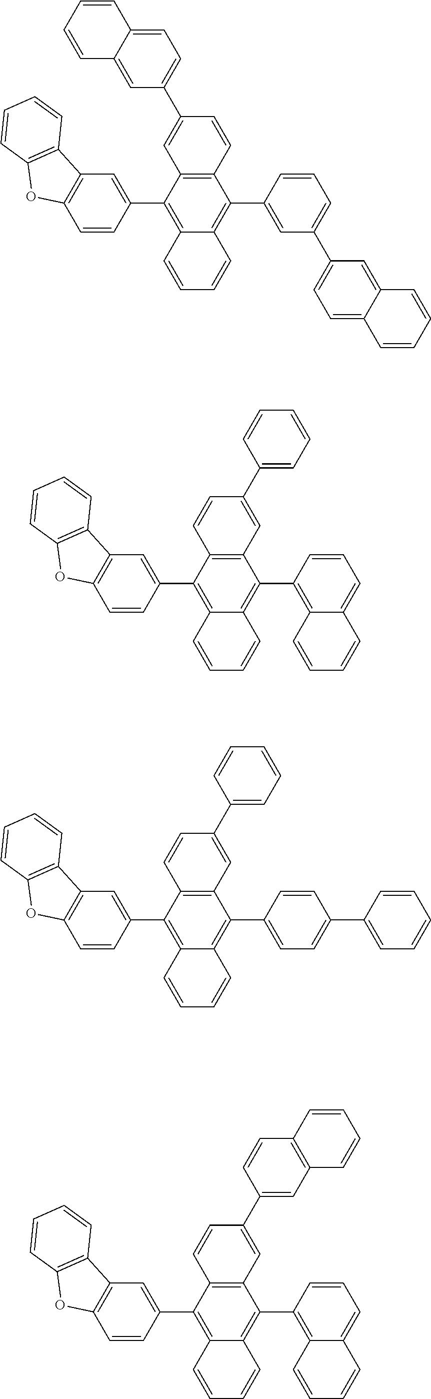 [SMILES: c1cc(-c2ccc3ccccc3c2)cc(-c2c3ccccc3c(-c3ccc4oc5ccccc5c4c3)c3cc(-c4ccc5ccccc5c4)ccc23)c1 ; c1ccc(-c2ccc3c(-c4ccc5oc6ccccc6c5c4)c4ccccc4c(-c4cccc5ccccc45)c3c2)cc1 ; c1ccc(-c2ccc(-c3c4ccccc4c(-c4ccc5oc6ccccc6c5c4)c4ccc(-c5ccccc5)cc34)cc2)cc1 ; c1ccc2cc(-c3ccc4c(-c5ccc6oc7ccccc7c6c5)c5ccccc5c(-c5cccc6ccccc56)c4c3)ccc2c1]

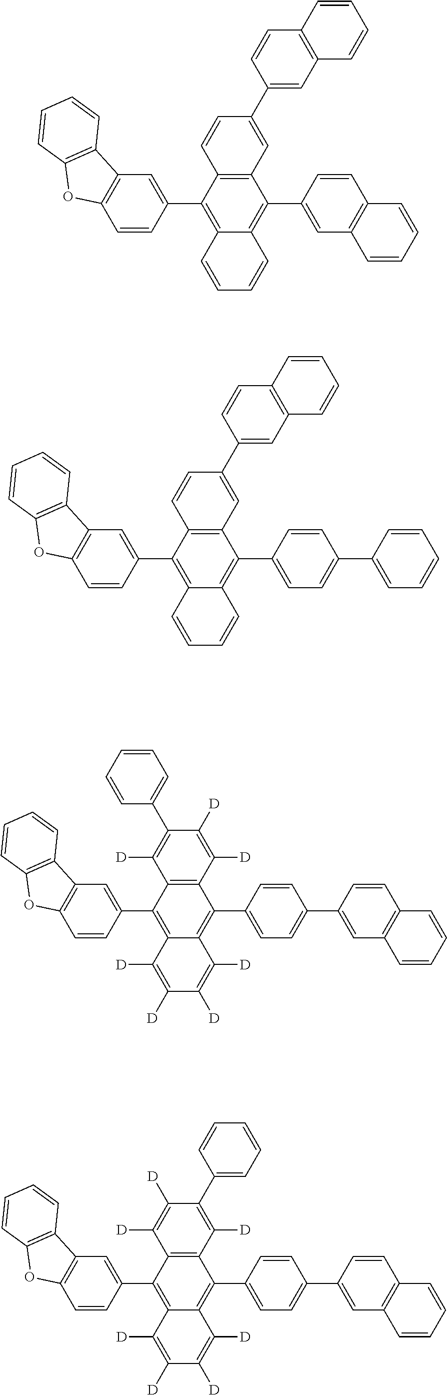 [SMILES: c1ccc2cc(-c3ccc4c(-c5ccc6oc7ccccc7c6c5)c5ccccc5c(-c5ccc6ccccc6c5)c4c3)ccc2c1 ; c1ccc(-c2ccc(-c3c4ccccc4c(-c4ccc5oc6ccccc6c5c4)c4ccc(-c5ccc6ccccc6c5)cc34)cc2)cc1 ; [2H]c1c([2H])c([2H])c2c(-c3ccc4oc5ccccc5c4c3)c3c([2H])c(-c4ccccc4)c([2H])c([2H])c3c(-c3ccc(-c4ccc5ccccc5c4)cc3)c2c1[2H] ; [2H]c1c([2H])c([2H])c2c(-c3ccc(-c4ccc5ccccc5c4)cc3)c3c([2H])c(-c4ccccc4)c([2H])c([2H])c3c(-c3ccc4oc5ccccc5c4c3)c2c1[2H]]

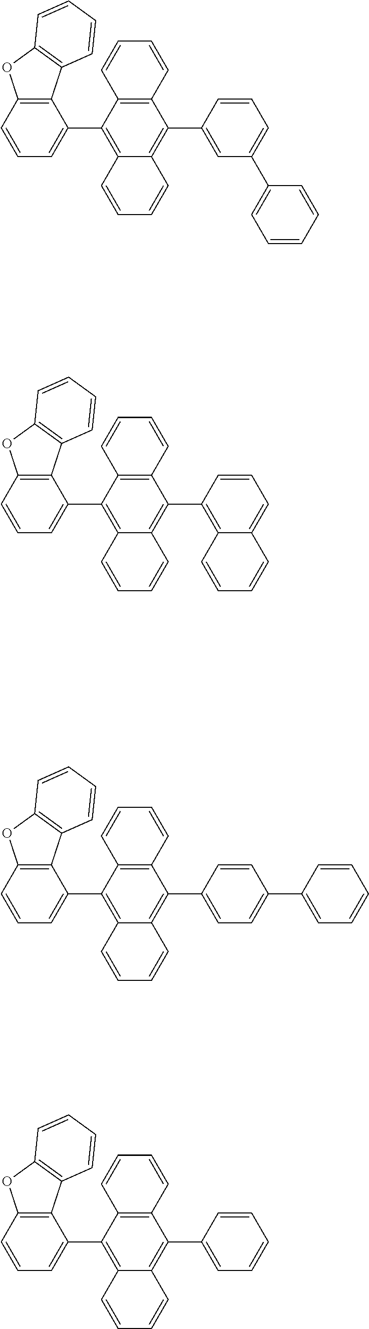 [SMILES: c1ccc(-c2cccc(-c3c4ccccc4c(-c4cccc5oc6ccccc6c45)c4ccccc34)c2)cc1 ; c1ccc2c(-c3c4ccccc4c(-c4cccc5oc6ccccc6c45)c4ccccc34)cccc2c1 ; c1ccc(-c2ccc(-c3c4ccccc4c(-c4cccc5oc6ccccc6c45)c4ccccc34)cc2)cc1 ; c1ccc(-c2c3ccccc3c(-c3cccc4oc5ccccc5c34)c3ccccc23)cc1]

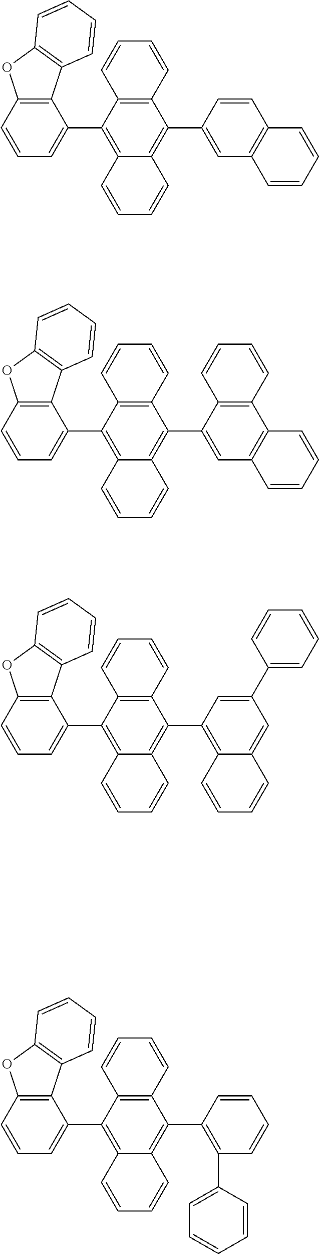 [SMILES: c1ccc2cc(-c3c4ccccc4c(-c4cccc5oc6ccccc6c45)c4ccccc34)ccc2c1 ; c1ccc2c(c1)cc(-c1c3ccccc3c(-c3cccc4oc5ccccc5c34)c3ccccc13)c1ccccc12 ; c1ccc(-c2cc(-c3c4ccccc4c(-c4cccc5oc6ccccc6c45)c4ccccc34)c3ccccc3c2)cc1 ; c1ccc(-c2ccccc2-c2c3ccccc3c(-c3cccc4oc5ccccc5c34)c3ccccc23)cc1]

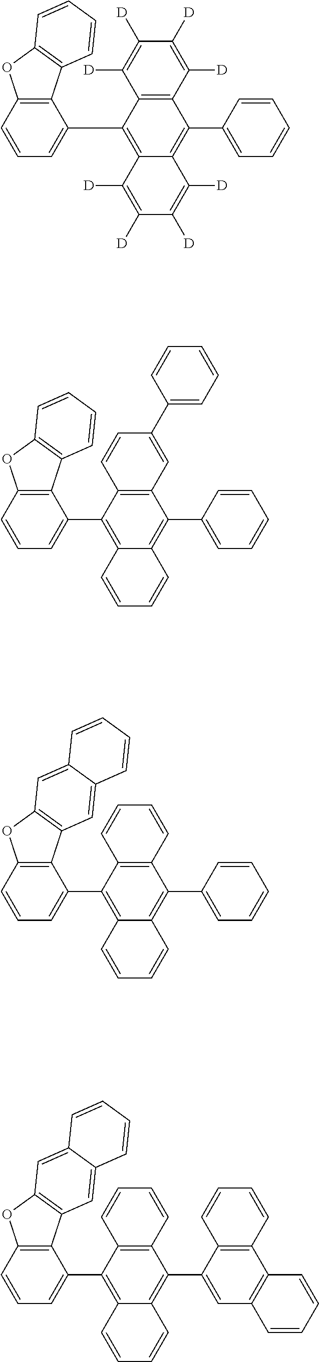 [SMILES: [2H]c1c([2H])c([2H])c2c(-c3cccc4oc5ccccc5c34)c3c([2H])c([2H])c([2H])c([2H])c3c(-c3ccccc3)c2c1[2H] ; c1ccc(-c2ccc3c(-c4cccc5oc6ccccc6c45)c4ccccc4c(-c4ccccc4)c3c2)cc1 ; c1ccc(-c2c3ccccc3c(-c3cccc4oc5cc6ccccc6cc5c34)c3ccccc23)cc1 ; c1ccc2cc3c(cc2c1)oc1cccc(-c2c4ccccc4c(-c4cc5ccccc5c5ccccc45)c4ccccc24)c13]

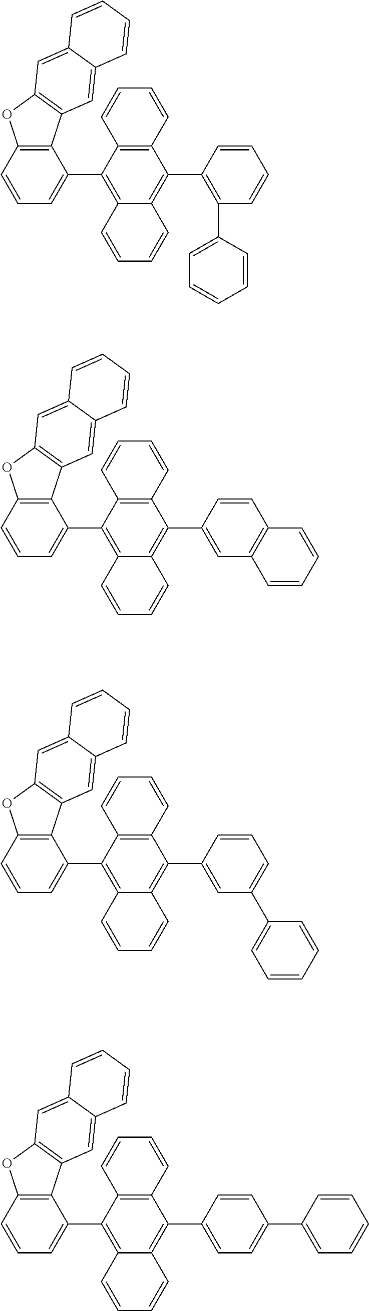 [SMILES: c1ccc(-c2ccccc2-c2c3ccccc3c(-c3cccc4oc5cc6ccccc6cc5c34)c3ccccc23)cc1 ; c1ccc2cc(-c3c4ccccc4c(-c4cccc5oc6cc7ccccc7cc6c45)c4ccccc34)ccc2c1 ; c1ccc(-c2cccc(-c3c4ccccc4c(-c4cccc5oc6cc7ccccc7cc6c45)c4ccccc34)c2)cc1 ; c1ccc(-c2ccc(-c3c4ccccc4c(-c4cccc5oc6cc7ccccc7cc6c45)c4ccccc34)cc2)cc1]

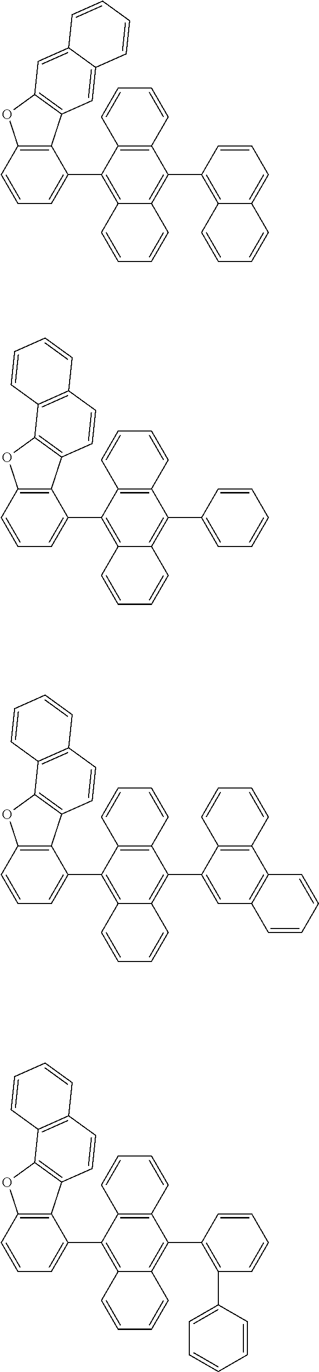 [SMILES: c1ccc2cc3c(cc2c1)oc1cccc(-c2c4ccccc4c(-c4cccc5ccccc45)c4ccccc24)c13 ; c1ccc(-c2c3ccccc3c(-c3cccc4oc5c6ccccc6ccc5c34)c3ccccc23)cc1 ; c1ccc2c(c1)cc(-c1c3ccccc3c(-c3cccc4oc5c6ccccc6ccc5c34)c3ccccc13)c1ccccc12 ; c1ccc(-c2ccccc2-c2c3ccccc3c(-c3cccc4oc5c6ccccc6ccc5c34)c3ccccc23)cc1]

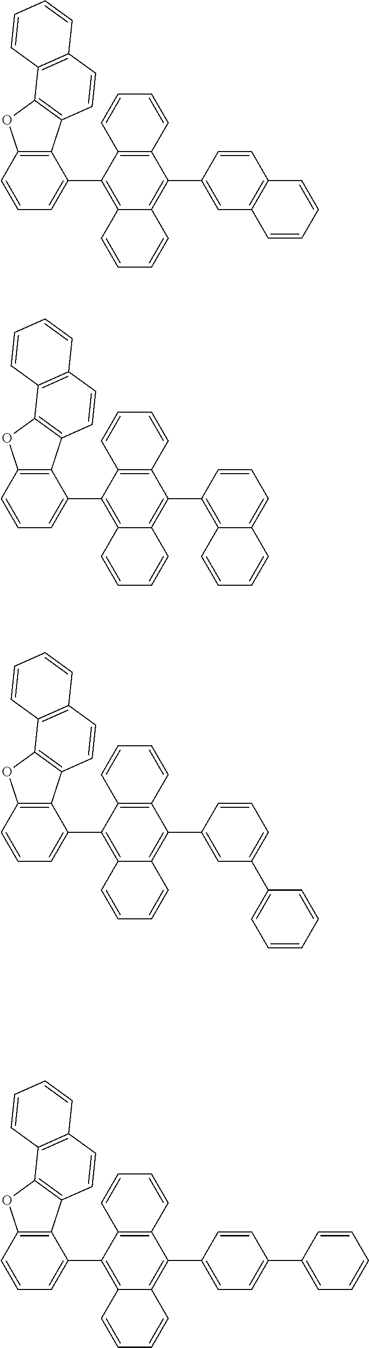 [SMILES: c1ccc2cc(-c3c4ccccc4c(-c4cccc5oc6c7ccccc7ccc6c45)c4ccccc34)ccc2c1 ; c1ccc2c(-c3c4ccccc4c(-c4cccc5oc6c7ccccc7ccc6c45)c4ccccc34)cccc2c1 ; c1ccc(-c2cccc(-c3c4ccccc4c(-c4cccc5oc6c7ccccc7ccc6c45)c4ccccc34)c2)cc1 ; c1ccc(-c2ccc(-c3c4ccccc4c(-c4cccc5oc6c7ccccc7ccc6c45)c4ccccc34)cc2)cc1]

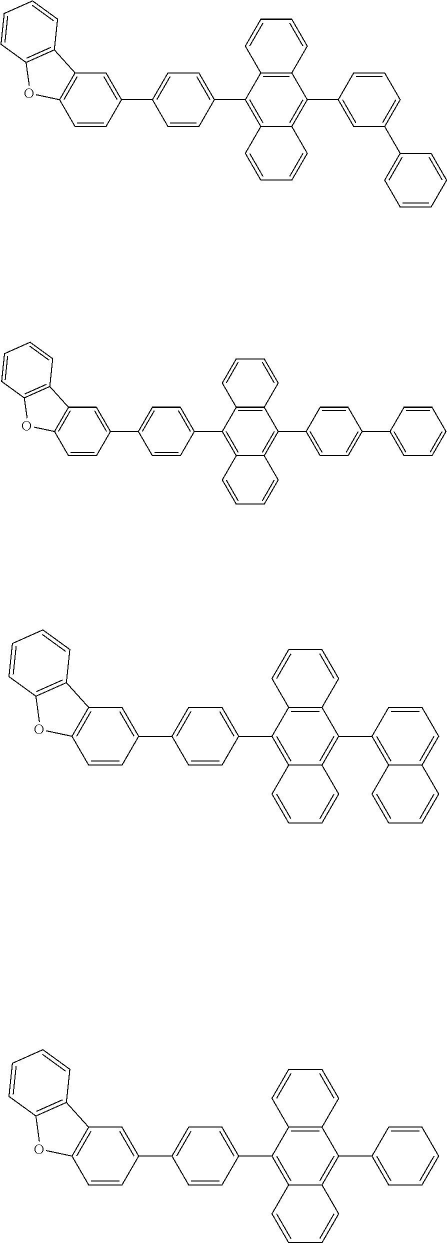 [SMILES: c1ccc(-c2cccc(-c3c4ccccc4c(-c4ccc(-c5ccc6oc7ccccc7c6c5)cc4)c4ccccc34)c2)cc1 ; c1ccc(-c2ccc(-c3c4ccccc4c(-c4ccc(-c5ccc6oc7ccccc7c6c5)cc4)c4ccccc34)cc2)cc1 ; c1ccc2c(-c3c4ccccc4c(-c4ccc(-c5ccc6oc7ccccc7c6c5)cc4)c4ccccc34)cccc2c1 ; c1ccc(-c2c3ccccc3c(-c3ccc(-c4ccc5oc6ccccc6c5c4)cc3)c3ccccc23)cc1]

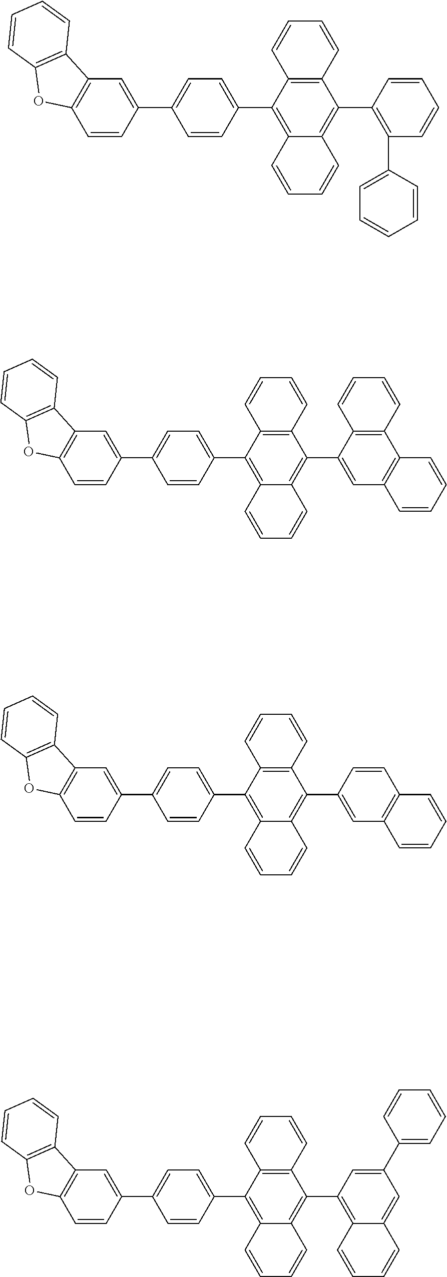 [SMILES: c1ccc(-c2ccccc2-c2c3ccccc3c(-c3ccc(-c4ccc5oc6ccccc6c5c4)cc3)c3ccccc23)cc1 ; c1ccc2c(c1)cc(-c1c3ccccc3c(-c3ccc(-c4ccc5oc6ccccc6c5c4)cc3)c3ccccc13)c1ccccc12 ; c1ccc2cc(-c3c4ccccc4c(-c4ccc(-c5ccc6oc7ccccc7c6c5)cc4)c4ccccc34)ccc2c1 ; c1ccc(-c2cc(-c3c4ccccc4c(-c4ccc(-c5ccc6oc7ccccc7c6c5)cc4)c4ccccc34)c3ccccc3c2)cc1]

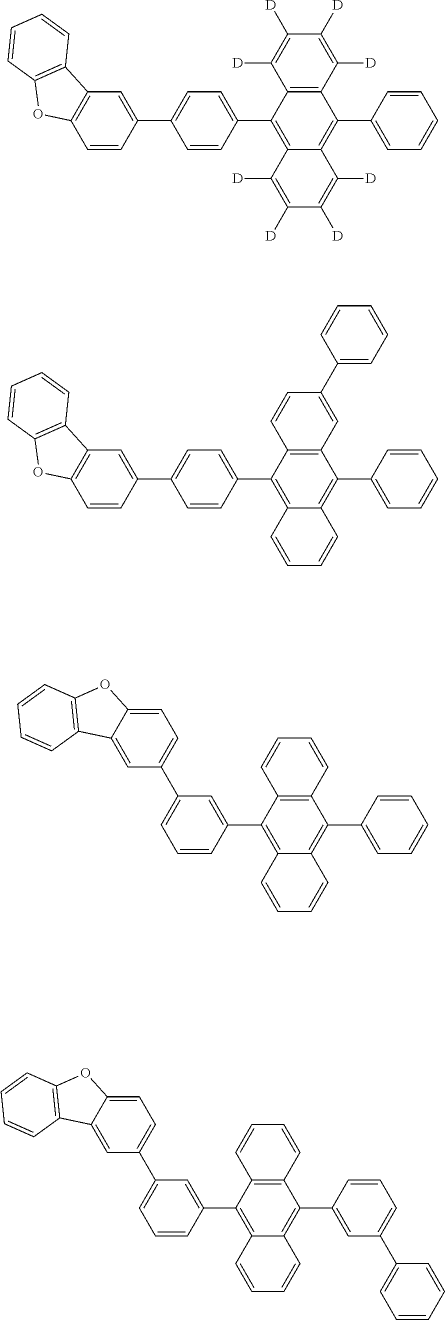 [SMILES: [2H]c1c([2H])c([2H])c2c(-c3ccc(-c4ccc5oc6ccccc6c5c4)cc3)c3c([2H])c([2H])c([2H])c([2H])c3c(-c3ccccc3)c2c1[2H] ; c1ccc(-c2ccc3c(-c4ccc(-c5ccc6oc7ccccc7c6c5)cc4)c4ccccc4c(-c4ccccc4)c3c2)cc1 ; c1ccc(-c2c3ccccc3c(-c3cccc(-c4ccc5oc6ccccc6c5c4)c3)c3ccccc23)cc1 ; c1ccc(-c2cccc(-c3c4ccccc4c(-c4cccc(-c5ccc6oc7ccccc7c6c5)c4)c4ccccc34)c2)cc1]

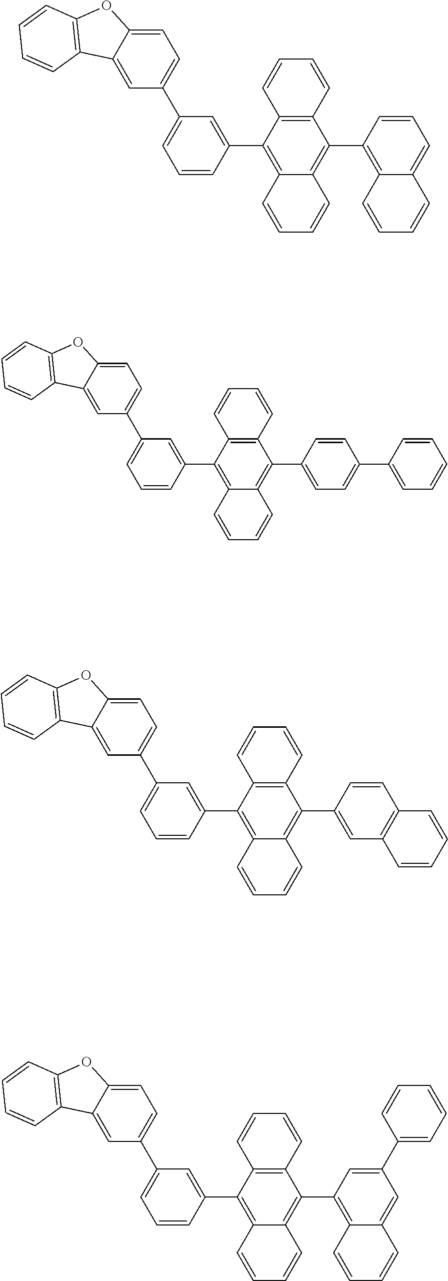 [SMILES: c1cc(-c2ccc3oc4ccccc4c3c2)cc(-c2c3ccccc3c(-c3cccc4ccccc34)c3ccccc23)c1 ; c1ccc(-c2ccc(-c3c4ccccc4c(-c4cccc(-c5ccc6oc7ccccc7c6c5)c4)c4ccccc34)cc2)cc1 ; c1cc(-c2ccc3oc4ccccc4c3c2)cc(-c2c3ccccc3c(-c3ccc4ccccc4c3)c3ccccc23)c1 ; c1ccc(-c2cc(-c3c4ccccc4c(-c4cccc(-c5ccc6oc7ccccc7c6c5)c4)c4ccccc34)c3ccccc3c2)cc1]

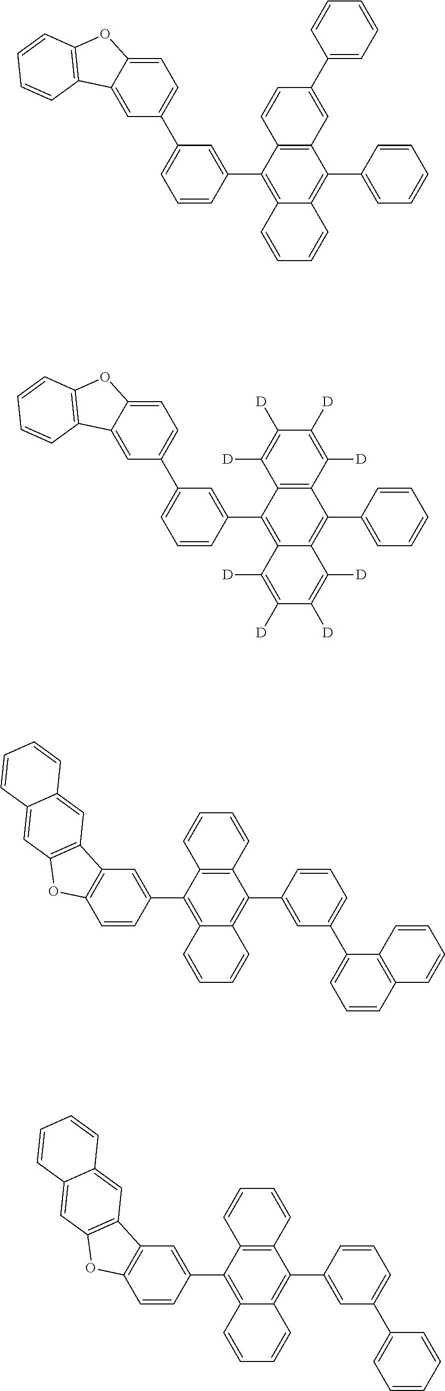 [SMILES: c1ccc(-c2ccc3c(-c4cccc(-c5ccc6oc7ccccc7c6c5)c4)c4ccccc4c(-c4ccccc4)c3c2)cc1 ; [2H]c1c([2H])c([2H])c2c(-c3cccc(-c4ccc5oc6ccccc6c5c4)c3)c3c([2H])c([2H])c([2H])c([2H])c3c(-c3ccccc3)c2c1[2H] ; c1cc(-c2cccc3ccccc23)cc(-c2c3ccccc3c(-c3ccc4oc5cc6ccccc6cc5c4c3)c3ccccc23)c1 ; c1ccc(-c2cccc(-c3c4ccccc4c(-c4ccc5oc6cc7ccccc7cc6c5c4)c4ccccc34)c2)cc1]

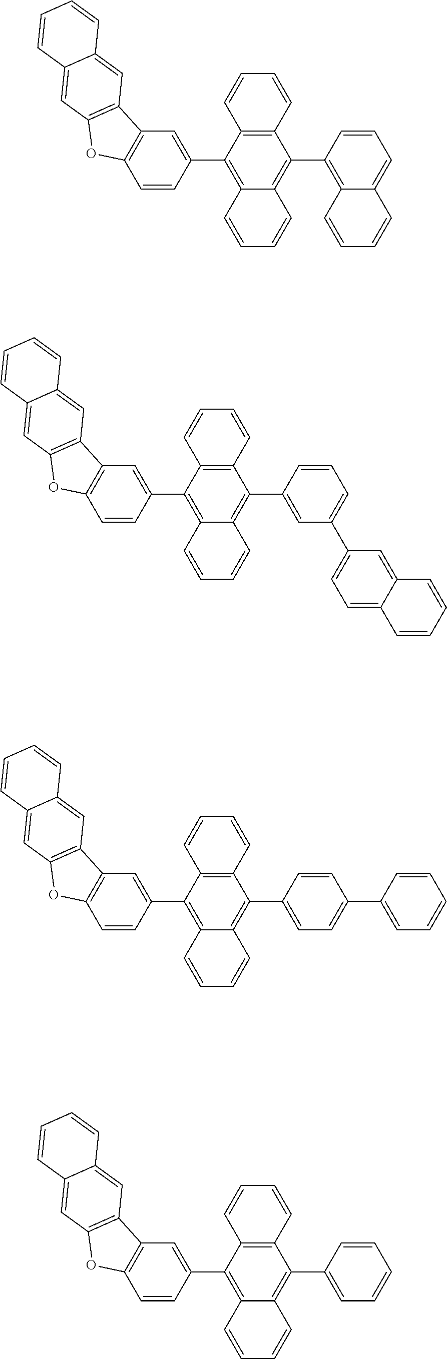 [SMILES: c1ccc2cc3c(cc2c1)oc1ccc(-c2c4ccccc4c(-c4cccc5ccccc45)c4ccccc24)cc13 ; c1cc(-c2ccc3ccccc3c2)cc(-c2c3ccccc3c(-c3ccc4oc5cc6ccccc6cc5c4c3)c3ccccc23)c1 ; c1ccc(-c2ccc(-c3c4ccccc4c(-c4ccc5oc6cc7ccccc7cc6c5c4)c4ccccc34)cc2)cc1 ; c1ccc(-c2c3ccccc3c(-c3ccc4oc5cc6ccccc6cc5c4c3)c3ccccc23)cc1]

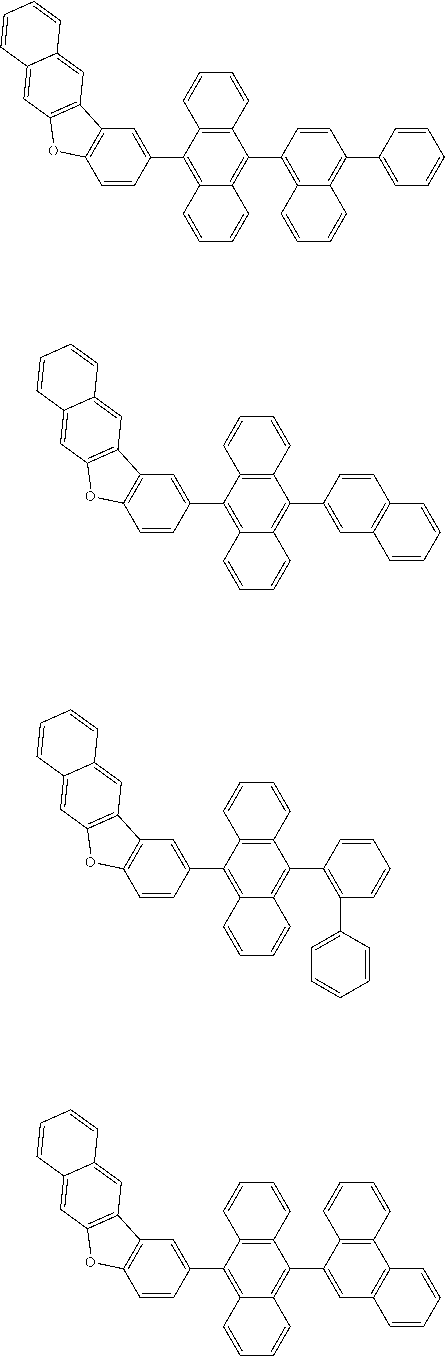 [SMILES: c1ccc(-c2ccc(-c3c4ccccc4c(-c4ccc5oc6cc7ccccc7cc6c5c4)c4ccccc34)c3ccccc23)cc1 ; c1ccc2cc(-c3c4ccccc4c(-c4ccc5oc6cc7ccccc7cc6c5c4)c4ccccc34)ccc2c1 ; c1ccc(-c2ccccc2-c2c3ccccc3c(-c3ccc4oc5cc6ccccc6cc5c4c3)c3ccccc23)cc1 ; c1ccc2cc3c(cc2c1)oc1ccc(-c2c4ccccc4c(-c4cc5ccccc5c5ccccc45)c4ccccc24)cc13]

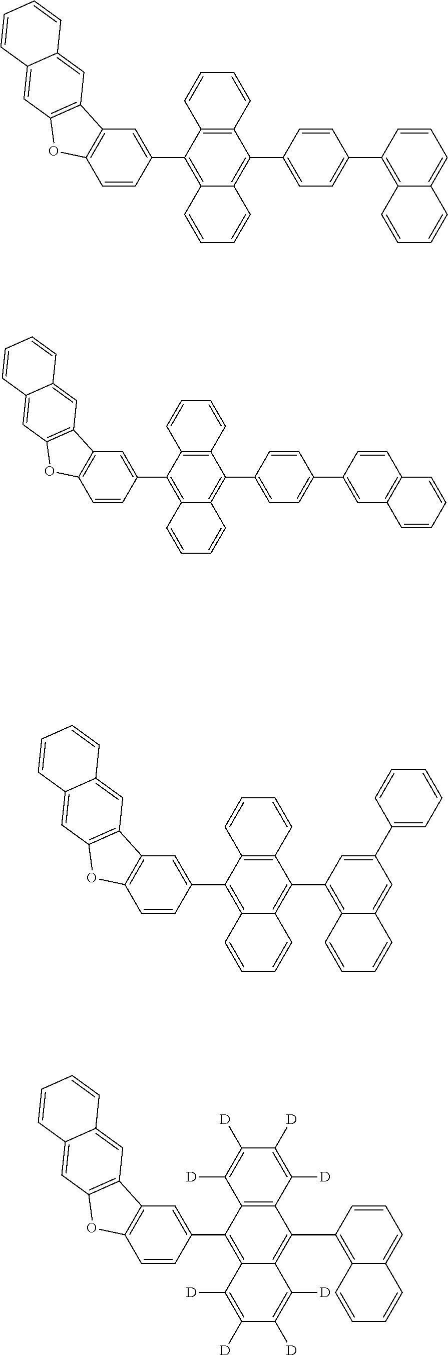 [SMILES: c1ccc2cc3c(cc2c1)oc1ccc(-c2c4ccccc4c(-c4ccc(-c5cccc6ccccc56)cc4)c4ccccc24)cc13 ; c1ccc2cc(-c3ccc(-c4c5ccccc5c(-c5ccc6oc7cc8ccccc8cc7c6c5)c5ccccc45)cc3)ccc2c1 ; c1ccc(-c2cc(-c3c4ccccc4c(-c4ccc5oc6cc7ccccc7cc6c5c4)c4ccccc34)c3ccccc3c2)cc1 ; [2H]c1c([2H])c([2H])c2c(-c3cccc4ccccc34)c3c([2H])c([2H])c([2H])c([2H])c3c(-c3ccc4oc5cc6ccccc6cc5c4c3)c2c1[2H]]

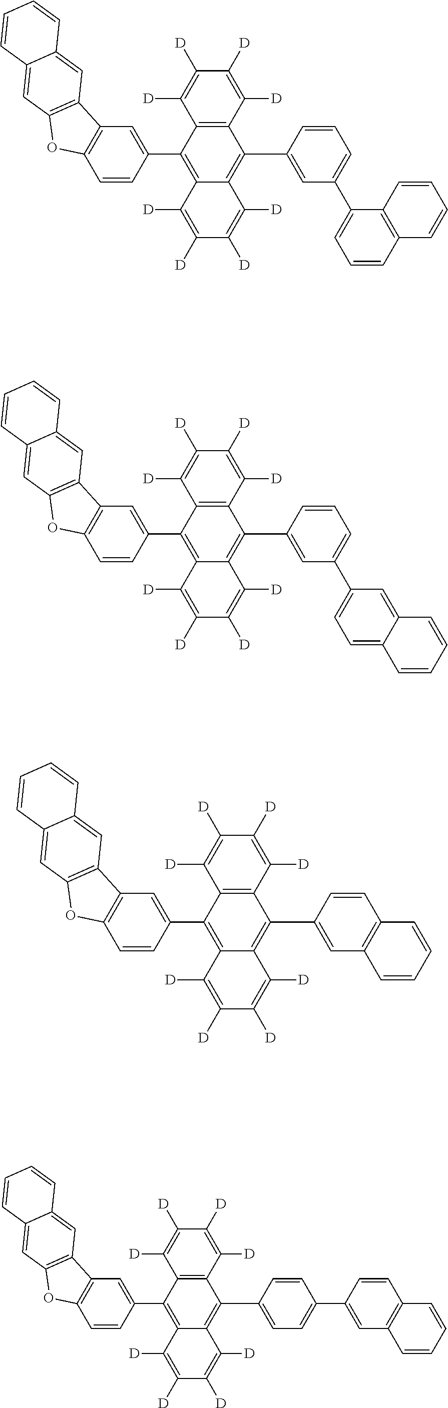 [SMILES: [2H]c1c([2H])c([2H])c2c(-c3ccc4oc5cc6ccccc6cc5c4c3)c3c([2H])c([2H])c([2H])c([2H])c3c(-c3cccc(-c4cccc5ccccc45)c3)c2c1[2H] ; [2H]c1c([2H])c([2H])c2c(-c3ccc4oc5cc6ccccc6cc5c4c3)c3c([2H])c([2H])c([2H])c([2H])c3c(-c3cccc(-c4ccc5ccccc5c4)c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccc4ccccc4c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccc(-c4ccc5ccccc5c4)cc3)c2c1[2H]]

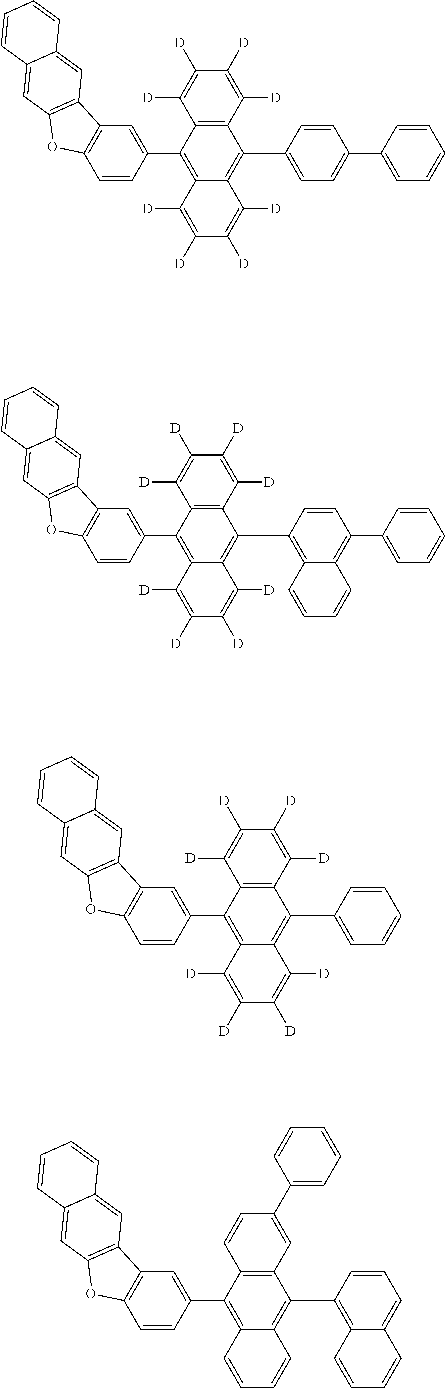 [SMILES: [2H]c1c([2H])c([2H])c2c(-c3ccc4oc5cc6ccccc6cc5c4c3)c3c([2H])c([2H])c([2H])c([2H])c3c(-c3ccc(-c4ccccc4)cc3)c2c1[2H] ; [2H]c1c([2H])c([2H])c2c(-c3ccc(-c4ccccc4)c4ccccc34)c3c([2H])c([2H])c([2H])c([2H])c3c(-c3ccc4oc5cc6ccccc6cc5c4c3)c2c1[2H] ; [2H]c1c([2H])c([2H])c2c(-c3ccc4oc5cc6ccccc6cc5c4c3)c3c([2H])c([2H])c([2H])c([2H])c3c(-c3ccccc3)c2c1[2H] ; c1ccc(-c2ccc3c(-c4ccc5oc6cc7ccccc7cc6c5c4)c4ccccc4c(-c4cccc5ccccc45)c3c2)cc1]

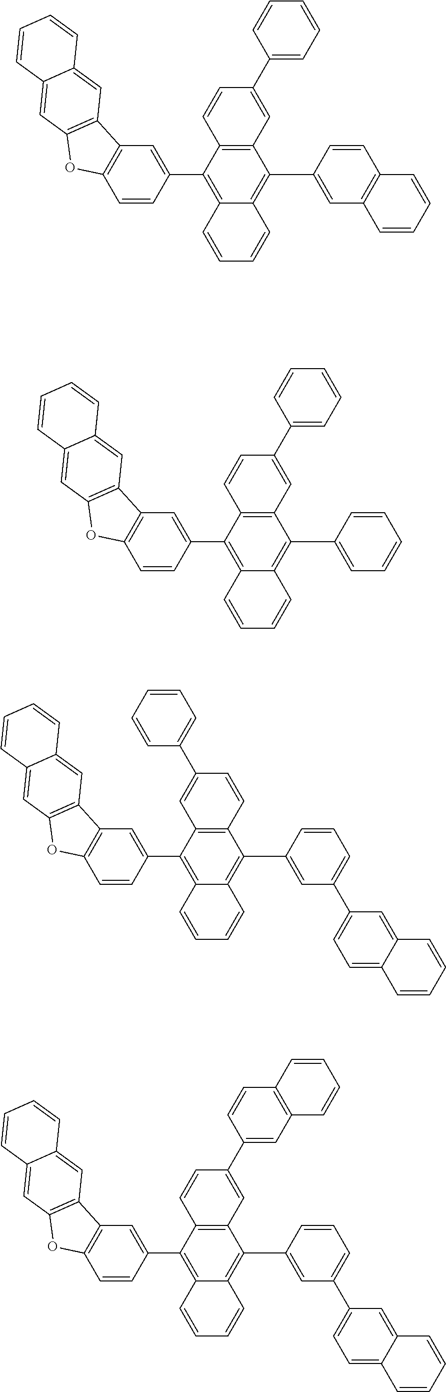 [SMILES: c1ccc(-c2ccc3c(-c4ccc5oc6cc7ccccc7cc6c5c4)c4ccccc4c(-c4ccc5ccccc5c4)c3c2)cc1 ; c1ccc(-c2ccc3c(-c4ccc5oc6cc7ccccc7cc6c5c4)c4ccccc4c(-c4ccccc4)c3c2)cc1 ; c1ccc(-c2ccc3c(-c4cccc(-c5ccc6ccccc6c5)c4)c4ccccc4c(-c4ccc5oc6cc7ccccc7cc6c5c4)c3c2)cc1 ; c1cc(-c2ccc3ccccc3c2)cc(-c2c3ccccc3c(-c3ccc4oc5cc6ccccc6cc5c4c3)c3ccc(-c4ccc5ccccc5c4)cc23)c1]

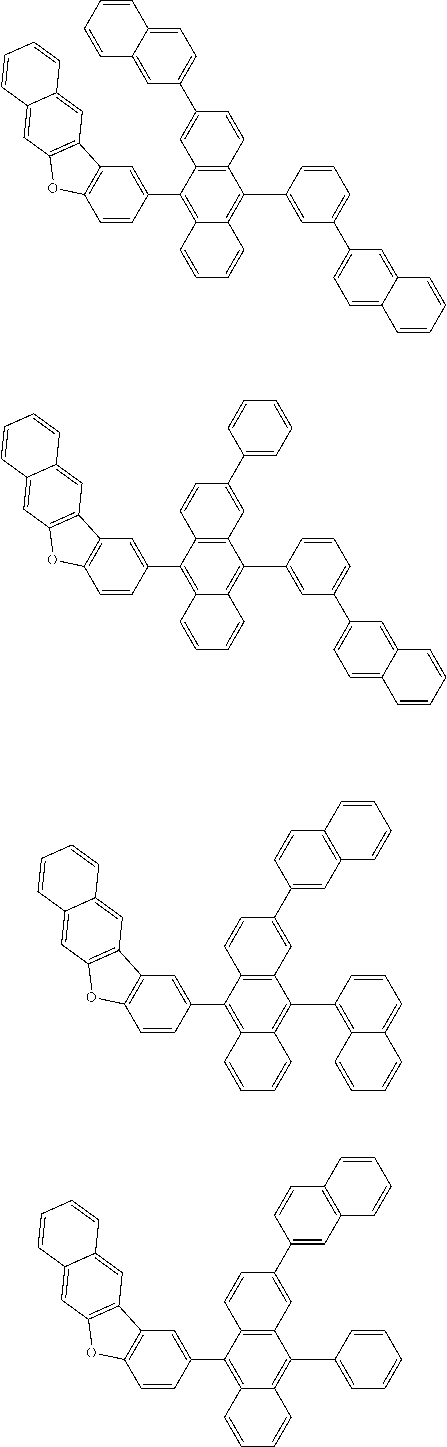 [SMILES: c1cc(-c2ccc3ccccc3c2)cc(-c2c3ccccc3c(-c3ccc4oc5cc6ccccc6cc5c4c3)c3cc(-c4ccc5ccccc5c4)ccc23)c1 ; c1ccc(-c2ccc3c(-c4ccc5oc6cc7ccccc7cc6c5c4)c4ccccc4c(-c4cccc(-c5ccc6ccccc6c5)c4)c3c2)cc1 ; c1ccc2cc(-c3ccc4c(-c5ccc6oc7cc8ccccc8cc7c6c5)c5ccccc5c(-c5cccc6ccccc56)c4c3)ccc2c1 ; c1ccc(-c2c3ccccc3c(-c3ccc4oc5cc6ccccc6cc5c4c3)c3ccc(-c4ccc5ccccc5c4)cc23)cc1]

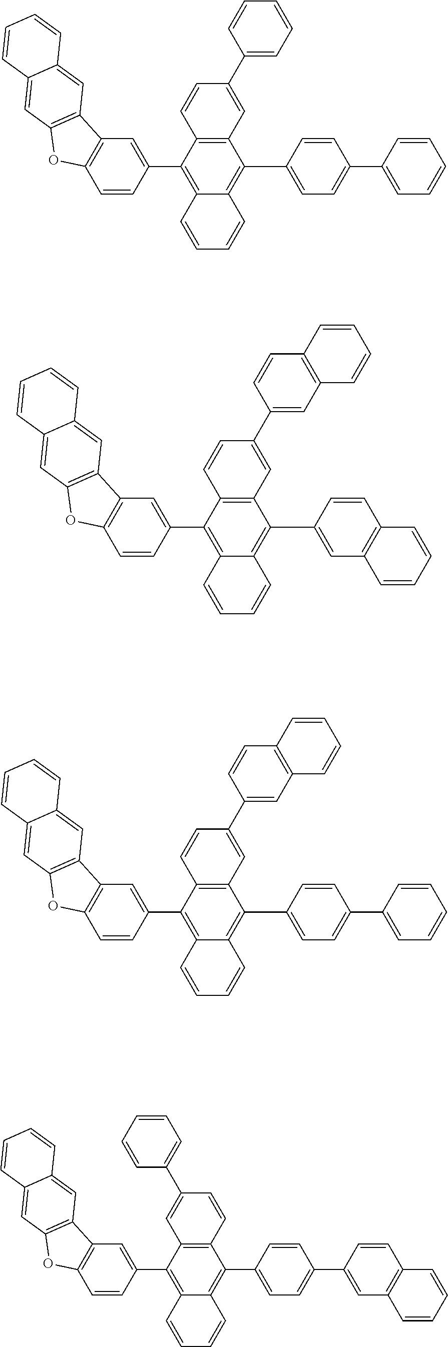 [SMILES: c1ccc(-c2ccc(-c3c4ccccc4c(-c4ccc5oc6cc7ccccc7cc6c5c4)c4ccc(-c5ccccc5)cc34)cc2)cc1 ; c1ccc2cc(-c3ccc4c(-c5ccc6oc7cc8ccccc8cc7c6c5)c5ccccc5c(-c5ccc6ccccc6c5)c4c3)ccc2c1 ; c1ccc(-c2ccc(-c3c4ccccc4c(-c4ccc5oc6cc7ccccc7cc6c5c4)c4ccc(-c5ccc6ccccc6c5)cc34)cc2)cc1 ; c1ccc(-c2ccc3c(-c4ccc(-c5ccc6ccccc6c5)cc4)c4ccccc4c(-c4ccc5oc6cc7ccccc7cc6c5c4)c3c2)cc1]

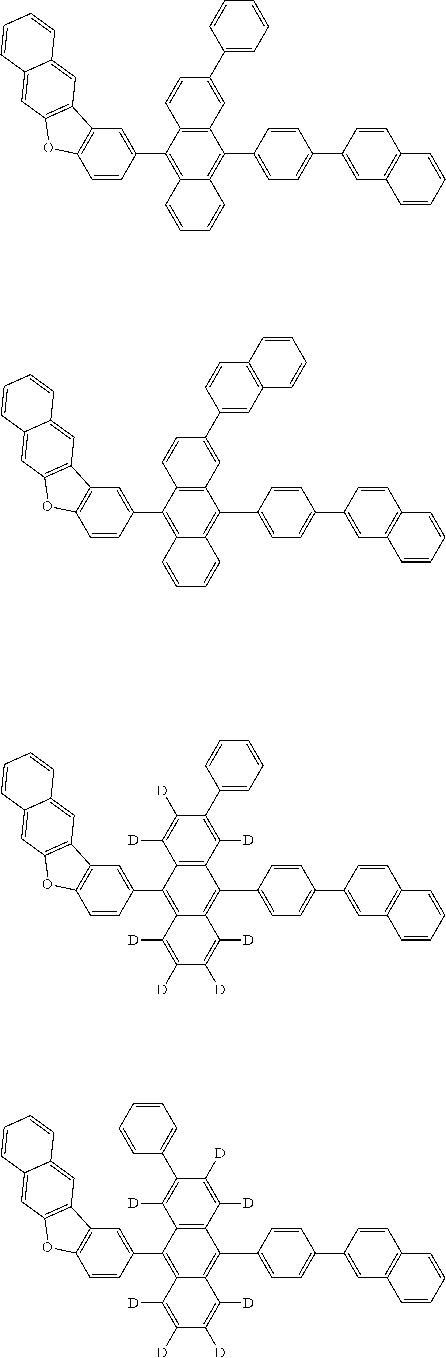 [SMILES: c1ccc(-c2ccc3c(-c4ccc5oc6cc7ccccc7cc6c5c4)c4ccccc4c(-c4ccc(-c5ccc6ccccc6c5)cc4)c3c2)cc1 ; c1ccc2cc(-c3ccc(-c4c5ccccc5c(-c5ccc6oc7cc8ccccc8cc7c6c5)c5ccc(-c6ccc7ccccc7c6)cc45)cc3)ccc2c1 ; [2H]c1c([2H])c([2H])c2c(-c3ccc(-c4ccc5ccccc5c4)cc3)c3c([2H])c(-c4ccccc4)c([2H])c([2H])c3c(-c3ccc4oc5cc6ccccc6cc5c4c3)c2c1[2H] ; [2H]c1c([2H])c([2H])c2c(-c3ccc4oc5cc6ccccc6cc5c4c3)c3c([2H])c(-c4ccccc4)c([2H])c([2H])c3c(-c3ccc(-c4ccc5ccccc5c4)cc3)c2c1[2H]]

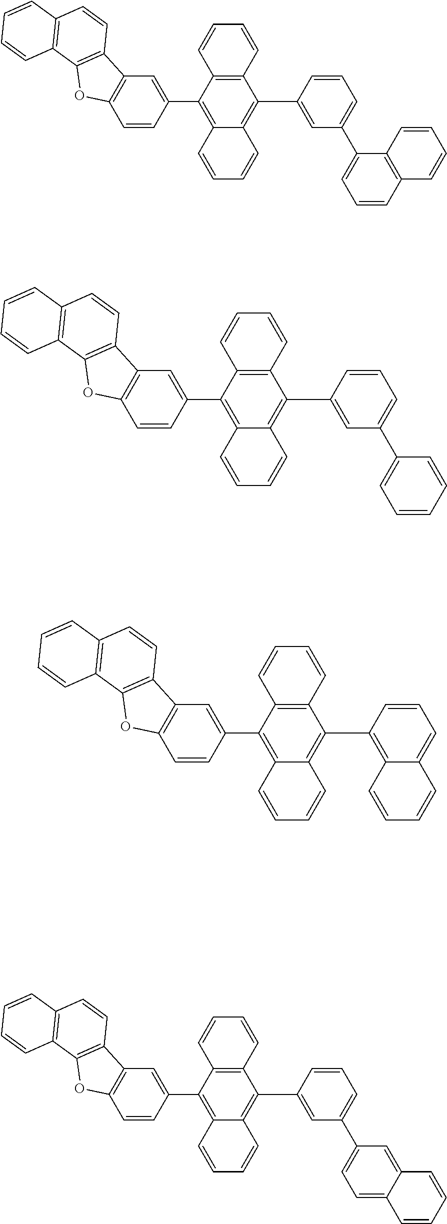 [SMILES: c1cc(-c2cccc3ccccc23)cc(-c2c3ccccc3c(-c3ccc4oc5c6ccccc6ccc5c4c3)c3ccccc23)c1 ; c1ccc(-c2cccc(-c3c4ccccc4c(-c4ccc5oc6c7ccccc7ccc6c5c4)c4ccccc34)c2)cc1 ; c1ccc2c(-c3c4ccccc4c(-c4ccc5oc6c7ccccc7ccc6c5c4)c4ccccc34)cccc2c1 ; c1cc(-c2ccc3ccccc3c2)cc(-c2c3ccccc3c(-c3ccc4oc5c6ccccc6ccc5c4c3)c3ccccc23)c1]

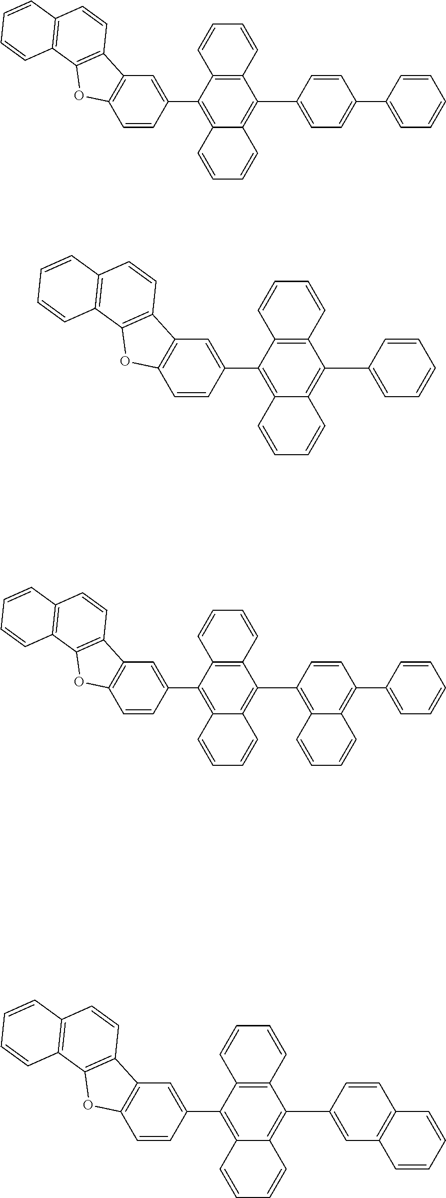 [SMILES: c1ccc(-c2ccc(-c3c4ccccc4c(-c4ccc5oc6c7ccccc7ccc6c5c4)c4ccccc34)cc2)cc1 ; c1ccc(-c2c3ccccc3c(-c3ccc4oc5c6ccccc6ccc5c4c3)c3ccccc23)cc1 ; c1ccc(-c2ccc(-c3c4ccccc4c(-c4ccc5oc6c7ccccc7ccc6c5c4)c4ccccc34)c3ccccc23)cc1 ; c1ccc2cc(-c3c4ccccc4c(-c4ccc5oc6c7ccccc7ccc6c5c4)c4ccccc34)ccc2c1]

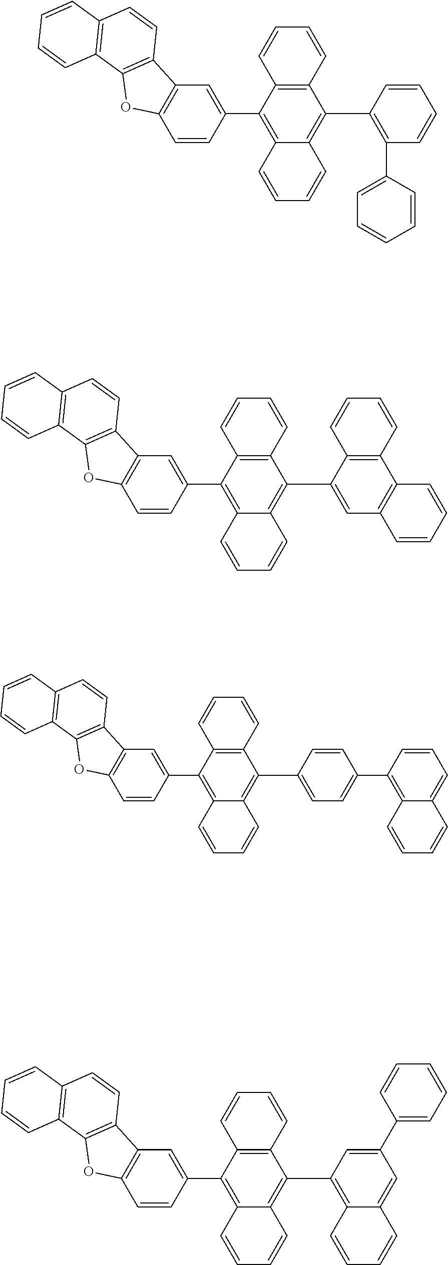 [SMILES: c1ccc(-c2ccccc2-c2c3ccccc3c(-c3ccc4oc5c6ccccc6ccc5c4c3)c3ccccc23)cc1 ; c1ccc2c(c1)cc(-c1c3ccccc3c(-c3ccc4oc5c6ccccc6ccc5c4c3)c3ccccc13)c1ccccc12 ; c1ccc2c(-c3ccc(-c4c5ccccc5c(-c5ccc6oc7c8ccccc8ccc7c6c5)c5ccccc45)cc3)cccc2c1 ; c1ccc(-c2cc(-c3c4ccccc4c(-c4ccc5oc6c7ccccc7ccc6c5c4)c4ccccc34)c3ccccc3c2)cc1]

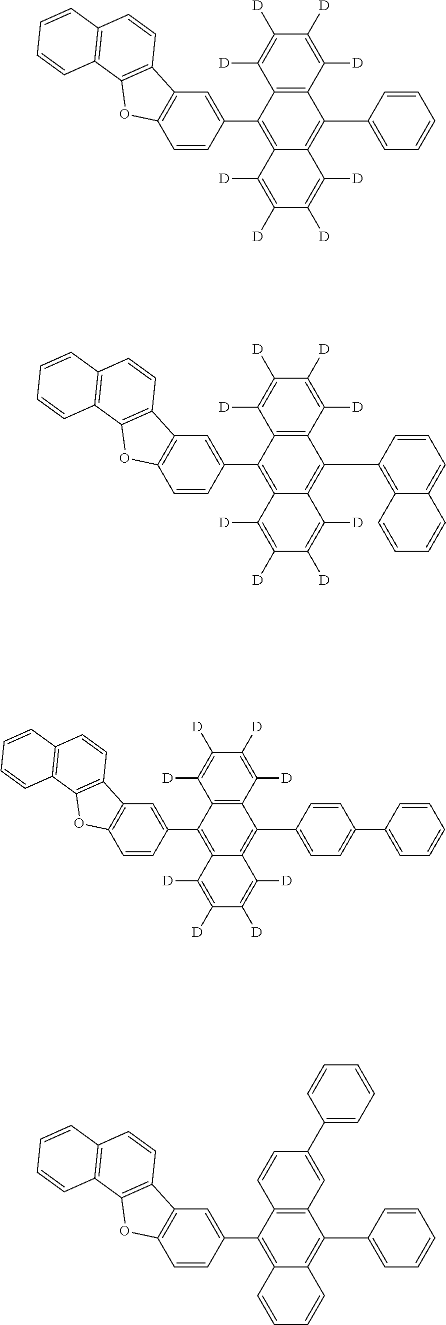 [SMILES: [2H]c1c([2H])c([2H])c2c(-c3ccc4oc5c6ccccc6ccc5c4c3)c3c([2H])c([2H])c([2H])c([2H])c3c(-c3ccccc3)c2c1[2H] ; [2H]c1c([2H])c([2H])c2c(-c3cccc4ccccc34)c3c([2H])c([2H])c([2H])c([2H])c3c(-c3ccc4oc5c6ccccc6ccc5c4c3)c2c1[2H] ; [2H]c1c([2H])c([2H])c2c(-c3ccc4oc5c6ccccc6ccc5c4c3)c3c([2H])c([2H])c([2H])c([2H])c3c(-c3ccc(-c4ccccc4)cc3)c2c1[2H] ; c1ccc(-c2ccc3c(-c4ccc5oc6c7ccccc7ccc6c5c4)c4ccccc4c(-c4ccccc4)c3c2)cc1]

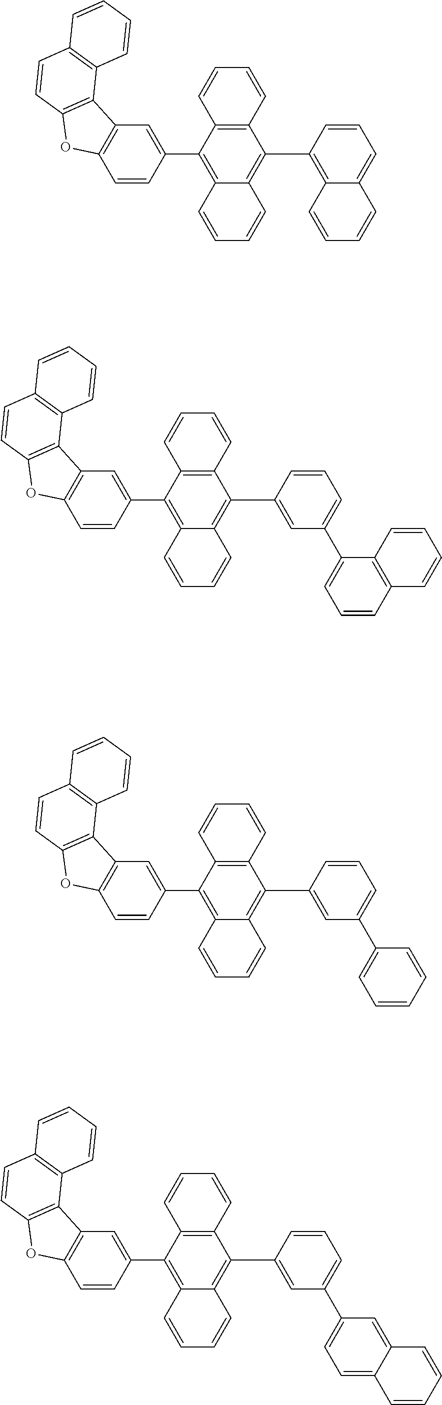 [SMILES: c1ccc2c(-c3c4ccccc4c(-c4ccc5oc6ccc7ccccc7c6c5c4)c4ccccc34)cccc2c1 ; c1cc(-c2cccc3ccccc23)cc(-c2c3ccccc3c(-c3ccc4oc5ccc6ccccc6c5c4c3)c3ccccc23)c1 ; c1ccc(-c2cccc(-c3c4ccccc4c(-c4ccc5oc6ccc7ccccc7c6c5c4)c4ccccc34)c2)cc1 ; c1cc(-c2ccc3ccccc3c2)cc(-c2c3ccccc3c(-c3ccc4oc5ccc6ccccc6c5c4c3)c3ccccc23)c1]

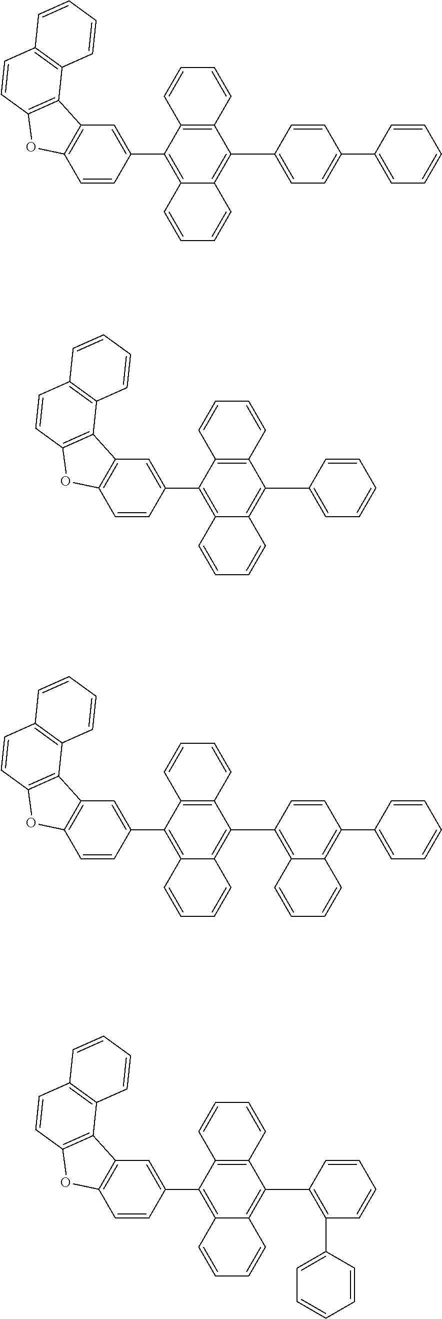 [SMILES: c1ccc(-c2ccc(-c3c4ccccc4c(-c4ccc5oc6ccc7ccccc7c6c5c4)c4ccccc34)cc2)cc1 ; c1ccc(-c2c3ccccc3c(-c3ccc4oc5ccc6ccccc6c5c4c3)c3ccccc23)cc1 ; c1ccc(-c2ccc(-c3c4ccccc4c(-c4ccc5oc6ccc7ccccc7c6c5c4)c4ccccc34)c3ccccc23)cc1 ; c1ccc(-c2ccccc2-c2c3ccccc3c(-c3ccc4oc5ccc6ccccc6c5c4c3)c3ccccc23)cc1]

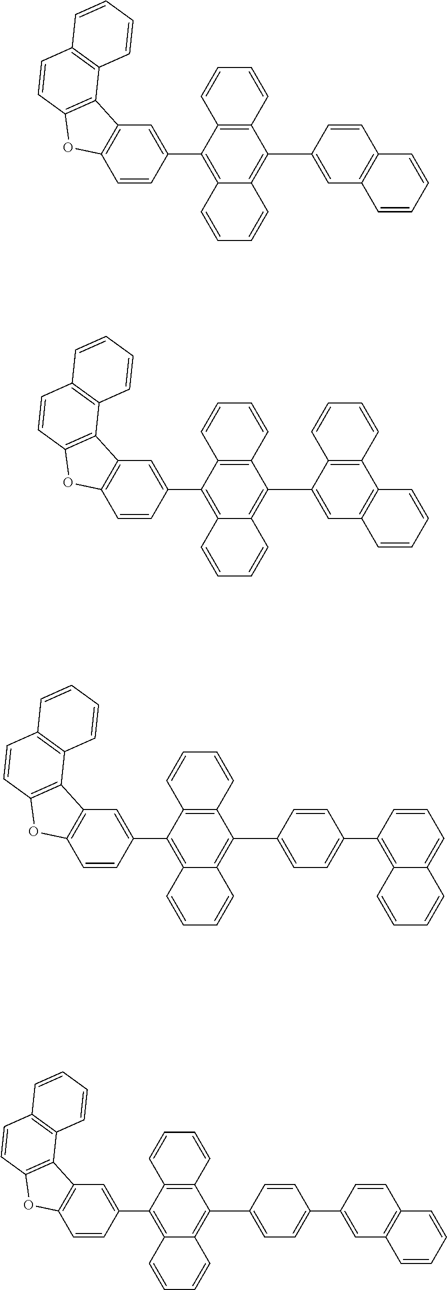 [SMILES: c1ccc2cc(-c3c4ccccc4c(-c4ccc5oc6ccc7ccccc7c6c5c4)c4ccccc34)ccc2c1 ; c1ccc2c(c1)cc(-c1c3ccccc3c(-c3ccc4oc5ccc6ccccc6c5c4c3)c3ccccc13)c1ccccc12 ; c1ccc2c(-c3ccc(-c4c5ccccc5c(-c5ccc6oc7ccc8ccccc8c7c6c5)c5ccccc45)cc3)cccc2c1 ; c1ccc2cc(-c3ccc(-c4c5ccccc5c(-c5ccc6oc7ccc8ccccc8c7c6c5)c5ccccc45)cc3)ccc2c1]

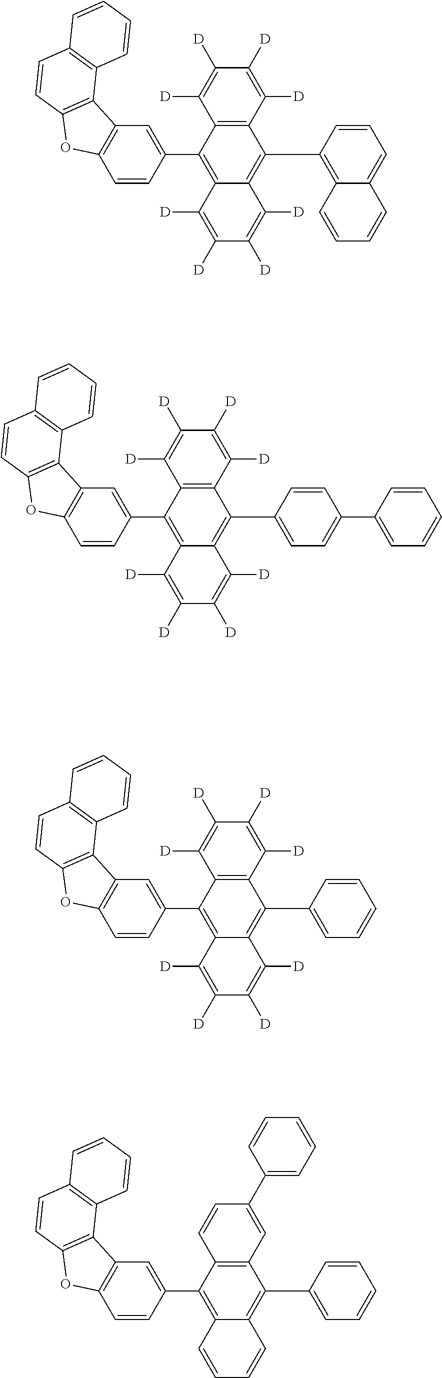 [SMILES: [2H]c1c([2H])c([2H])c2c(-c3cccc4ccccc34)c3c([2H])c([2H])c([2H])c([2H])c3c(-c3ccc4oc5ccc6ccccc6c5c4c3)c2c1[2H] ; [2H]c1c([2H])c([2H])c2c(-c3ccc4oc5ccc6ccccc6c5c4c3)c3c([2H])c([2H])c([2H])c([2H])c3c(-c3ccc(-c4ccccc4)cc3)c2c1[2H] ; [2H]c1c([2H])c([2H])c2c(-c3ccc4oc5ccc6ccccc6c5c4c3)c3c([2H])c([2H])c([2H])c([2H])c3c(-c3ccccc3)c2c1[2H] ; c1ccc(-c2ccc3c(-c4ccc5oc6ccc7ccccc7c6c5c4)c4ccccc4c(-c4ccccc4)c3c2)cc1]

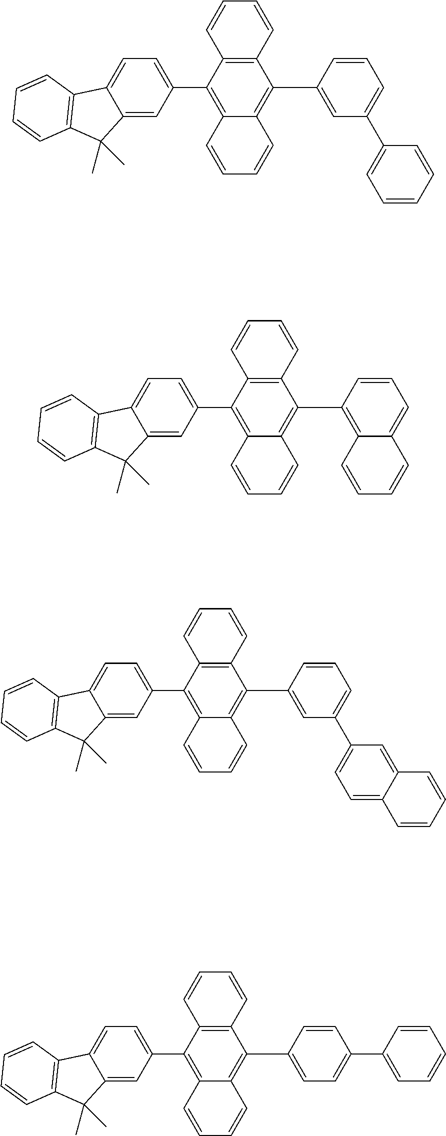

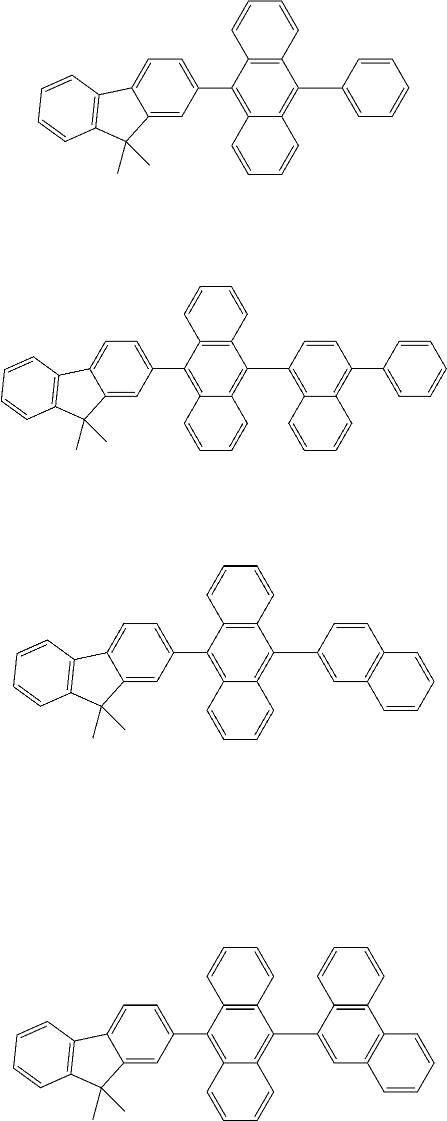

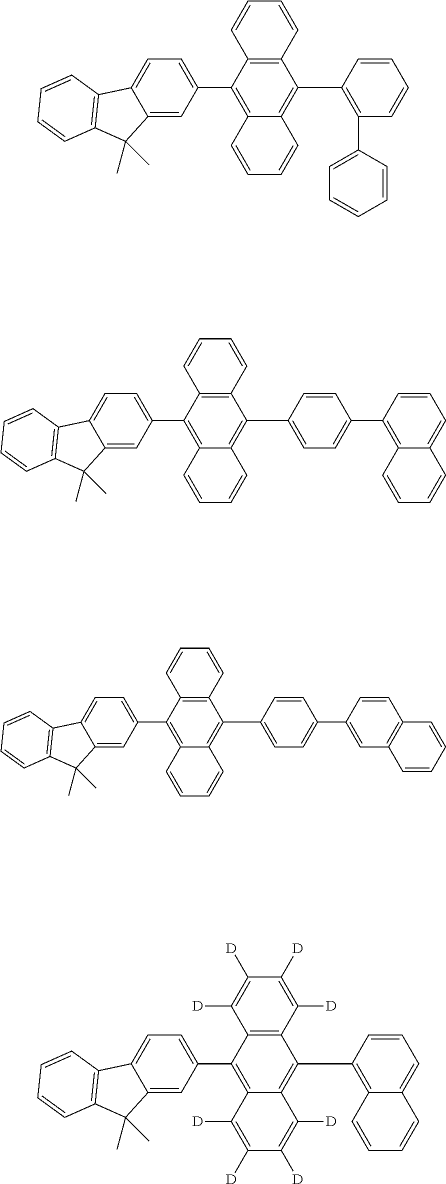

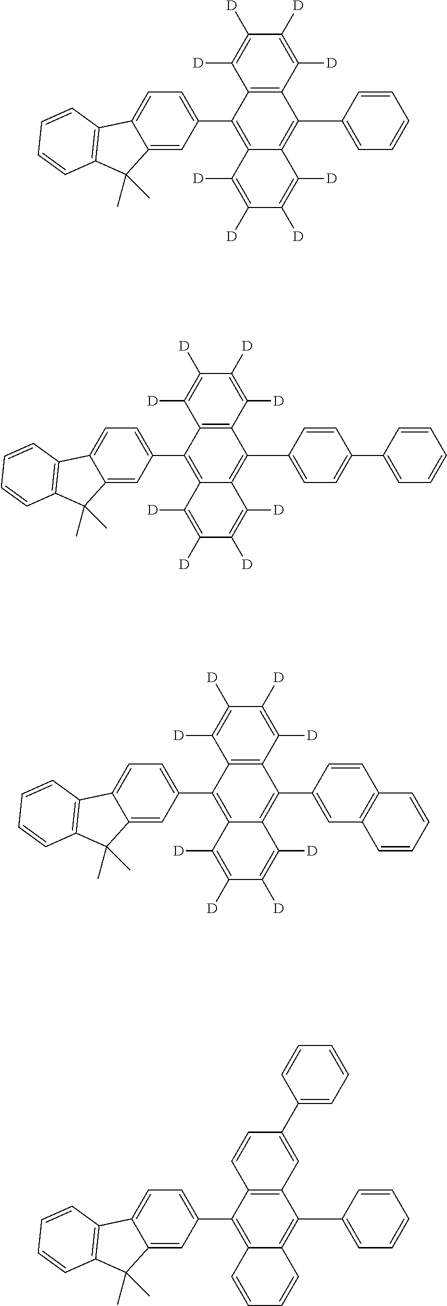

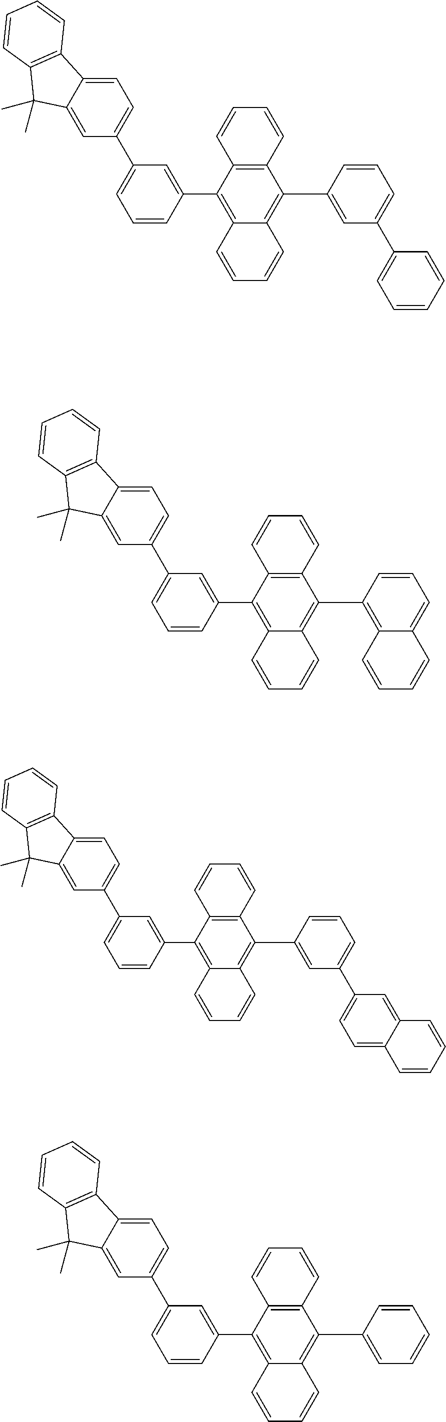

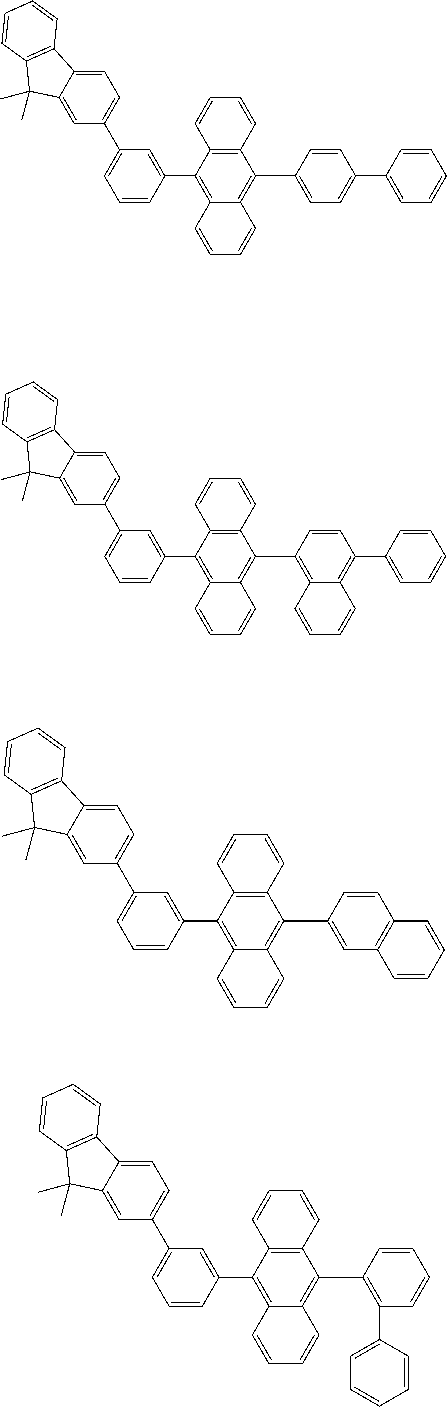

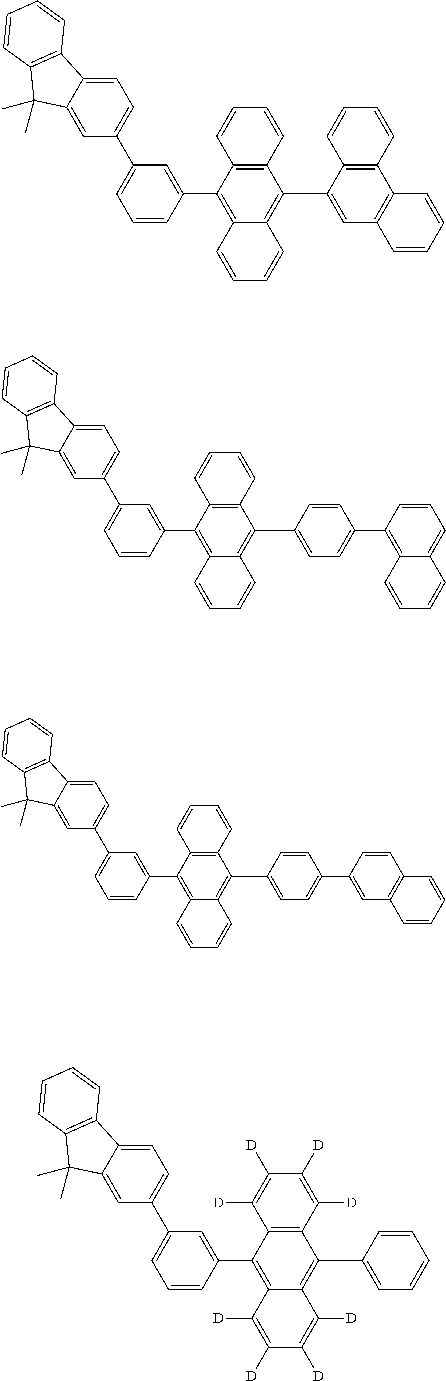

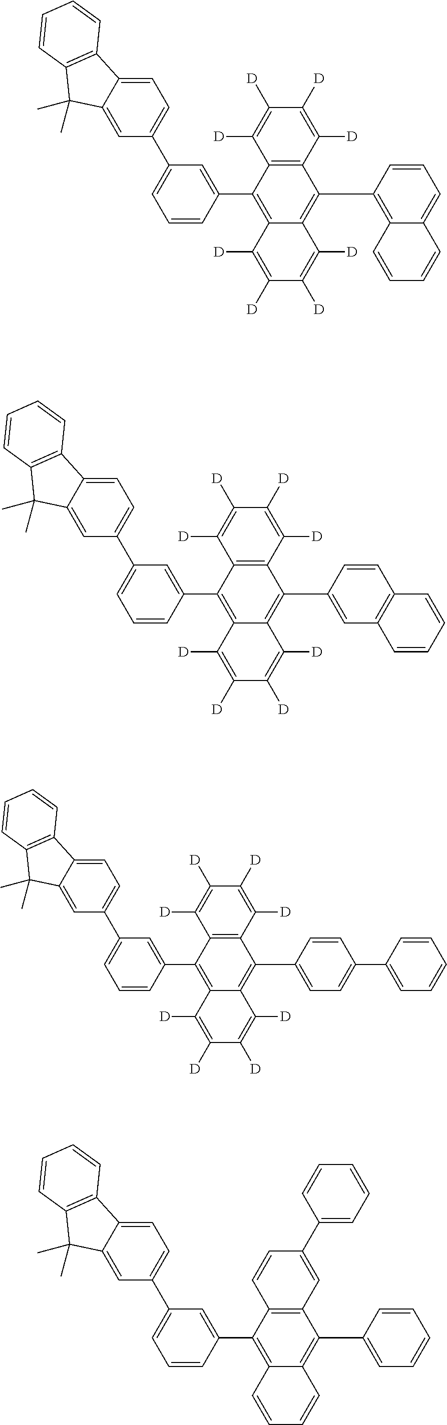

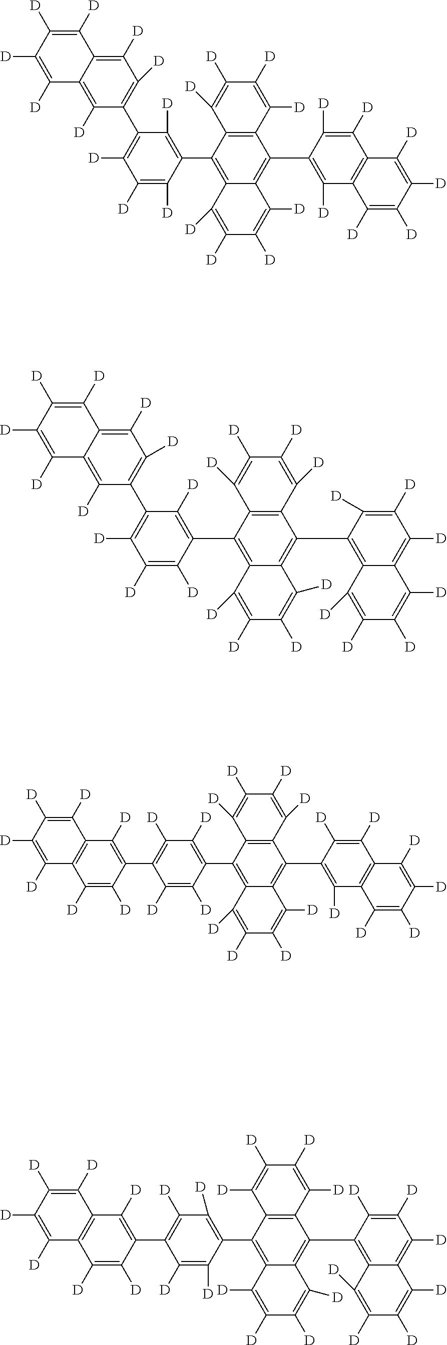

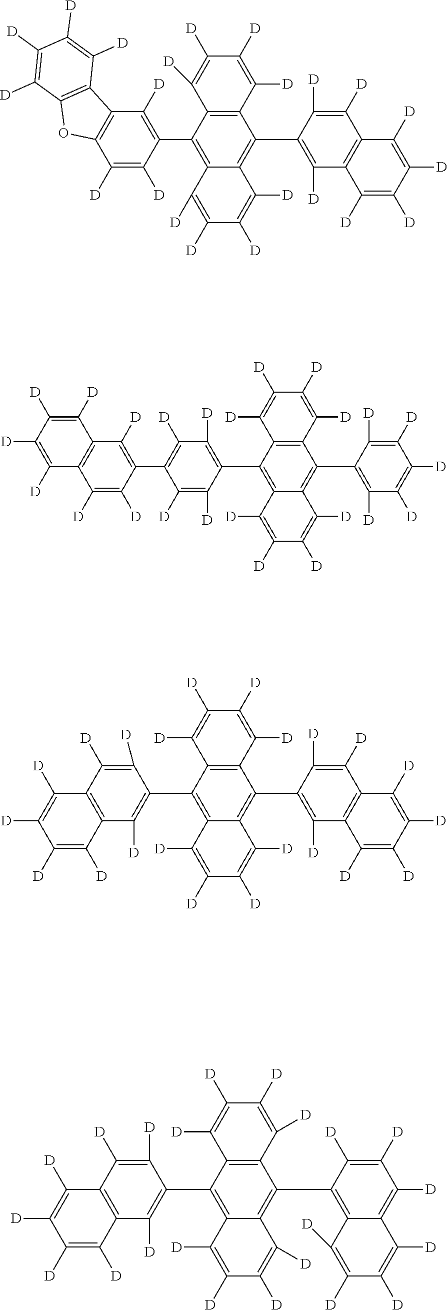

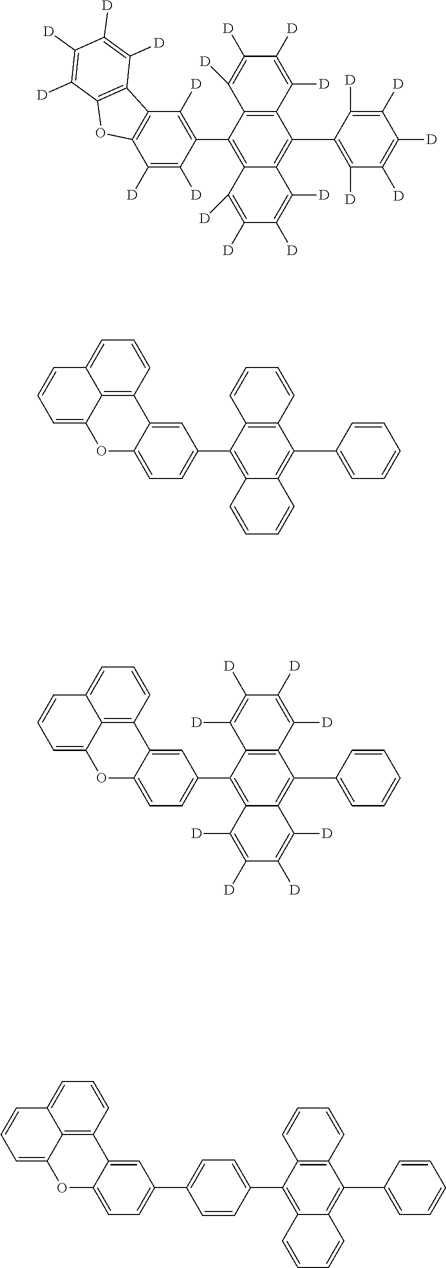 [SMILES: [2H]c1c([2H])c([2H])c(-c2c3c([2H])c([2H])c([2H])c([2H])c3c(-c3c([2H])c([2H])c4oc5c([2H])c([2H])c([2H])c([2H])c5c4c3[2H])c3c([2H])c([2H])c([2H])c([2H])c23)c([2H])c1[2H] ; c1ccc(-c2c3ccccc3c(-c3ccc4c(c3)-c3cccc5cccc(c35)O4)c3ccccc23)cc1 ; [2H]c1c([2H])c([2H])c2c(-c3ccc4c(c3)-c3cccc5cccc(c35)O4)c3c([2H])c([2H])c([2H])c([2H])c3c(-c3ccccc3)c2c1[2H] ; c1ccc(-c2c3ccccc3c(-c3ccc(-c4ccc5c(c4)-c4cccc6cccc(c46)O5)cc3)c3ccccc23)cc1]

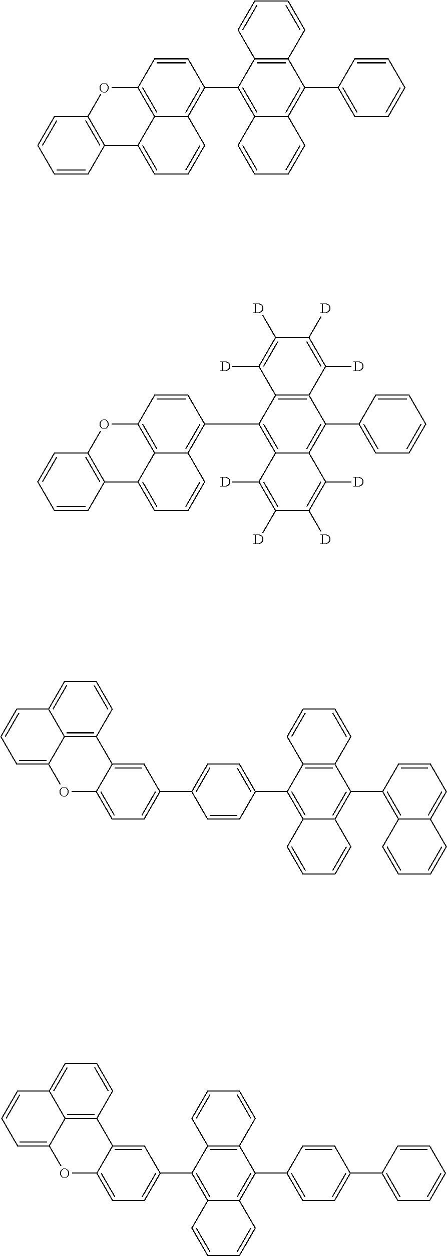 [SMILES: c1ccc(-c2c3ccccc3c(-c3ccc4c5c(cccc35)-c3ccccc3O4)c3ccccc23)cc1 ; [2H]c1c([2H])c([2H])c2c(-c3ccc4c5c(cccc35)-c3ccccc3O4)c3c([2H])c([2H])c([2H])c([2H])c3c(-c3ccccc3)c2c1[2H] ; c1ccc2c(-c3c4ccccc4c(-c4ccc(-c5ccc6c(c5)-c5cccc7cccc(c57)O6)cc4)c4ccccc34)cccc2c1 ; c1ccc(-c2ccc(-c3c4ccccc4c(-c4ccc5c(c4)-c4cccc6cccc(c46)O5)c4ccccc34)cc2)cc1]

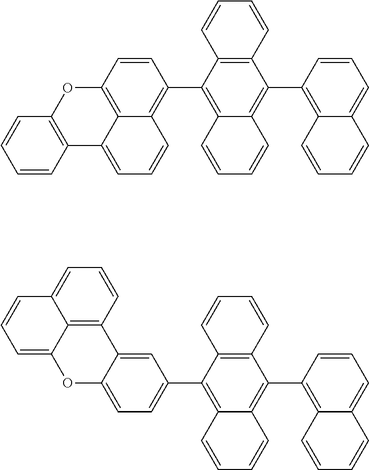 [SMILES: c1ccc2c(c1)Oc1ccc(-c3c4ccccc4c(-c4cccc5ccccc45)c4ccccc34)c3cccc-2c13 ; c1ccc2c(-c3c4ccccc4c(-c4ccc5c(c4)-c4cccc6cccc(c46)O5)c4ccccc34)cccc2c1]

### (Organic EL Device)

The organic EL device according to an aspect of the invention has a cathode, an anode, an emitting layer disposed between the cathode and the anode, and a layer (first layer) disposed between the emitting layer and the cathode, wherein the first layer contains a first compound and a second compound.

The ratio of the first compound to the second compound in the first layer is not particularly limited, and in one embodiment, the mass ratio (first compound:second compound) is within a range of 10:90 to 90:10.

In one embodiment, the mass ratio of the first compound to the second compound (the first compound: the second compound) is within a range of 10:90 to 70:30.

In one embodiment, the mass ratio of the first compound to the second compound (the first compound: the second compound) is within a range of 40:60 to 60:40.

The first layer may contain other compounds than the first compound and the second compound, or may not contain other compound than the first compound and the second compound.

In one embodiment, the first layer consists essentially of the first compound and the second compound.

The expression “consists essentially of the first compound and the second compound” means that no other compound is contained in the first layer, or the other compound is contained in a small amount within a range such that the effect of the invention is not impaired. For example, the case where other compound is mixed as an inevitable impurity is met to this state.

In one embodiment, the content (total amount) of other compounds than the first compound and the second compound in the first layer is, for example, 1% by mass or less, 0.5% by mass or less, 0.1% by mass or less, or 0.01% by mass or less.

In one embodiment, the first layer consists of the first compound and the second compound.

As typical device configurations of the organic EL device, structures obtained by stacking each of the following structures on a substrate can be exemplified.

(1) anode/emitting layer/electron-transporting zone/cathode
(2) anode/hole-transporting zone/emitting layer/electron-transporting zone/cathode
(“/” indicates that the layers are stacked directly adjacent to each other.)

The electron-transporting zone generally consists of one or more layers selected from an electron-injecting layer and an electron-transporting layer. The region between the emitting layer and the cathode generally corresponds to this electron-transporting zone.

The hole-transporting zone generally consists of one or more layers selected from a hole-injecting layer and a hole-transporting layer.

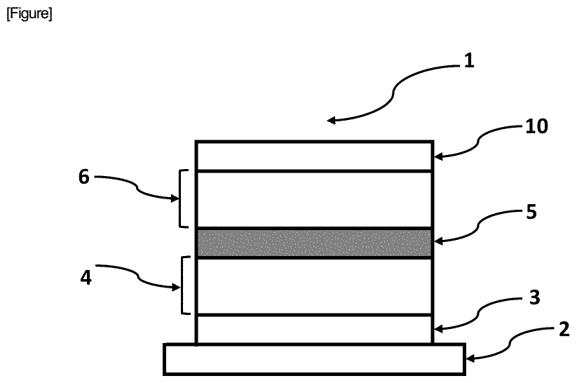

Schematic configuration of the organic EL device of an aspect of the invention will be explained by referring to the FIG. 1.

The organic EL device 1 according to an aspect of the invention has a substrate 2, an anode 3, an emitting layer 5, a cathode 10, a hole-transporting zone 4 disposed between the anode 3 and the emitting layer 5, and an electron-transporting zone 6 disposed between the emitting layer 5 and the cathode 10.

Parts which can be used in the organic EL device according to an aspect of the invention, materials for forming respective layers, other than the above-mentioned compounds, and the like, will be described below

### (Substrate)

A substrate is used as a support of an emitting device. As the substrate, glass, quartz, plastic or the like can be used, for example. Further, a flexible substrate may be used. The “flexible substrate” means a bendable (flexible) substrate, and specific examples thereof include plastic substrates formed of each of polycarbonate and polyvinyl chloride, and the like.

### (Anode)

For the anode formed on the substrate, metals, alloys, electrically conductive compounds, mixtures thereof, and the like, which have a large work function (specifically 4.0 eV or higher) are preferably used. Specific examples thereof include indium oxide-tin oxide (ITO: Indium Tin Oxide), indium oxide-tin oxide containing silicon or silicon oxide, indium oxide-zinc oxide, tungsten oxide, indium oxide containing zinc oxide, graphene, and the like. In addition thereto, specific examples thereof include gold (Au), platinum (Pt), nitrides of a metallic material (for example, titanium nitride), and the like.

### (Hole-Injecting Layer)

The hole-injecting layer is a layer containing a substance having a high hole-injecting property. As such a substance having a high hole-injecting property, molybdenum oxide, titanium oxide, vanadium oxide, rhenium oxide, ruthenium oxide, chromium oxide, zirconium oxide, hafnium oxide, tantalum oxide, silver oxide, tungsten oxide, manganese oxide, aromatic amine compounds, or polymer compounds (oligomers, dendrimers, polymers, etc.) can be given.

### (Hole-Transporting Layer)

The hole-transporting layer is a layer containing a substance having a high hole-transporting property. For the hole-transporting layer, aromatic amine compounds, carbazole derivatives, anthracene derivatives, and the like can be used. Polymer compounds such as poly(N-vinylcarbazole) (abbreviation: PVK) and poly(4-vinyltriphenylamine) (abbreviation: PVTPA) can also be used. However, substances other than the above-described substances may be used as long as the substances have a higher hole-transporting property in comparison with an electron-transporting property. It should be noted that the layer containing the substance having a high hole-transporting property may be not only a single layer, but also a stacking layer composed of two or more layers formed of the above-described substances.

### (Guest (Dopant) Material of Emitting Layer)

The emitting layer is a layer containing a substance having a high emitting property, and various materials can be used for forming it. For example, as the substances having a high emitting property, fluorescent compounds which emit fluorescence or phosphorescent compounds which emit phosphorescence can be used. The fluorescent compound is a compound which can emit from a singlet excited state, and the phosphorescent compound is a compound which can emit from a triplet excited state.

As blue fluorescent emitting materials which can be used for an emitting layer, pyrene derivatives, styrylamine derivatives, chrysene derivatives, fluoranthene derivatives, fluorene derivatives, diamine derivatives, triarylamine derivatives, and the like can be used. As green fluorescent emitting materials which can be used for an emitting layer, aromatic amine derivatives and the like can be used. As red fluorescent emitting materials which can be used for an emitting layer, tetracene derivatives, diamine derivatives and the like can be used.

As blue phosphorescent emitting materials which can be used for an emitting layer, metal complexes such as iridium complexes, osmium complexes, platinum complexes and the like are used. As green phosphorescent emitting materials which can be used for an emitting layer, iridium complexes and the like are used. As red phosphorescent emitting materials which can be used for an emitting layer, metal complexes such as iridium complexes, platinum complexes, terbium complexes, europium complexes and the like are used.

### (Host Material for Emitting Layer)

As the host compound of the emitting layer, in addition to the anthracene derivative described above, various compounds can be used, and a compound having a higher lowest unoccupied orbital level (LUMO level) and a lower highest occupied orbital level (HOMO level) than the above-described dopant material is preferable. The host compound generally means a material for dispersing the above-described dopant material.

Examples of the host compound other than the anthracene derivative described above include 1) metal complexes such as aluminum complexes, beryllium complexes, and zinc complexes, 2) heterocyclic compounds such as oxadiazole derivatives, benzimidazole derivatives, and phenanthroline derivatives, 3) fused aromatic compounds such as carbazole derivatives, phenanthrene derivatives, pyrene derivatives, and chrysene derivatives, and 4) aromatic amine compounds such as triarylamine derivatives, and fused polycyclic aromatic amine derivatives.

The emitting layer of the organic EL device may be any of an emitting layer of a fluorescent emitting type, of a phosphorescent emitting type, and of which using a TADF (Thermally Activated Delayed Fluorescence) mechanism.

Further, the organic EL device may be a monochromatic emitting device of a fluorescent emitting type, of a phosphorescent emitting type, or of using a thermally activated delayed fluorescent mechanism; may be a hybrid type white emitting device of the above-mentioned emitting devices; may be a simple type having a single emitting unit; or may be a tandem type having a plurality of emitting units. Here, the “emitting unit” refers to a minimum unit which has one or more organic layers, one of which is an emitting layer, and which can emit light by recombination of injected holes and electrons.

### (Electron-Transporting Layer)

The electron-transporting layer is a layer that contains a substance having a high electron-transporting property. For the electron-transporting layer, 1) metal complexes such as aluminum complexes, beryllium complexes, zinc complexes, and the like; 2) heteroaromatic complexes such as imidazole derivatives, benzimidazole derivatives, azine derivatives, carbazole derivatives, phenanthroline derivatives, and the like; and 3) polymer compounds can be used.

In the organic EL device according to an aspect of the invention, examples of materials that can be contained in layers other than the first layer in the electron-transporting zone include the above-described compounds and the like. Examples of materials that can be contained in the first layer other than the first compound and the second compound include the above-described compounds and the like.

In one embodiment, the organic EL device has a first layer (also referred to as a “first electron-transporting layer” or a “hole barrier layer”) and a second layer (also referred to as a “second electron-transporting layer”) in this order from the emitting layer side toward the cathode.

In one embodiment, the second layer contains one or more compounds selected from the group consisting of a compounds containing an alkali metal and compounds containing a metal belonging to Group 13 in the Periodic Table of the Elements. Examples of such compounds include lithium fluoride, lithium oxide, 8-hydroxyquinolinolato-lithium (Liq), cesium fluoride, tris(8-quinolinolato)aluminum (Alq3), tris(4-methyl-8-quinolinolato)aluminum (Almq3), bis(2-methyl-8-quinolinolato)(4-phenylphenolato)aluminum (BAlq), and the like.

In one embodiment, the organic EL device does not have any other layer between the first layer and the emitting layer.

In one embodiment, the organic EL device does not have any other layer between the first layer and the second layer.

### (Electron-Injecting Layer)

The electron-injecting layer is a layer which contains a substance having a high electron-injecting property. For the electron-injecting layer, lithium (Li), ytterbium (Yb), lithium fluoride (LiF), cesium fluoride (CsF), calcium fluoride (CaF₂), metal complex compounds such as 8-hydroxyquinolinolato-lithium (Liq), alkali metals, alkaline earth metals and compounds of the alkali metals and the alkaline earth metals such as lithium oxide (LiOₓ) can be used.

### (Cathode)

For the cathode, metals, alloys, electrically conductive compounds, mixtures thereof, and the like having a small work function (specifically, 3.8 eV or lower) are preferably used. Specific examples of such cathode materials include elements belonging to Group 1 or Group 2 of the Periodic Table of the Elements, i.e., alkali metals such as lithium (Li) and cesium (Cs), alkaline earth metals such as magnesium (Mg), calcium (Ca) and strontium (Sr), and alloys containing these metals (e.g., MgAg and AlLi); rare earth metals such as europium (Eu) and ytterbium (Yb), and alloys containing these metals.

The cathode is usually formed by a vacuum vapor deposition or a sputtering method. Further, in the case of using a silver paste or the like, a coating method, an inkjet method, or the like can be employed.

In the case where the electron-injecting layer is provided, a cathode can be formed of a substance selected from various electrically conductive materials such as aluminum, silver, ITO, graphene, indium oxide-tin oxide containing silicon or silicon oxide, regardless of the work function value.

In the organic EL device according to an aspect of the invention, the thickness of each layer is not particularly limited, but is generally preferable that the thickness be in the range of several nm to 1 μm in order to suppress defects such as pinholes, to make applied voltages to be low, and to increase luminous efficiency.

### (Method for Fabricating Organic EL Device)

In the organic EL device according to an aspect of the invention, the methods for forming the respective layers are not particularly limited. Conventionally-known methods for forming each layer such as a vacuum deposition process, a spin coating process and the like can be used. Each layer such as the emitting layer can be formed by a known method such as a vacuum deposition process, a molecular beam deposition process (MBE process), or an application process such as a dipping process, a spin coating process, a casting process, a bar coating process, or a roll coating process, using a solution prepared by dissolving the material in a solvent.

In one embodiment, the first layer may be formed by the use of a composition containing the first compound and the second compound satisfying the Conditions 1 and 2 described above. As the method of this embodiment, for example, a method in which the first compound and the second compound are mixed in advance and then vapor-deposited from single vapor deposition source to form the first layer is exemplified. This method has an advantage that can simplify the fabricating apparatus and the fabricating process.

The composition used in the above embodiments are described below.

The ratio of the first compound to the second compound in the composition is not particularly limited, and in one embodiment, the mass ratio (first compound:second compound) may be within a range of 10:90 to 90:10, for example, within a range of 10:90 to 70:30, or within a range of 40:60 to 60:40.

The composition may contain or may not contain other compounds than the first compound and the second compound. Examples of the other compound include the materials described in the first layer above.

In one embodiment, the composition consists essentially of the first compound and the second compound.

The expression “consists essentially of the first compound and the second compound” means that the composition contains no other compound, or that the composition contains other compound in a small amount within such a range that it does not impair the effect of the invention. For example, the case where other compound is mixed as an inevitable impurity is corresponded to this state.

In one embodiment, the content (total amount) of other compounds than the first compound and the second in the above-described composition is, for example, 1% by mass or less, 0.5% by mass or less, 0.1% by mass or less, or 0.01% by mass or less.

In one embodiment, the above-described composition consists of the first compound and the second compound.

The combination of the first compound and the second compound in the above-described composition is not particularly limited as long as they satisfy the above-described Conditions 1 and 2, and the first compound and the second compound can be appropriately combined. Some examples of the combination of the first compound and the second compound include Combination 1 to Combination 16 of “Some examples of the combination of the first compound and the second compound” exemplified in the organic EL device according to an aspect of the invention described above.

The form of the composition is not particularly limited, and examples thereof include a solid, a powder and the like, and the composition may be formed into a pellet shape.

When the composition is a powder (mixed powder), the powder may contain the first compound and the second compound in one particle, or the powder may be a mixture of particles composed of the first compound and particles composed of the second compound.

As a method for producing the powder, a conventionally-known method can be employed. For example, the first compound and the second compound may be pulverized and mixed using a mortar or the like, or the first compound and the second compound may be placed in a container or the like, heated in a chemically inert environment, then cooled to ambient temperature, and the obtained mixture may be pulverized with a mixer or the like to obtain a powder.

### [Electronic Apparatus]

The electronic apparatus according to an aspect of the invention is characterized in that the organic EL device according to an aspect of the invention is equipped with.

Specific examples of the electronic apparatuses include display components such as an organic EL panel module, and the like; display devices for a television, a cellular phone, a personal computer, and the like; and emitting devices such as a light, a vehicular lamp, and the like.

### EXAMPLES

<Compounds>

The first compounds used for fabricating the organic EL devices of Examples and Comparative Examples are shown below.

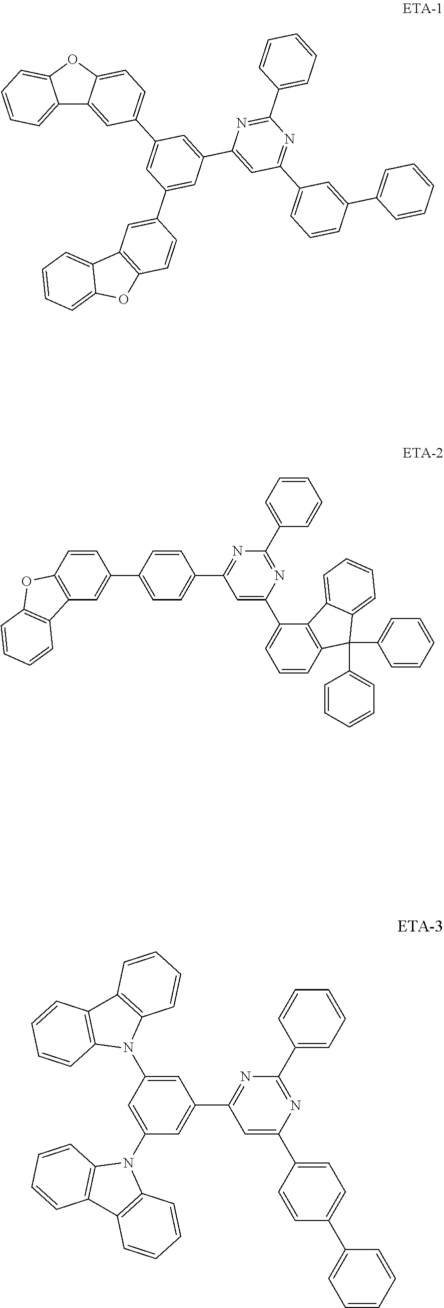 [SMILES: c1ccc(-c2cccc(-c3cc(-c4cc(-c5ccc6oc7ccccc7c6c5)cc(-c5ccc6oc7ccccc7c6c5)c4)nc(-c4ccccc4)n3)c2)cc1 ; c1ccc(-c2nc(-c3ccc(-c4ccc5oc6ccccc6c5c4)cc3)cc(-c3cccc4c3-c3ccccc3C4(c3ccccc3)c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

The second compounds used for fabricating the organic EL devices of Examples and Comparative Examples are shown below.

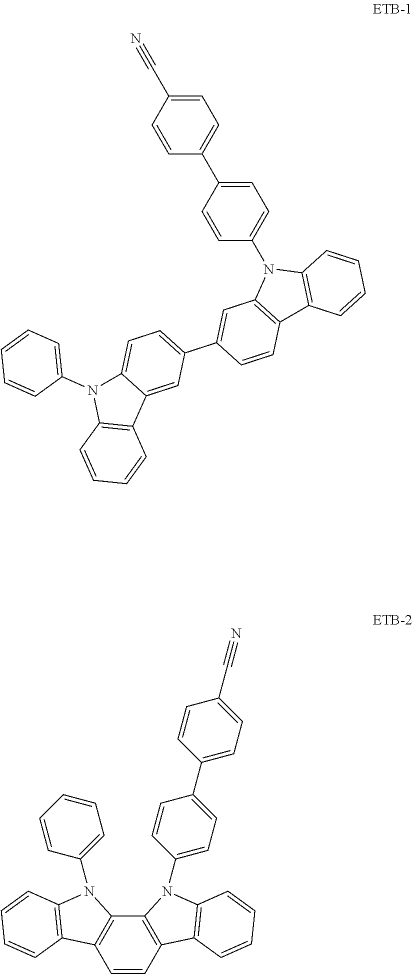 [SMILES: N#Cc1ccc(-c2ccc(-n3c4ccccc4c4ccc(-c5ccc6c(c5)c5ccccc5n6-c5ccccc5)cc43)cc2)cc1 ; N#Cc1ccc(-c2ccc(-n3c4ccccc4c4ccc5c6ccccc6n(-c6ccccc6)c5c43)cc2)cc1]

The host compound of the emitting layer used for fabricating the organic EL devices of Examples and Comparative Examples is shown below.

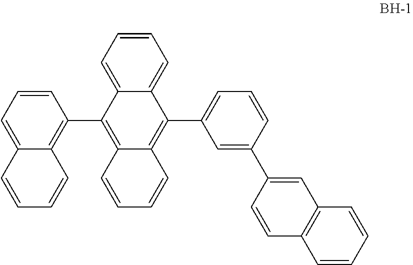 [SMILES: c1cc(-c2ccc3ccccc3c2)cc(-c2c3ccccc3c(-c3cccc4ccccc34)c3ccccc23)c1]

The structures of the other compounds used for fabricating the organic EL devices of Examples and Comparative Examples are shown below.

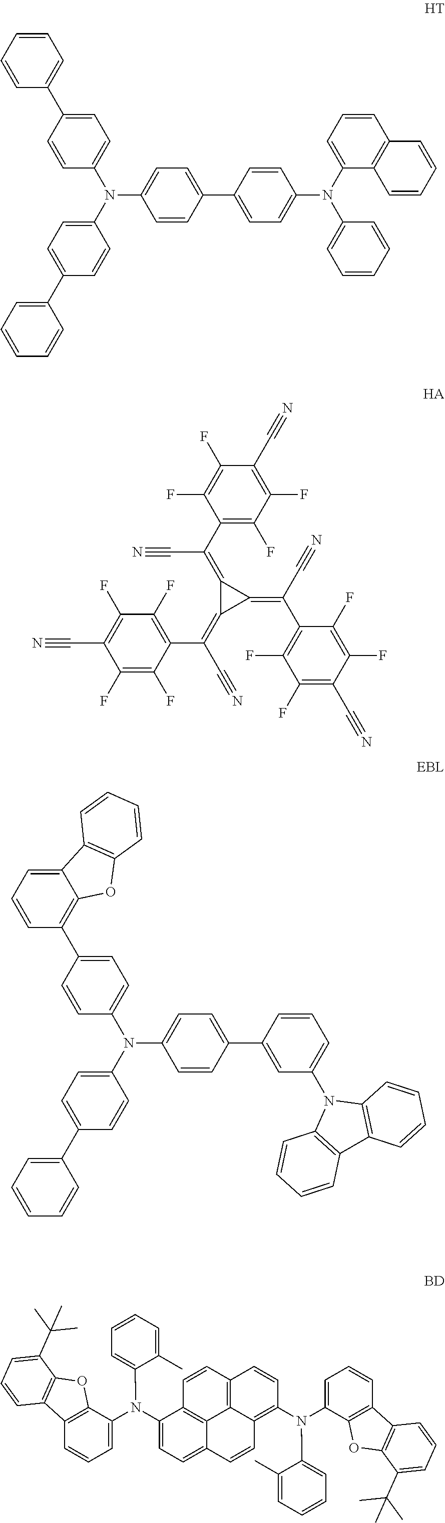 [SMILES: c1ccc(-c2ccc(N(c3ccc(-c4ccccc4)cc3)c3ccc(-c4ccc(N(c5ccccc5)c5cccc6ccccc56)cc4)cc3)cc2)cc1 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1 ; Cc1ccccc1N(c1ccc2ccc3c(N(c4ccccc4C)c4cccc5c4oc4c(C(C)(C)C)cccc45)ccc4ccc1c2c43)c1cccc2c1oc1c(C(C)(C)C)cccc12]

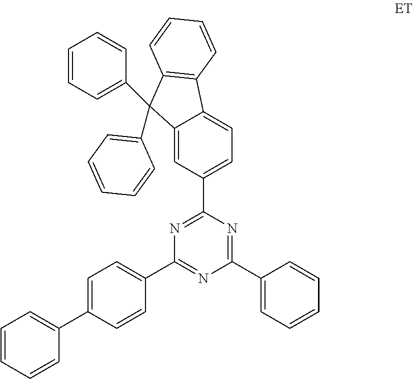 [SMILES: c1ccc(-c2ccc(-c3nc(-c4ccccc4)nc(-c4ccc5c(c4)C(c4ccccc4)(c4ccccc4)c4ccccc4-5)n3)cc2)cc1]

### <Evaluation of Compound>

The electron affinities of the first compound, the second compound, and the host compound were evaluated by the following measurement method. The results are shown in Table 1.

The electron affinity Af was calculated by the next formula and the subsequent formulas.

Af=−1.19×(Ere−Efc)−4.78 eV

Here, each symbol means the following.

Ere: First reduction potential (DPV, Negative scan)
Efc: Ferrocene's primary potential (DPV, Positive scan), (ca. +0.55V vs Ag/AgCl)

The redox potential was measured by differential pulse voltammetry (DPV) using an electrochemical analyzer (CHI630B, manufactured by ALS).

N,N-dimethylformamide (DMF) was used as the solvent, and the sample concentration was 1.0 mmol/L. Tetrabutylammonium hexafluorophosphate (TBHP) (100 mmol/L) was used as the supporting electrolyte. Glassy carbon and Pt were used as the working electrode and the counter electrode, respectively.
(Reference documents) M. E. Thompson, et al., Organic Electronics, 6 (2005), p. 11-20, Organic Electronics, 10 (2009), p. 515-520

TABLE 1

| | Electron Affinity Af |
|---|---|
| | (eV) |
| ETA-1 | 2.17 |
| ETA-2 | 2.17 |
| ETA-3 | 2.33 |
| ETB-1 | 2.01 |
| ETB-2 | 1.94 |
| BH-1 | 2.09 |

### Example 1

### <Fabrication of Organic EL Device>

An organic EL device was fabricated as follows.

A 25 mm×75 mm×1.1 mm-thick glass substrate with an ITO transparent electrode (anode) (manufactured by GEOMATEC Co., Ltd.) was subjected to ultrasonic cleaning in isopropyl alcohol for 5 minutes, and then subjected to UV-ozone cleaning for 30 minutes. The thickness of the ITO film was 130 nm.

The glass substrate with the transparent electrode after being cleaned was mounted onto a substrate holder in a vacuum vapor deposition apparatus. First, Compound HT and Compound HA were co-deposited to be 3% by mass in a proportion of the Compound HA on a surface on the side on which the transparent electrode was formed so as to cover the transparent electrode to form a first hole-transporting layer having a thickness of 10 nm.

Compound HT was deposited on the first hole-transporting layer to form a second hole-transporting layer having a thickness of 80 nm.

Compound EBL was deposited on the second hole-transporting layer to form a third hole-transporting layer having a thickness of 5 nm.

Compound BH-1 (host material) and Compound BD (dopant material) were co-deposited on the third hole-transporting layer to be 4% by mass in a proportion of the Compound BD to form an emitting layer having a thickness of 25 nm.

Compound ETA-1 and Compound ETB-1 were co-deposited on the emitting layer to be 40% by mass in a proportion of Compound ETB-1 to form a first electron-transporting layer having a thickness of 5 nm.

Compound ET and 8-hydroxyquinolinolato-lithium (Liq) were co-deposited on the first electron-transporting layer to be 50% by mass in a proportion of Liq to form a second electron-transporting layer having a thickness of 20 nm.

Metal Yb was deposited on the second electron-transporting layer to form an electron-injecting layer having a thickness of 1 nm.

Metal Al was deposited on the electron-injecting layer to form a cathode having a thickness of 50 nm.

The device configuration of the organic EL device of Example 1 is shown in a simplified style as follows.

### ITO(130)/HT:HA(10:3%)/HT(80)/EBL(5)/BH-1:BD(25:4%)/ETA-1:ETB-1(5:40%)/ET:Lig(20:50%)/Yb(1)/Al(50)

Numerical values in parentheses indicate film thickness (unit: nm). In parentheses, the numerical values in percentage indicate the proportion (% by mass) of the latter compound in the layer.

Further, the absolute value of the difference between the electron affinity Af_{H} of the host compound of the emitting layer and the electron affinity Af_{ETA} of the compound ETA-1 (the first compound) (IAfH-AfETAI), and the absolute value of the difference between the electron affinity Af_{H} of the host compound and the electron affinity Af_{ETB} of ETB-1 (the second compound) (|Af_{H}−Af_{ETB}|) are shown in Table 2.

### <Evaluation of Organic EL Device>

The organic EL device thus fabricated was evaluated as follows. The results are shown in Table 2.

Driving Voltage

Initial properties of the organic EL device was measured under driving at room temperature with DC (direct current) constant current of 10 mA/cm²·External quantum efficiency

A voltage was applied to the organic EL device so that the current density was 10 mA/cm², and the EL emission spectrum was measured by using Spectroradiometer CS-2000 (manufactured by KONICA MINOLTA, INC.). External quantum efficiency (EQE) (%) was calculated from the obtained spectral radiance spectrum.

### Examples 2 and 3

Organic EL devices were fabricated and evaluated in the same manner as in Example 1, except that the content proportion of Compound ETA-1 and Compound ETB-1 in the first electron-transporting layer was changed as shown in Table 2. The results are shown in Table 2.

### Example 4

An organic EL device was fabricated and evaluated in the same manner as in Example 1 except that Compound ETA-2 was used in place of Compound ETA-1. The results are shown in Table 2.

### Examples 5 and 6

Organic EL devices were fabricated and evaluated in the same manner as in Example 4, except that the content proportion of Compound ETA-2 and Compound ETB-1 in the first electron-transporting layer was changed as shown in Table 2. The results are shown in Table 2.

### Comparative Examples 1 to 5

Organic EL devices were fabricated and evaluated in the same manner as in Example 1, except that the compounds used and the composition (content proportion) in the first electron-transporting layer were changed as shown in Table 2. The results are shown in Table 2.

TABLE 2

| | First electron-transporting layer | | | | Driving | |
|---|---|---|---|---|---|---|
| | First | Second | | | Voltage | EQE |
| | compound | compound | \|Af_{H} − Af_{ETA}\| | \|Af_{H} − Af_{ETB}\| | (V) | (%) |
| Example 1 | ETA-1 | ETB-1 | 0.08 | 0.08 | 3.8 | 9.3 |
| | (60% by mass) | (40% by mass) | | | | |
| Example 2 | ETA-1 | ETB-1 | 0.08 | 0.08 | 3.8 | 9.3 |
| | (40% by mass) | (60% by mass) | | | | |
| Example 3 | ETA-1 | ETB-1 | 0.08 | 0.08 | 3.8 | 9.3 |
| | (20% by mass) | (80% by mass) | | | | |
| Example 4 | ETA-2 | ETB-1 | 0.08 | 0.08 | 3.7 | 10.0 |
| | (60% by mass) | (40% by mass) | | | | |
| Example 5 | ETA-2 | ETB-1 | 0.08 | 0.08 | 3.7 | 10.0 |
| | (40% by mass) | (60% by mass) | | | | |
| Example 6 | ETA-2 | ETB-1 | 0.08 | 0.08 | 3.9 | 9.4 |
| | (20% by mass) | (80% by mass) | | | | |
| Comp. | ETA-3 | ETB-1 | 0.24 | 0.08 | 4.1 | 7.7 |
| Ex. 1 | (40% by mass) | (60% by mass) | | | | |
| Comp. | ETA-3 | ETB-1 | 0.24 | 0.08 | 4.2 | 7.9 |
| Ex. 2 | (20% by mass) | (80% by mass) | | | | |
| Comp. | ETA-1 | ETB-2 | 0.08 | 0.15 | 4.1 | 8.6 |
| Ex. 3 | (20% by mass) | (80% by mass) | | | | |
| Comp. | ETA-3 | ETB-2 | 0.24 | 0.15 | 4.2 | 7.3 |
| Ex. 4 | (40% by mass) | (60% by mass) | | | | |
| Comp. | ETA-3 | ETB-2 | 0.24 | 0.15 | 4.4 | 7.1 |
| Ex. 5 | (20% by mass) | (80% by mass) | | | | |

Comparative Example 1 and Comparative Example 2 are Comparative Examples that satisfy the Condition 2 but not satisfy the Condition 1 (i.e., the absolute value of the affinity of the first compound is too large to that of the host).

Comparative Example 3 is a Comparative Example that satisfies Condition 1 but not satisfy Condition 2 (i.e., the absolute value of the affinity of the second compound is too small to that of the host).

Comparative Example 4 and Comparative Example 5 are Comparative Examples that do not satisfy both Condition 1 and Condition 2.

The organic EL devices obtained in Comparative Examples 1 to 5 have higher driving voltages and lower efficiency than the organic EL devices obtained in Examples 1 to 6. From this fact, it can be seen that by satisfying the above-described Conditions 1 and 2 at the same time, an organic EL device having higher performance can be obtained.

### <Synthesis of Compound>

### (Synthesis Example 1) Synthesis of ETA-2

Compound ETA-2 was synthesized in accordance with the synthetic route described below.

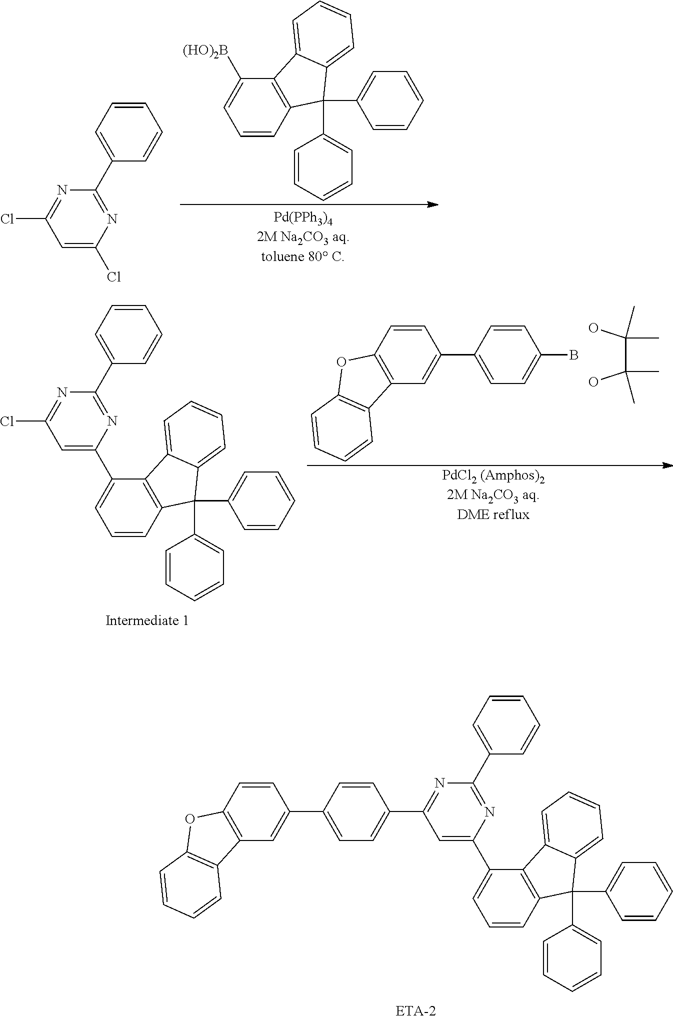

### (1-1) Synthesis of Intermediate 1

4,6-dichloro-2-phenylpyrimidine (15 g) and (9,9-diphenyl-9H-fluoren-4-yl)boronic acid (24 g) were dissolved in toluene (888 mL) and 1,2-dimethoxyethane (444 mL), tetrakis(triphenylphosphine)palladium(0) (3.1 g) and an aqueous sodium carbonate solution (2 M, 100 mL) were added thereto, and the mixture was stirred at 80° C. for 21 hours. After completion of the reaction, the reaction solution was cooled to room temperature and extracted with toluene. The resulting organic layer was washed with saturated brine, dried over magnesium sulfate, and the solvent was evaporated under reduced pressure. The residue was purified by silica gel column chromatography and suspension washing to obtain Intermediate 1 (16 g, yield: 43%) as a white solid.

### (1-2) Synthesis of Compound ETA-2

To Intermediate 1 (7.0 g) and 2-[4-(4,4,5,5-tetramethyl-1,3,2-dioxaborolan-2-yl)phenyl]dibenzofuran (4.9 g), 1,2-dimethoxyethane (69 mL) was added, and the mixture was stirred. PdCl₂(Amphos)₂ (0.39 g) and an aqueous sodium carbonate solution (2 M, 21 mL) were added thereto, and the mixture was stirred at 80° C. for 6 hours. After completion of the reaction, the reaction solution was cooled to room temperature, and the precipitated solid was collected by filtration. The obtained solid was purified by silica gel column chromatography and recrystallization to obtain a white solid (8.1 g, yield: 82%).

As a result of mass spectrum analysis, the resultant white solid has m/e=715, and identified as Compound ETA-2.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification and the specification of Japanese application(s) on the basis of which the present application claims Paris convention priority are incorporated herein by reference in its entirety.

1. An organic electroluminescence device comprising:
a cathode;
an anode; and
an emitting layer disposed between the cathode and the anode,
a first layer disposed between the emitting layer and the cathode,
wherein
the emitting layer comprises a host compound,
the first layer comprises a first compound and a second compound; and
the three compounds are in a relationship satisfying the following Conditions 1 and 2:
(Condition 1)
the electron affinity Af_{H} of the host compound and the electron affinity Af_{ETA} of the first compound satisfy the following expressions (1-1) and (1-2):
Af_{H}<Af_{ETA} (1-1)

|Af_{H}−Af_{ETA}|≤0.10 (1-2)
(Condition 2)
the electron affinity Af_{H} of the host compound and the electron affinity Af_{ETB} of the second compound satisfy the following expressions (2-1) and (2-2):
Af_{H}>Af_{ETB} (2-1)

|Af_{H}−Af_{ETB}≡1≤0.10 (2-2)
(Condition 2)
the electron affinity Af_{H} of the host compound and the electron affinity Af_{ETB} of the second compound satisfy the following expressions (2-1) and (2-2):
Af_{H}>Af_{ETB} (2-1)

|Af_{H}−Af_{ETB}≡1≤0.10 (2-2).

2. The organic electroluminescence device according to claim 1, which does not have any other layer disposed between the first layer and the emitting layer.

3. The organic electroluminescence device of claim 1, wherein the first layer consists essentially of the first compound and the second compound.

4. The organic electroluminescence device according to claim 1, wherein the first layer consists of the first compound and the second compound.

5. The organic electroluminescence device according to claim 1, wherein the first layer comprises the first compound and the second compound in a mass ratio range (first compound:second compound) of 10:90 to 90:10.

6. The organic electroluminescence device according to claim 1, wherein the first layer comprises the first compound and the second compound in a mass ratio range (first compound:second compound) of 10:90 to 70:30.

7. The organic electroluminescence device according to claim 1, wherein the first layer comprises the first compound and the second compound in a mass ratio range (first compound:second compound) of 40:60 to 60:40.

8. The organic electroluminescence device according to claim 1, further comprising a second layer comprising an electron-transporting material disposed between the first layer and the cathode.

9. The organic electroluminescence device according to claim 1, which does not have any other layer between the first layer and the second layer.

10. The organic electroluminescence device according to claim 1, wherein the electron affinity Af_{H} of the host compound and the electron affinity Af_{ETA} of the first compound satisfy the following expression (1-2-1):

|Af_{H}−Af_{ETA}|≤0.09 (1-2-1).

11. The organic electroluminescence device according to claim 1, wherein the electron affinity Af_{H} of the host compound and the electron affinity Af_{ETB} of the second compound satisfy the expression formula (2-2-1):

|Af_{H}−Af_{ETB}|≤0.09 (2-2-1).

12. The organic electroluminescence device according to claim 1,
wherein the emitting layer comprises a fluorescent emitting material.

13. The organic electroluminescence device according to claim 1,
wherein the first compound is a compound represented by the following formula (1): 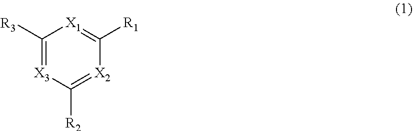
wherein in the formula (1),
X₁ to X₃ are independently CR₄ or N;
at least one of X₁ to X₃ is N;
R₄ is a hydrogen atom or a substituent R;
when two or more R₄'s are present, the two or more R₄'s may be the same as or different from each other;
R₁ to R₃ are independently a hydrogen atom or a substituent R;
the substituent R is
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;
when two or more of the substituent R's are present, the two or more of the substituent R's may be the same as or different from each other; and
R₉₀₁ to R₉₀₇ are independently
a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and
when two or more of each of R₉₀₁ to R₉₀₇ are present, the two or more of each of R₉₀₁ to R₉₀₇ may be the same as or different from each other.

14. The organic electroluminescence device according to claim 13, wherein the compound represented by the formula (1) is a compound represented by the following formula (11): 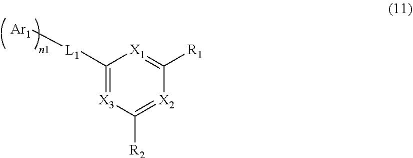
wherein in the formula (11),
X₁ to X₃, R₁, and R₂ are as defined in the formula (1);
L₁ is
a single bond,
a substituted or unsubstituted aromatic hydrocarbon group including 6 to 50 ring carbon atoms, or
a substituted or unsubstituted heterocyclic group including 5 to 50 ring atoms;
Ar₁ is
a substituted or unsubstituted aryl group including 6 to 50 ring carbon atoms, or
a substituted or unsubstituted monovalent heterocyclic group including 5 to 50 ring atoms; and
n1 is an integer of 1 to 3; when n1 is 2 or more, two or more Ar₁'s may be the same as or different from each other.

15. The organic electroluminescence device according to claim 14, wherein Ar₁ is a group represented by the following formula (12): 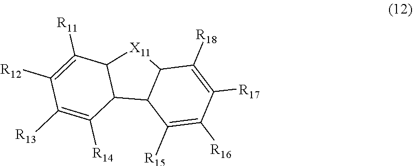
wherein in the formula (12),
Xᵢᵢ is O, S, N(R₂₁), or C(R₂₂)(R₂₃);
one of R₁₁ to R₁₈ and R₂₁ to R₂₃ is a single bond which bonds with L₁;
one or more sets of adjacent two or more of R₁₁ to R₁₈ which are not the single bond which bonds with L₁ form a substituted or unsubstituted, saturated or unsaturated ring by bonding with each other, or do not form a substituted or unsubstituted, saturated or unsaturated ring;
R₁₁ to R₁₈ which are not the single bond which bonds with L₁ and which do not form the substituted or unsubstituted, saturated or unsaturated ring, and R₂₁ to R₂₃ which are not the single bond which bonds with L₁ are independently a hydrogen atom or a substituent R; and
the substituent R is as defined in the formula (1).

16. The organic electroluminescence device according to claim 15, wherein X₁₁ is O or S.

17. The organic electroluminescence device according to claim 13, wherein the compound represented by the formula (1) is a compound represented by the following formula (21): 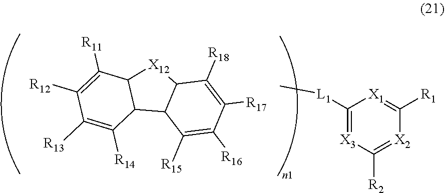
wherein in the formula (21),
X₁ to X₃, R₁, and R₂ are as defined in the formula (1);
L₁ is as defined in the formula (11);
X₁₂ is O or S;
one of R₁₁ to R₁₈ is a single bond which bonds with L₁;
one or more sets of adjacent two or more of R₁₁ to R₁₈ which are not the single bond which bonds with L₁ form a substituted or unsubstituted, saturated or unsaturated ring by bonding with each other, or do not form a substituted or unsubstituted, saturated or unsaturated ring;
R₁₁ to R₁₈ which are not the single bond which bonds with L₁ and which do not form the substituted or unsubstituted, saturated or unsaturated ring are independently a hydrogen atom or a substituent R;
n1 is an integer of 1 to 3; when n1 is 2 or more, two or more of the structures in parentheses may be the same as or different from each other; and
the substituent R is as defined in the formula (1).

18. The organic electroluminescence device according to claim 14, wherein
L₁ is
a single bond, or
an unsubstituted arylene group including 6 to 50 ring carbon atoms; and
the substituent R is
an unsubstituted alkyl group including 1 to 50 carbon atoms,
an unsubstituted alkenyl group including 2 to 50 carbon atoms,
an unsubstituted alkynyl group including 2 to 50 carbon atoms,
an unsubstituted cycloalkyl group including 3 to 50 ring carbon atoms,
—Si(R₉₁₁)(R₉₁₂)(R₉₁₃),
—O—(R₉₁₄),
—S—(R₉₁₅),
—N(R₉₁₆)(R₉₁₇),
a halogen atom, a cyano group, a nitro group, or
an unsubstituted aryl group including 6 to 50 ring carbon atoms; and
R₉₁₁ to R₉₁₇ are independently
a hydrogen atom,
an unsubstituted alkyl group including 1 to 50 carbon atoms,
an unsubstituted cycloalkyl group having 3 to 50 ring carbon atoms, or
an unsubstituted aryl group including 6 to 50 ring carbon atoms.

19. The organic electroluminescence device according to claim 13, wherein two of X₁ to X₃ are N's.

20. The organic electroluminescence device according to claim 1, wherein the second compound is a compound represented by the following formula (51): 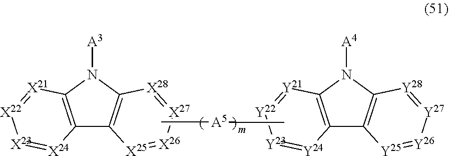
wherein in the formula (51),
A³ and A⁴ are independently
a substituted or unsubstituted aryl group including 6 to 30 ring carbon atoms, or
a substituted or unsubstituted monovalent heterocyclic group including 5 to 30 ring atoms;
A⁵ is
a substituted or unsubstituted monocyclic hydrocarbon group including 3 to 6 ring carbon atoms, or
a substituted or unsubstituted monocyclic heterocyclic group including 3 to 6 ring atoms;
m is an integer of 0 to 3;
when m is 0, (A⁵)ₘ represents a single bond;
one of X²⁵ to X²⁸ is a carbon atom which is bonded with A⁵;
X²¹ to X²⁴, and X²⁵ to X²⁸ which are not the carbon atom which is bonded with A⁵ are independently N or CR^{a};
one of Y²¹ to Y²⁴ is a carbon atom which is bonded with A⁵;
Y²⁵ to Y²⁸, and Y²¹ to Y²⁴ which are not a carbon atom which is bonded with A⁵ are independently N or CR^{a};
one or more sets of adjacent two or more R^{a}'s form a substituted or unsubstituted, saturated or unsaturated ring by bonding with each other, or do not form the substituted or unsubstituted, saturated or unsaturated ring;
R^{a}'s which do not form the substituted or unsubstituted, saturated or unsaturated ring are independently a hydrogen atom or a substituent R;
the substituent R is selected from the group consisting of:
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇)
a halogen atom, a cyano group, a nitro group,
a substituted or unsubstituted aryl group including 6 to 50 ring carbon atoms, and
a substituted or unsubstituted monovalent heterocyclic group including 5 to 50 ring atoms;
R₉₀₁ to R₉₀₇ are independently
a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and
when two or more of each of R₉₀₁ to R₉₀₇ are present, the two or more of each of R₉₀₁ to R₉₀₇ may be the same as or different from each other;
when two or more of the substituent R's are present, each of the two or more of the substituent R's may be the same as or different from each other; and
provided that the compound represented by the formula (51) satisfies either or both of the following Conditions (i) and (ii);
Condition (i): at least one of A³ and A⁴ is
a substituted aryl group including 6 to 30 ring carbon atoms that has at least one cyano group as the substituent, or
a monovalent heterocyclic group including 5 to 30 ring atoms that has at least one cyano group as the substituent; and
Condition (ii): at least one of X¹¹ to X²⁸ and Y²¹ to Y²⁸ is CR^{a}, and at least one R^{a} among the at least one CR^{a} is
a substituted aryl group including 6 to 30 ring carbon atoms that has at least one cyano group as the substituent, or
a monovalent heterocyclic group including 5 to 30 ring atoms that has at least one cyano group as the substituent.

21. The organic electroluminescence device according to claim 20, wherein m in the formula (51) is 0.

22. The organic electroluminescence device according to claim 20, wherein the compound represented by the formula (51) is a compound represented by the following formula (72): 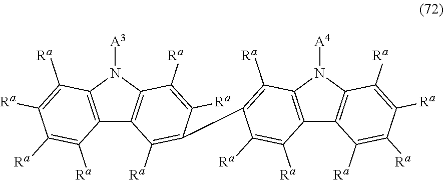
wherein in the formula (72), R^{a}, A³, and A⁴ are as defined in the formula (51).

23. The organic electroluminescence device according to claim 20, wherein the substituted aryl group including 6 to 30 ring carbon atoms that has at least one cyano group as the substituent in the Conditions (i) and (ii) is a group selected from groups represented by each of the following formulas (2-1) to (2-5):

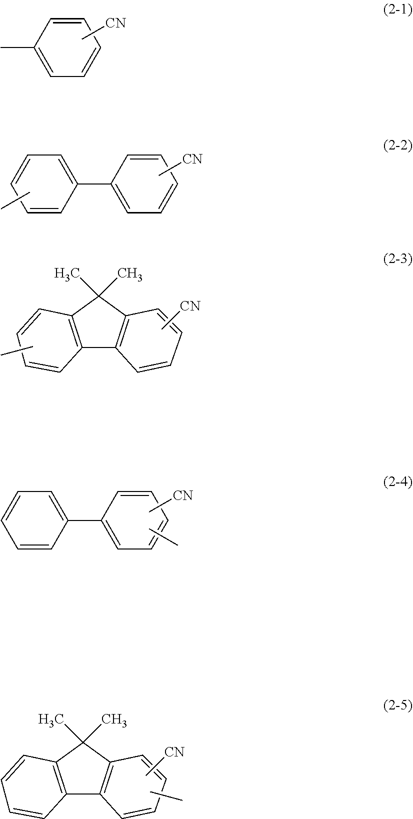

24. The organic electroluminescence device according to claim 20, wherein the compound represented by the formula (51) satisfies the Condition (i) but not the Condition (ii).

25. The organic electroluminescence device according to claim 20, wherein the compound represented by the formula (51) satisfies either or both of the following Conditions (ia) and (iia):
Condition (ia): at least one of A³ and A⁴ is
a substituted aryl group including 6 to 30 ring carbon atoms that has at least one cyano group as the substituent, but no other substituent, or
a monovalent heterocyclic group including 5 to 30 ring atoms that has a cyano group but no other substituent;
Condition (iia): at least one of X²¹ to X²⁸ and Y²¹ to Y²⁸ is CR^{a} and at least one R^{a} among the at least one CR^{a} is
a substituted aryl group including 6 to 30 ring carbon atoms that has at least one cyano group as the substituent, but no other substituent, or
a monovalent heterocyclic group including 5 to 30 ring atoms that has a cyano group but no other substituent.

26. The organic electroluminescence device according to claim 20, wherein the compound represented by the formula (51) satisfies the Condition (i) or (ia) but not the Conditions (ii) and (iia);
X²¹ to X²⁴, X²⁵ to X²⁸ which are not the carbon atom which is bonded with A⁵, Y²⁵ to Y²⁸, and Y²¹ to Y²⁴ which are not the carbon atom which is bonded with A⁵ are all CR^{a}'s;
m is 0; and
A³ and A⁴ are independently a substituted or unsubstituted aryl group including 6 to 12 ring carbon atoms.

27. The organic electroluminescence device according to claim 1, wherein the host compound is an anthracene derivative.

28. The organic electroluminescence device according to claim 1,
wherein the host compound is a compound represented by the following formula (101): 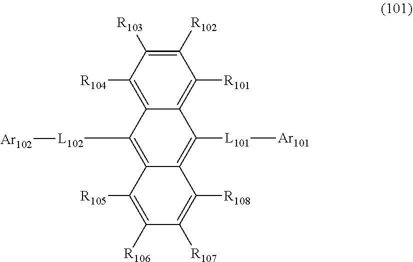
wherein in the formula (101),
one or more sets of adjacent two or more of R₁₀₁ to R₁₀₆ form a substituted or unsubstituted, saturated or unsaturated ring by bonding with each other, or do not form the substituted or unsubstituted, saturated or unsaturated ring;
R₁₀₁ to R₁₀₈ which do not form the substituted or unsubstituted, saturated or unsaturated ring are independently a hydrogen atom or a substituent R;
L₁₀₁ and L₁₀₂ are independently
a single bond,
a substituted or unsubstituted arylene group including 6 to 50 ring carbon atoms, or a substituted or unsubstituted divalent heterocyclic group including 5 to 50 ring atoms;
Ar₁₀₁ and Ar₁₀₂ are independently
a substituted or unsubstituted aryl group including 6 to 50 ring carbon atoms, or
a substituted or unsubstituted monovalent heterocyclic group including 5 to 50 ring atoms;
the substituent R is
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;
when two or more of the substituent R's are present, the two or more of the substituent R's may be the same as or different from each other; and
R₉₀₁ to R₉₀₇ are independently
a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and
when two or more of each of R₉₀₁ to R₉₀₇ are present, the two or more of each of R₉₀₁ to R₉₀₇ may be the same as or different from each other.

29. The organic electroluminescence device according to claim 28, wherein at least of:
hydrogen atoms possessed by the substituted or unsubstituted, saturated or unsaturated ring formed by bonding one or more sets of adjacent two or more of R₁₀₁ to R₁₀₈ each other,
R₁₀₁ to R₁₀₈ which are hydrogen atoms,
hydrogen atoms possessed by R₁₀₁ to R₁₀₈ which are substituents R,
hydrogen atoms possessed by L₁₀₁,
hydrogen atoms possessed by L₁₀₂,
hydrogen atoms possessed by Ar₁₀₁, and
hydrogen atoms possessed by A₁₀₂
is a deuterium atom.

30. The organic electroluminescence device according to claim 28, wherein the compound represented by the formula (101) is a compound represented by the following formula (102): 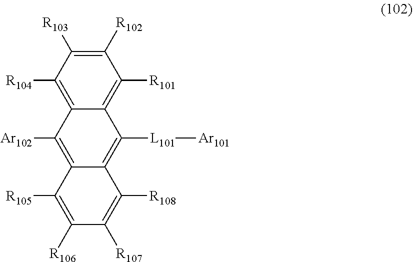
wherein in the formula (102), R₁₀₁ to R₁₀₈, L₁₀₁, Ar₁₀₁, and Ar₁₀₂ are as defined in the formula (101).

31. The organic electroluminescence device according to claim 28, wherein the compound represented by the formula (101) the host compound is a compound represented by the following formula (103): 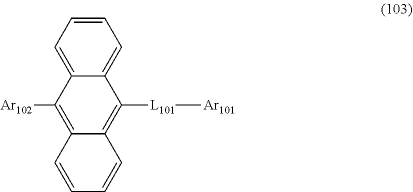
wherein in the formula (103), L₁₀₁, Ar₁₀₁, and Ar₁₀₂ are as defined in the formula (101).

32. An electronic apparatus equipped with the organic electroluminescence device according to claim 1.

33. A method for fabricating the organic electroluminescence device according to claim 1, comprising forming the first layer using a composition comprising the first compound and the second compound.
